(19) United States
(12) Patent Application Publication
(10) Pub. No.: US 2026/0164380 A1
(43) Pub. Date: Jun. 11, 2026

(54) SYSTEM AND METHOD FOR PHYSICAL BROADCAST CHANNEL (PBCH) SCRAMBLING AND SOFT COMBINING

(71) Applicant: QUALCOMM Incorporated, San Diego, CA (US)

(72) Inventors: Liangping MA, San Diego, CA (US); Hung Dinh LY, San Diego, CA (US); Yongle WU, San Diego, CA (US); Alberto RICO ALVARINO, San Diego, CA (US)

(21) Appl. No.: 19/028,793

(22) Filed: Jan. 17, 2025

Related U.S. Application Data
(63) Continuation-in-part of application No. 18/976,879, filed on Dec. 11, 2024.

(51) Int. Cl. H04W 56/00; H03M 13/29; H03M 13/39

(52) U.S. Cl. CPC H04W 56/0015; H03M 13/2927; H03M 13/3927

(57) ABSTRACT

Various aspects of the present disclosure generally relate to wireless communication, and to supporting physical broadcast channel (PBCH) scrambling and soft combining that supports larger synchronization signal block (SSB) periodicity. For example, a network node may transmit multiple SSBs in accordance with an SSB periodicity. The SSBs respectively include multiple PBCHs, and the PBCHs respectively include multiple master information blocks (MIBs) in accordance with an MIB periodicity. Each of the PBCHs includes a respective scrambled portion and a respective unscrambled portion. The unscrambled portions each include timing information in accordance with the SSB periodicity and the MIB periodicity. The UE decodes the PBCHs by soft combining the PBCHs in accordance with the timing information and descrambles resulting scrambled PBCH payloads in accordance with scrambling sequences associated with the unscrambled portions.

### CROSS-REFERENCE TO RELATED APPLICATIONS

The present application claims priority from and is a continuation-in-part of pending U.S. patent application Ser. No. 18/976,879, filed Dec. 11, 2024, and entitled “SYSTEM AND METHOD FOR PHYSICAL BROADCAST CHANNEL (PBCH) SCRAMBLING AND SOFT COMBINING,” the content of which is incorporated herein by reference in its entirety.

### FIELD OF THE DISCLOSURE

Aspects of the present disclosure relate generally to wireless communication systems, and more particularly, to physical broadcast channel (PBCH) scrambling and soft combining in wireless communication systems.

### BACKGROUND

Wireless communications systems are widely deployed to provide various types of services such as voice, video, packet data, messaging, broadcast, and other types of traffic. The services may include unicast, multicast, and/or broadcast services, among other examples. Typical wireless communication systems may support multiple-access radio access technologies and include a number of base stations or network nodes, each supporting communication for multiple communication devices, which may be otherwise known as user equipment (UE). These systems may be capable of supporting communication with multiple users by sharing available system resources (such as time domain resources, frequency domain resources, spatial domain resources, and device transmit power, among other examples). These systems may employ multiple-access technologies such as code division multiple access (CDMA) technology, time division multiple access (TDMA) technology, frequency division multiple access (FDMA) technology, orthogonal frequency division multiple access (OFDMA) technology, discrete Fourier transform spread orthogonal frequency division multiplexing (DFT-S-OFDM) technology, single-carrier frequency division multiple access (SC-FDMA) technology, and time division synchronous code division multiple access (TD-SCDMA) technology.

The above multiple-access technologies have been adopted in various telecommunication standards to provide common protocols that enable different wireless communication devices to communicate on a municipal, national, regional, or global level. An example telecommunication standard is New Radio (NR). NR, which may also be referred to as 5G, is part of a continuous mobile broadband evolution promulgated by the Third Generation Partnership Project (3GPP). NR (and other mobile broadband evolutions beyond NR) may be designed to better support Internet of things (IoT) and reduced capability device deployments, industrial connectivity, millimeter wave (mmWave) expansion, licensed and unlicensed spectrum access, non-terrestrial network (NTN) deployment, sidelink and other device-to-device direct communication technologies (for example, cellular vehicle-to-everything (CV2X) communication), massive multiple-input multiple-output (MIMO), disaggregated network architectures and network topology expansions, multiple-subscriber implementations, carrier aggregation, high-precision positioning, and/or radio frequency (RF) sensing, among other examples. As the demand for mobile broadband access continues to increase, further improvements in NR may be implemented, and other radio access technologies, such as 6G, may be introduced to further advance mobile broadband evolution.

To enable initial cell selection by one or more UEs, a network node may transmit synchronization signal blocks (SSBs) according to a fixed SSB periodicity, which may be designated in a wireless communication standard. A respective physical broadcast channel (PBCH) is included in each SSB, and a payload of each PBCH includes a master information block (MIB) that provides parameters to the UEs for decoding additional messages. One element included in the PBCH payload is a system frame number (SFN), which is used as timing information for the cell supported by the network node and is thus incremented at a fixed rate. As part of the process of generating the PBCHs, the network node performs a first scrambling process on a portion of a respective PBCH payload, and this process is not applied to a fixed portion of the SFN that is expected to vary in PBCHs included in consecutive SSBs. The first scrambling process increases the data size as part of the scrambling operations, and omitting the time-varying bits from being scrambled prevents a single bit difference between two PBCH payloads from being multiplied into multiple bit differences by the first scrambling process. In low signal coverage situations, a UE may perform a soft combining process on multiple PBCHs to improve decoding performance. A design principle of the soft combining process is to skip the scrambling of the bits of the SFN that change during the time period in which the soft combining is performed. According to current wireless communication specification(s), the bits of the SFN for which the scrambling is skipped are based on a particular predetermined SSB periodicity, and these SFN bits are located in the PBCH payload portion that excludes the MIB. For some types of wireless networks for which power conservation is an important goal, such as satellite networks, increasing the SSB periodicity is one possible manner of reducing power consumption. However, increasing the SSB periodicity increases the amount of time, as tracked by the SFN, between PBCH payloads that are contained within the SSBs, and as such, additional bits of the SFN vary between consecutive PBCH payloads. Because these additional time-varying bits undergo the first scrambling process, each additional bit of the SFN that varies results in multiple bit differences between the PBCH payloads received by the UE due to the first scrambling process. Increasing the number of bit differences between consecutive PBCH payloads can present challenges to the soft combining process at the UE, such as significantly decreasing the decoding performance or significantly increasing the latency and power consumption associated with the soft combining process. Additionally, increasing the SSB periodicity can significantly increase the initial cell selection delay.

### SUMMARY

The following summarizes some aspects of the present disclosure to provide a basic understanding of the discussed technology. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in summary form as a prelude to the more detailed description that is presented later.

Some aspects described herein relate to a user equipment (UE) for wireless communication. The UE includes a processing system that includes one or more processors and one or more memories coupled with the one or more processors. The processing system is configured to cause the UE to receive, from a network node, a plurality of synchronization signal blocks (SSBs) in accordance with an SSB periodicity. The plurality of SSBs respectively includes a plurality of physical broadcast channels (PBCHs). The plurality of PBCHs respectively includes a plurality of master information blocks (MIBs) in accordance with a MIB periodicity. Each PBCH of the plurality of PBCHs includes a scrambled portion and an unscrambled portion. The unscrambled portion includes timing information in accordance with the SSB periodicity and the MIB periodicity, cell access information, or both. The processing system is also configured to cause the UE to decode the plurality of PBCHs by soft combining the PBCHs in accordance with the timing information, the cell access information, or both.

Some aspects described herein relate to a method of wireless communication performed by a UE. The method includes receiving, from a network node, a plurality of SSBs in accordance with an SSB periodicity. The plurality of SSBs respectively includes a plurality of PBCHs. The plurality of PBCHs respectively includes a plurality of MIBs in accordance with a MIB periodicity. Each PBCH of the plurality of PBCHs includes a scrambled portion and an unscrambled portion. The unscrambled portion includes timing information in accordance with the SSB periodicity and the MIB periodicity, cell access information, or both. The method also includes decoding the plurality of PBCHs by soft combining the PBCHs in accordance with the timing information, the cell access information, or both.

Some aspects described herein relate to an apparatus. The apparatus includes means for receiving, from a network node, a plurality of SSBs in accordance with an SSB periodicity. The plurality of SSBs respectively includes a plurality of PBCHs. The plurality of PBCHs respectively includes a plurality of MIBs in accordance with a MIB periodicity. Each PBCH of the plurality of PBCHs includes a scrambled portion and an unscrambled portion. The unscrambled portion includes timing information in accordance with the SSB periodicity and the MIB periodicity, cell access information, or both. The apparatus also includes means for decoding the plurality of PBCHs by soft combining the PBCHs in accordance with the timing information, the cell access information, or both.

Some aspects described herein relate to a non-transitory computer-readable medium that stores instructions that, when executed by one or more processors, cause the one or more processors to perform operations. The operations include receiving, from a network node, a plurality of SSBs in accordance with an SSB periodicity. The plurality of SSBs respectively includes a plurality of PBCHs. The plurality of PBCHs respectively includes a plurality of MIBs in accordance with a MIB periodicity. Each PBCH of the plurality of PBCHs includes a scrambled portion and an unscrambled portion. The unscrambled portion includes timing information in accordance with the SSB periodicity and the MIB periodicity, cell access information, or both. The operations also include decoding the plurality of PBCHs by soft combining the PBCHs in accordance with the timing information, the cell access information, or both.

Some aspects described herein relate to a network node for wireless communication. The network node includes a processing system that includes one or more processors and one or more memories coupled with the one or more processors. The processing system is configured to cause the network node to generate a plurality of PBCHs. The plurality of PBCHs respectively include a plurality of MIBs in accordance with a MIB periodicity. Each PBCH of the plurality of PBCHs includes a scrambled portion and an unscrambled portion. The unscrambled portion includes timing information in accordance with an SSB periodicity and the MIB periodicity, cell access information, or both. The processing system is also configured to cause the network node to transmit, to a UE and in accordance with the SSB periodicity, a plurality of SSBs that respectively include the plurality of PBCH.

Some aspects described herein relate to a method of wireless communication performed by a network node. The method includes generating a plurality of PBCHs. The plurality of PBCHs respectively include a plurality of MIBs in accordance with a MIB periodicity. Each PBCH of the plurality of PBCHs includes a scrambled portion and an unscrambled portion. The unscrambled portion includes timing information in accordance with an SSB periodicity and the MIB periodicity, cell access information, or both. The method also includes transmitting, to a UE and in accordance with the SSB periodicity, a plurality of SSBs that respectively include the plurality of PBCH.

Some aspects described herein relate to an apparatus. The apparatus includes means for generating a plurality of PBCHs. The plurality of PBCHs respectively include a plurality of MIBs in accordance with a MIB periodicity. Each PBCH of the plurality of PBCHs includes a scrambled portion and an unscrambled portion. The unscrambled portion includes timing information in accordance with an SSB periodicity and the MIB periodicity, cell access information, or both. The apparatus also includes means for transmitting, to a UE and in accordance with the SSB periodicity, a plurality of SSBs that respectively include the plurality of PBCH.

Some aspects described herein relate to a non-transitory computer-readable medium that stores instructions that, when executed by one or more processors, cause the one or more processors to perform operations. The operations include generating a plurality of PBCHs. The plurality of PBCHs respectively include a plurality of MIBs in accordance with a MIB periodicity. Each PBCH of the plurality of PBCHs includes a scrambled portion and an unscrambled portion. The unscrambled portion includes timing information in accordance with an SSB periodicity and the MIB periodicity, cell access information, or both. The operations also include transmitting, to a UE and in accordance with the SSB periodicity, a plurality of SSBs that respectively include the plurality of PBCH.

Some aspects described herein relate to a UE for wireless communication. The UE includes a processing system that includes one or more processors and one or more memories coupled with the one or more processors. The processing system is configured to cause the UE to receive, from a network node, a plurality of SSBs in accordance with an SSB periodicity. The plurality of SSBs respectively includes a plurality of PBCHs. The plurality of PBCHs respectively includes a plurality of MIBs in accordance with a MIB periodicity. The processing system is also configured to cause the UE to decode the plurality of PBCHs by soft combining the plurality of PBCHs to generate a plurality of scrambled PBCH payloads. The processing system is also configured to cause the UE to, for each scrambled PBCH payload of the plurality of PBCH payloads, identify a set of unscrambled bits of the scrambled PBCH payload in accordance with the SSB periodicity and the MIB periodicity, and descramble the scrambled PBCH payload in accordance with a portion of a scrambling sequence that is associated with the set of unscrambled bits.

Some aspects described herein relate to a method of wireless communication performed by a UE. The method includes receiving, from a network node, a plurality of SSBs in accordance with an SSB periodicity. The plurality of SSBs respectively includes a plurality of PBCHs. The plurality of PBCHs respectively includes a plurality of MIBs in accordance with a MIB periodicity. The method also includes decoding the plurality of PBCHs by soft combining the plurality of PBCHs to generate a plurality of scrambled PBCH payloads. The method also includes, for each scrambled PBCH payload of the plurality of scrambled PBCH payloads, identifying a set of unscrambled bits of the scrambled PBCH payload in accordance with the SSB periodicity and the MIB periodicity, and descrambling the scrambled PBCH payload in accordance with a portion of a scrambling sequence that is associated with the set of unscrambled bits.

Some aspects described herein relate to an apparatus. The apparatus includes means for receiving, from a network node, a plurality of SSBs in accordance with an SSB periodicity. The plurality of SSBs respectively includes a plurality of PBCHs. The plurality of PBCHs respectively includes a plurality of MIBs in accordance with a MIB periodicity. The apparatus also includes means for decoding the plurality of PBCHs by soft combining the plurality of PBCHs to generate a plurality of scrambled PBCH payloads. The apparatus includes means for identifying, for each scrambled PBCH payload of the plurality of scrambled PBCH payloads, a set of unscrambled bits of the scrambled PBCH payload in accordance with the SSB periodicity and the MIB periodicity. The apparatus also includes means for descrambling, for each scrambled PBCH payload of the plurality of scrambled PBCH payloads, the scrambled PBCH payload in accordance with a portion of a scrambling sequence that is associated with the set of unscrambled bits.

Some aspects described herein relate to a non-transitory computer-readable medium that stores instructions that, when executed by one or more processors, cause the one or more processors to perform operations. The operations include receiving, from a network node, a plurality of SSBs in accordance with an SSB periodicity. The plurality of SSBs respectively includes a plurality of PBCHs. The plurality of PBCHs respectively includes a plurality of MIBs in accordance with a MIB periodicity. The operations also include decoding the plurality of PBCHs by soft combining the plurality of PBCHs to generate a plurality of scrambled PBCH payloads. The operations also include, for each scrambled PBCH payload of the plurality of scrambled PBCH payloads, identifying a set of unscrambled bits of the scrambled PBCH payload in accordance with the SSB periodicity and the MIB periodicity, and descrambling the scrambled PBCH payload in accordance with a portion of a scrambling sequence that is associated with the set of unscrambled bits.

Some aspects described herein relate to a network node for wireless communication. The network node includes a processing system that includes one or more processors and one or more memories coupled with the one or more processors. The processing system is configured to cause the network node to generate a plurality of PBCH payloads. The plurality of PBCH payloads respectively include a plurality of MIBs in accordance with a MIB periodicity. The processing system is also configured to cause the network node to, for each PBCH payload of the plurality of PBCH payloads, identify a set of unscrambled bits of the PBCH payload in accordance with a SSB periodicity and the MIB periodicity, scramble the PBCH payload in accordance with a portion of a scrambling sequence that is associated with the set of unscrambled bits, and perform channel coding on the scrambled PBCH payload to generate a respective PBCH of a plurality of PBCHs. The processing system is also configured to cause the network node to transmit, to a UE and in accordance with the SSB periodicity, a plurality of SSBs that respectively include the plurality of PBCHs.

Some aspects described herein relate to a method of wireless communication performed by a network node. The method includes generating a plurality of PBCH payloads. The plurality of PBCH payloads respectively include a plurality of MIBs in accordance with a MIB periodicity. The method also includes, for each PBCH payload of the plurality of PBCH payloads, identifying a set of unscrambled bits of the PBCH payload in accordance with a SSB periodicity and the MIB periodicity, scrambling the PBCH payload in accordance with a portion of a scrambling sequence that is associated with the set of unscrambled bits, and performing channel coding on the scrambled PBCH payload to generate a respective PBCH of a plurality of PBCHs. The method also includes transmitting, to a UE and in accordance with the SSB periodicity, a plurality of SSBs that respectively include the plurality of PBCHs.

Some aspects described herein relate to an apparatus. The apparatus includes means for generating a plurality of PBCH payloads. The plurality of PBCH payloads respectively include a plurality of MIBs in accordance with a MIB periodicity. The apparatus also includes means for identifying, for each PBCH payload of the plurality of PBCH payloads, a set of unscrambled bits of the PBCH payload in accordance with a SSB periodicity and the MIB periodicity. The apparatus includes means for scrambling, for each PBCH payload of the plurality of PBCH payloads, the PBCH payload in accordance with a portion of a scrambling sequence that is associated with the set of unscrambled bits. The apparatus also includes means for performing, for each PBCH payload of the plurality of PBCH payloads, channel coding on the scrambled PBCH payload to generate a respective PBCH of a plurality of PBCHs. The apparatus also includes means for transmitting, to a UE and in accordance with the SSB periodicity, a plurality of SSBs that respectively include the plurality of PBCHs.

Some aspects described herein relate to a non-transitory computer-readable medium that stores instructions that, when executed by one or more processors, cause the one or more processors to perform operations. The operations include generating a plurality of PBCH payloads. The plurality of PBCH payloads respectively include a plurality of MIBs in accordance with a MIB periodicity. The operations also include, for each PBCH payload of the plurality of PBCH payloads, identifying a set of unscrambled bits of the PBCH payload in accordance with a SSB periodicity and the MIB periodicity, scrambling the PBCH payload in accordance with a portion of a scrambling sequence that is associated with the set of unscrambled bits, and performing channel coding on the scrambled PBCH payload to generate a respective PBCH of a plurality of PBCHs. The operations also include transmitting, to a UE and in accordance with the SSB periodicity, a plurality of SSBs that respectively include the plurality of PBCHs.

Aspects of the present disclosure may generally be implemented by or as a method, apparatus, system, computer program product, non-transitory computer-readable medium, user equipment, base station, network node, network entity, wireless communication device, and/or processing system as substantially described with reference to, and as illustrated by, the specification and accompanying drawings.

Other aspects, features, and implementations of the present disclosure will become apparent to a person having ordinary skill in the art, upon reviewing the following description of specific, example implementations of the present disclosure in conjunction with the accompanying figures. While features of the present disclosure may be described relative to particular implementations and figures below, all implementations of the present disclosure can include one or more of the advantageous features described herein. In other words, while one or more implementations may be described as having particular advantageous features, one or more of such features may also be used in accordance with the various implementations of the disclosure described herein. In similar fashion, while example implementations may be described below as device, system, or method implementations, such example implementations can be implemented in various devices, systems, methods, and computer-readable media.

### BRIEF DESCRIPTION OF THE DRAWINGS

A further understanding of the nature and advantages of the present disclosure may be realized by reference to the following drawings. In the appended figures, similar components or features may have the same reference label and designations. Further, various components of the same type may be distinguished by following the reference label by a dash and a second label that distinguishes among the similar components, or by following the reference label with a letter. If just the first reference label is used in the specification, the description is applicable to any one of the similar components having the same first reference label irrespective of the second reference label or letter.

FIG. 1 is a block diagram illustrating details of an example wireless communication network in accordance with the present disclosure.

FIG. 2 is a block diagram illustrating examples of a network node and a user equipment (UE) in accordance with the present disclosure.

FIG. 3 is a block diagram illustrating an example disaggregated base station architecture in accordance with the present disclosure.

FIG. 4 is a block diagram illustrating an example of a wireless communication system that supports physical broadcast channel (PBCH) scrambling and soft combining in accordance with the present disclosure.

FIGS. 5A-5C are block diagrams illustrating examples of a network node providing information associated with a different wireless network to a UE in accordance with the present disclosure.

FIG. 6 is a diagram illustrating an example of PBCH scrambling in accordance with the present disclosure.

FIGS. 7A-7C are timing diagrams illustrating examples of PBCH scrambling and timing in accordance with the present disclosure.

FIG. 8 is a flow diagram illustrating an example process that supports PBCH scrambling soft combining in accordance with the present disclosure.

FIG. 9 is a flow diagram illustrating an example process that supports PBCH scrambling soft combining in accordance with the present disclosure.

FIG. 10 is a block diagram of an example UE that supports PBCH scrambling and soft combining in accordance with the present disclosure.

FIG. 11 is a flow diagram illustrating an example process that supports PBCH scrambling and soft combining in accordance with the present disclosure.

FIG. 12 is a flow diagram illustrating an example process that supports PBCH scrambling soft combining in accordance with the present disclosure.

FIG. 13 is a block diagram of an example network node that supports PBCH scrambling and soft combining in accordance with the present disclosure.

### DETAILED DESCRIPTION

Various aspects of the disclosure are described more fully hereinafter with reference to the accompanying drawings. This disclosure may, however, be embodied in many different forms and is not to be construed as limited to any specific structure or function presented throughout this disclosure. Rather, these aspects are provided so that this disclosure will be thorough and complete, and will fully convey the scope of the disclosure to those skilled in the art. Based on the teachings herein, one skilled in the art may appreciate that the scope of the disclosure is intended to cover any aspect of the disclosure disclosed herein, whether implemented independently of or combined with any other aspect of the disclosure. For example, an apparatus may be implemented or a method may be practiced using any quantity of the aspects set forth herein. In addition, the scope of the disclosure is intended to cover such an apparatus or method which is practiced using other structure, functionality, or structure and functionality in addition to or other than the various aspects of the disclosure set forth herein. Any aspect of the disclosure disclosed herein may be embodied by one or more elements of a claim.

Several aspects of telecommunication systems will now be presented with reference to various apparatuses and techniques. These apparatuses and techniques will be described in the following detailed description and illustrated in the accompanying drawings by various blocks, modules, components, circuits, steps, processes, or algorithms (collectively referred to as “elements”). These elements may be implemented using hardware, software, or a combination of hardware and software. Whether such elements are implemented as hardware or software depends upon the particular application and design constraints imposed on the overall system.

The present disclosure provides systems, apparatus, methods, and computer-readable media that support physical broadcast channel (PBCH) scrambling and soft combining for wireless communication systems. The PBCH scrambling and soft combining described herein enable a wireless network to support a larger synchronization signal block (SSB) periodicity than other wireless network(s). Some aspects more specifically relate to a network node generating multiple PBCHs that respectively include multiple master information blocks (MIBs) in accordance with an MIB periodicity, such as an MIB periodicity that is specified in a wireless communications standard. For example, the network node may perform a scrambling process on a PBCH payload to generate a scrambled portion and an unscrambled portion. In this example, the network node omits application of the scrambling sequence to one or more bits of the PBCH payload, and these unscrambled bits are the unscrambled portion of the PBCH payload after performance of the scrambling process. The PBCH payload includes timing information such as a system frame number (SFN) as well as additional information prior to performance of the scrambling process, and the network node may leave a few bits of the SFN unscrambled during this first scrambling process. After performing the scrambling process on the PBCH payload, the network node may perform channel coding on the resultant payload to generate one of the multiple PBCHs. The network node performs similar operations on the other PBCH payloads to generate the remaining PBCHs, and the network node transmits the PBCHs within respective SSBs of multiple SSBs.

Unlike in typical wireless networks in which the unscrambled portion of a PBCH is preconfigured to be the second least significant bit (LSB) of the SFN and the third LSB of the SFN for each cell and regardless of the type of wireless network that is supported, the network node of the present disclosure selects bits of the SFN to be included in the unscrambled portion in accordance with an SSB periodicity and the MIB periodicity. Stated another way, the network node can identify the SSB periodicity and the MIB periodicity being supported and select which bits of the SFN to omit from performance of the scrambling process in accordance with the identified SSB periodicity and the identified MIB periodicity. Accordingly, the network node may select bits of the SFN other than the conventionally selected second LSB and third LSB in order to support a different SSB periodicity as compared to other cells or other types of wireless networks. As an example, if the SSB periodicity is once per 40 milliseconds (ms) and the MIB periodicity is once per 80 ms, the unscrambled portion may include the third LSB of the SFN and the fourth LSB of the SFN because these two bits may vary in consecutive PBCHs. In this example, because the SFN is incremented once per 10 ms and MIBs are transmitted within PBCHs included in SSBs once per 40 ms in accordance with the SSB periodicity, the SFN is incremented four times between each PBCH payload transmission, resulting in the third LSB and the fourth LSB changing in the consecutive MIBs according to the following repeating pattern: 00-01-10-11. In some implementations, the unscrambled portion further, or alternatively, includes cell access information of the PBCH, such as a cell barred bit, an intra-frequency reselection bit, or both.

Additionally, the scrambling sequence that is used to perform the first scrambling process may be selected in accordance with the unscrambled portion. For example, a value used to scramble one or more bits of a respective PBCH payload may be selected from one of multiple candidate values in accordance with the values of the unscrambled bits of the timing information, such as the third LSB, the fourth LSB, the fifth LSB, or other LSBs of the SFN. In this example, to scramble a PBCH payload, the network node may initialize or select a portion of a scrambling sequence in accordance with the values of bits that are to remain unscrambled after performance of the scrambling process, and the network node may apply the initialized or selected portion of the scrambling sequence to the other bits of the PBCH payload to generate the scrambled portion. Additionally, or alternatively, the network node may determine an initialization time to initialize or reinitialize the scrambling sequence, such as one or more SFN values, in accordance with the SSB periodicity instead of at particular fixed SFNs as in other wireless networks.

A user equipment (UE) that receives the SSBs from the network node may decode the respective PBCHs by soft combining the PBCHs in accordance with the respective unscrambled portions. For example, the UE may perform the soft combining in accordance with the timing information, the cell access information, or both, of respective PBCH payloads. In some aspects, for each decoded PBCH payload, the UE may identify the unscrambled portion, such as one or more bits that the network node omitted from performance of the scrambling process, and the UE may descramble the scrambled PBCH payloads in accordance with a scrambling sequence that is selected in accordance with the set of unscrambled bits. Additionally, or alternatively, the UE may identify the initialization time associated with the scrambling sequence, such that the UE is able to detect when a scrambling sequence may be reinitialized or change. Unlike in other wireless communication systems, in which a UE identifies the initialization time of a scrambling sequence associated with a PBCH at particular fixed SFNs, the UE of the present disclosure may identify the SFNs associated with initialization or change of the scrambling sequence in accordance with the SSB periodicity.

The present disclosure also provides techniques for enabling a first wireless network to advertise initial cell selection parameters, such as an SSB periodicity, for a nearby second wireless network. Some aspects more specifically relate to a network node of a terrestrial network (TN) providing, to a UE, an indicator of initial cell selection information associated with a non-terrestrial network (NTN), such as a satellite-based network, within or nearby the coverage area of the TN. In some implementations, the UE receives, from a first network node of the first wireless network, an indicator of coverage information associated with the second wireless network. The coverage information may include an SSB periodicity associated with the second wireless network, beam timing information associated with the second wireless network, one or more beam centers associated with the second wireless network, one or more beam diameters associated with the second wireless network, or a combination thereof. In some additional, or alternative, implementations, the UE receives, from the first network node, an indicator of frequency information associated with the second wireless network. The frequency information may include a raster frequency associated with the second wireless network, a subcarrier spacing (SCS) value associated with the second wireless network, or a combination thereof. The UE may perform an initial connection procedure with the second wireless network in accordance with the coverage information, the frequency information, or both, and the initial connection procedure may include the above-described soft combining of multiple PBCHs.

Particular implementations of the subject matter described in this disclosure can be implemented to realize one or more of the following potential advantages. In some aspects, the present disclosure provides techniques for supporting larger SSB periodicities. For example, in contrast to typical wireless networks in which the SSB periodicity for initial cell selection is set at a fixed value of once per 20 ms such that SSBs, and accordingly the PBCHs and the MIBs contained respectively within, are communicated once every 20 ms, wireless communication systems of the present disclosure can support larger SSB periodicities, such as once per 40 ms, once per 80 ms, or once per 160 ms. Larger SSB periodicities are associated with less frequent SSB transmissions by network nodes and reduced power consumption at network nodes, which can be particularly beneficial to some types of wireless networks such as NTNs that do not have access to fixed power supplies.

Additionally, because the unscrambled portions of PBCH payloads are selected or determined in accordance with the SSB periodicity and the MIB periodicity, instead of being fixed in accordance with a single fixed SSB periodicity and a single fixed MIB periodicity, these larger SSB periodicities can be supported without increasing the difficulty of the soft combining process at the UE. Instead of one or more bits of the scrambled portion of the PBCH payloads changing with respect to consecutive SSBs or a sequence of SSBs due to use of a larger SSB periodicity, the portions of the PBCH payloads to be scrambled, and not to be scrambled, can be selected in accordance with the SSB periodicity. In this manner, time-varying bits, or bits of PBCH payloads that have different values across consecutive PBCH payloads or a sequence of PBCH payloads (included in respective SSBs), are not scrambled and such bits may be identified at the UE during the soft combining process. Additionally, one or more unscrambled bits, the SSB periodicity, or both may be used to initialize a scrambling sequence and select a portion of the scrambling sequence to be applied to respective PBCH payloads. Applying the scrambling sequence to the PBCH payloads increase the randomness of the channel encoding output and thus reduces interference to one or more other wireless devices, such as one or more UEs in a neighboring cell. Additionally, aspects of decoding a single PBCH, including selection of the scrambling sequence and identification of the initialization time associated with a scrambling sequence, can be determined by the UE in accordance with the unscrambled bits and/or the SSB periodicity, thereby enabling the UE to correctly decode and descramble PBCHs that are included in SSBs transmitted according to SSB periodicities other than the single fixed SSB periodicity supported by other wireless networks.

Additionally, or alternatively, some implementations described herein enable a first wireless network, such as a TN, to advertise initial cell selection parameters of a second wireless network, such as an NTN, in a manner that shortens initial cell selection delay for the second wireless network. For example, a network node of the first wireless network may provide a UE with an indicator, such as in a system information block (SIB), a medium access control (MAC) control element (MAC-CE), or a radio resource control (RRC) message, of coverage and/or frequency information associated with the second wireless network. Accordingly, a UE that leaves the coverage area of a TN may search for an NTN cell faster, and thereby consume less power, even though the NTN may support a different SSB periodicity, different beams, different raster frequencies, or the like.

This disclosure relates generally to providing or participating in authorized shared access between two or more wireless communications systems, also referred to as wireless communications networks. In various implementations, the techniques and apparatus may be used for wireless communication networks such as code division multiple access (CDMA) networks, time division multiple access (TDMA) networks, frequency division multiple access (FDMA) networks, orthogonal FDMA (OFDMA) networks, single-carrier FDMA (SC-FDMA) networks, long term evolution (LTE) networks, Global System for Mobile Communications (GSM) networks, 5th Generation (5G) or new radio (NR) networks (sometimes referred to as “5G NR” networks, systems, or devices), as well as other communications networks. As described herein, the terms “networks” and “systems” may be used interchangeably.

Multiple-access radio access technologies (RATs) have been adopted in various telecommunication standards to provide common protocols that enable wireless communication devices to communicate on a municipal, enterprise, national, regional, or global level. For example, 5G New Radio (NR) is part of a continuous mobile broadband evolution promulgated by the Third Generation Partnership Project (3GPP). 5G NR supports various technologies and use cases including enhanced mobile broadband (eMBB), ultra-reliable low-latency communication (URLLC), massive machine-type communication (mMTC), millimeter wave (mmWave) technology, beamforming, network slicing, edge computing, Internet of Things (IoT) connectivity and management, and network function virtualization (NFV). 5G NR networks contemplate diverse deployments, diverse spectrum, and diverse services and devices that may be implemented using an OFDM-based unified, air interface.

5G NR devices, networks, and systems may be implemented to use optimized OFDM-based waveform features. These features may include scalable numerology and transmission time intervals (TTIs); a common, flexible framework to efficiently multiplex services and features with a dynamic, low-latency time division duplex (TDD) or frequency division duplex (FDD) design; and advanced wireless technologies, such as massive multiple input, multiple output (MIMO), robust mmWave transmissions, advanced channel coding, and device-centric mobility. Scalability of the numerology in 5G NR, with scaling of subcarrier spacing, may efficiently address operating diverse services across diverse spectrum and diverse deployments. For example, in various outdoor and macro coverage deployments of less than 3 gigahertz (GHz) FDD or TDD implementations, subcarrier spacing may occur with 15 kilohertz (kHz), for example over 1, 5, 10, 20 megahertz (MHz), and the like bandwidth. For other various outdoor and small cell coverage deployments of TDD greater than 3 GHz, subcarrier spacing may occur with 30 kHz over 80 or 100 MHz bandwidth. For other various indoor wideband implementations, using a TDD over the unlicensed portion of the 5 GHz band, the subcarrier spacing may occur with 60 kHz over a 160 MHz bandwidth. Finally, for various deployments transmitting with mmWave components at a TDD of 28 GHz, subcarrier spacing may occur with 120 kHz over a 500 MHz bandwidth.

The scalable numerology of 5G NR facilitates scalable TTI for diverse latency and quality of service (QoS) requirements. For example, shorter TTI may be used for low latency and high reliability, while longer TTI may be used for higher spectral efficiency. The efficient multiplexing of long and short TTIs allow transmissions to start on symbol boundaries. 5G NR also contemplates a self-contained integrated subframe design with uplink or downlink scheduling information, data, and acknowledgement in the same subframe. The self-contained integrated subframe supports communications in unlicensed or contention-based shared spectrum, adaptive uplink or downlink that may be flexibly configured on a per-cell basis to dynamically switch between uplink and downlink to meet the current traffic needs.

As the demand for broadband access increases and as technologies supported by wireless communication networks evolve, further technological improvements may be adopted in or implemented for 5G NR or future RATs, such as 6G, to further advance the evolution of wireless communication for a wide variety of existing and new use cases and applications. Such technological improvements may be associated with new frequency band expansion, licensed and unlicensed spectrum access, overlapping spectrum use, small cell deployments, non-terrestrial network (NTN) deployments, disaggregated network architectures and network topology expansion, device aggregation, advanced duplex communication, sidelink and other device-to-device direct communication, IoT (including passive or ambient IoT) networks, reduced capability (RedCap) UE functionality, industrial connectivity, multiple-subscriber implementations, high-precision positioning, radio frequency (RF) sensing, and/or artificial intelligence or machine learning (AI/ML), among other examples. These technological improvements may support use cases such as wireless backhauls, wireless data centers, extended reality (XR) and metaverse applications, meta services for supporting vehicle connectivity, holographic and mixed reality communication, autonomous and collaborative robots, vehicle platooning and cooperative maneuvering, sensing networks, gesture monitoring, human-brain interfacing, digital twin applications, asset management, and universal coverage applications using non-terrestrial and/or aerial platforms, among other examples. The methods, operations, apparatuses, and techniques described herein may enable one or more of the foregoing technologies and/or support one or more of the foregoing use cases. For clarity, certain aspects of the present disclosure may be described below with reference to example 5G NR implementations or in a 5G-centric way, and 5G terminology may be used as illustrative examples in portions of the description below; however, the description is not intended to be limited to 5G applications.

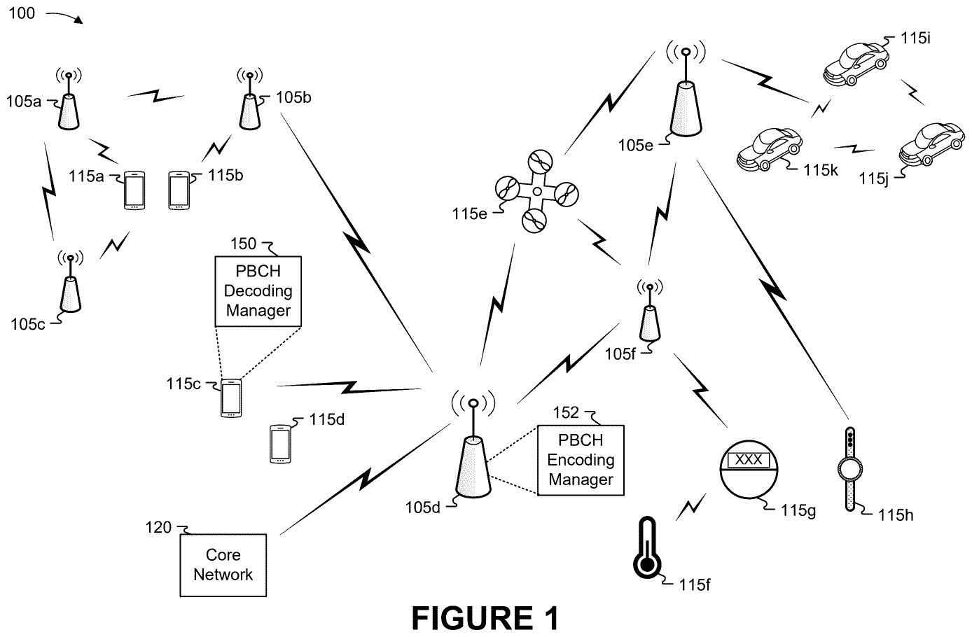

FIG. 1 is a block diagram illustrating details of an example wireless communication network 100 in accordance with the present disclosure. The wireless communication network 100 may, for example, be or include elements of a 5G (or NR) network or a 6G network, among other examples. As appreciated by those skilled in the art, components appearing in FIG. 1 are likely to have related counterparts in other network arrangements including, for example, cellular-style network arrangements and non-cellular-style-network arrangements, such as device-to-device, peer-to-peer, or ad hoc network arrangements, among other examples.

The wireless communication network 100 illustrated in FIG. 1 includes multiple network nodes 105, also referred to as network entities, and multiple user equipments (UEs) 115. A network node may be a station that communicates with UEs and may be referred to as a base station, an evolved node B (eNB), a next generation eNB (gNB), an access point, and the like. Each network node 105 may provide communication coverage for a particular geographic area. In 3GPP, the term “cell” can refer to this particular geographic coverage area of a network node or a network node subsystem serving the coverage area, depending on the context in which the term is used. In implementations of the wireless communication network 100 herein, the network nodes 105 may be associated with a same operator or different operators, such as the wireless communication network 100 may include a plurality of operator wireless networks. In some examples, an individual network node 105 or UE 115 may be operated by more than one network operating entity. In some other examples, each network node 105 and UE 115 may be operated by a single network operating entity.

The network nodes 105 and the UEs 115 of the wireless communication network 100 may communicate using the electromagnetic spectrum, which may be subdivided by frequency or wavelength into various classes, bands, carriers, and/or channels. For example, devices of the wireless communication network 100 may communicate using one or more operating bands. In some aspects, multiple wireless communication networks 100 may be deployed in a given geographic area. Each wireless communication network 100 may support a particular RAT (which may also be referred to as an air interface) and may operate on one or more carrier frequencies in one or more frequency ranges. Examples of RATs include a 4G RAT, a 5G/NR RAT, and/or a 6G RAT, among other examples. In some examples, when multiple RATs are deployed in a given geographic area, each RAT in the geographic area may operate on different frequencies to avoid interference with one another.

Various operating bands have been defined as frequency range designations FR1 (410 MHz through 7.125 GHz), FR2 (24.25 GHz through 52.6 GHz), FR3 (7.125 GHz through 24.25 GHz), FR4a or FR4-1 (52.6 GHz through 71 GHz), FR4 (52.6 GHz through 114.25 GHz), and FR5 (114.25 GHz through 300 GHz). Although a portion of FR1 is greater than 6 GHz, FR1 is often referred to (interchangeably) as a “Sub-6 GHz” band in some documents and articles. Similarly, FR2 is often referred to (interchangeably) as a “millimeter wave” band in some documents and articles, despite being different than the extremely high frequency (EHF) band (30 GHz through 300 GHz), which is identified by the International Telecommunications Union (ITU) as a “millimeter wave” band. The frequencies between FR1 and FR2 are often referred to as mid-band frequencies, which include FR3. Frequency bands falling within FR3 may inherit FR1 characteristics or FR2 characteristics, and thus may effectively extend features of FR1 or FR2 into mid-band frequencies. Thus, “sub-6 GHz,” if used herein, may broadly refer to frequencies that are less than 6 GHz, that are within FR1, and/or that are included in mid-band frequencies. Similarly, the term “millimeter wave,” if used herein, may broadly refer to frequencies that are included in mid-band frequencies, that are within FR2, FR4, FR4-a or FR4-1, or FR5, and/or that are within the EHF band. Higher frequency bands may extend 5G NR operation, 6G operation, and/or other RATs beyond 52.6 GHz. For example, each of FR4a, FR4-1, FR4, and FR5 falls within the EHF band. In some examples, the wireless communication network 100 may implement dynamic spectrum sharing (DSS), in which multiple RATs (for example, 4G/LTE and 5G/NR) are implemented with dynamic bandwidth allocation (for example, in accordance with user demand) in a single frequency band. It is contemplated that the frequencies included in these operating bands (for example, FR1, FR2, FR3, FR4, FR4-a, FR4-1, and/or FR5) may be modified, and techniques described herein may be applicable to those modified frequency ranges.

A network node 105 may include one or more devices, components, or systems that enable communication between a UE 115 and one or more devices, components, or systems of the wireless communication network 100. A network node 105 may be, may include, or may also be referred to as an NR network node, a 5G network node, a 6G network node, a Node B, an eNB, a gNB, an access point (AP), a transmission reception point (TRP), a mobility element, a core, a network entity, a network element, a network equipment, and/or another type of device, component, or system included in a radio access network (RAN).

A network node 105 may be implemented as a single physical node (for example, a single physical structure) or may be implemented as two or more physical nodes (for example, two or more distinct physical structures). For example, a network node 105 may be a device or system that implements part of a radio protocol stack, a device or system that implements a full radio protocol stack (such as a full gNB protocol stack), or a collection of devices or systems that collectively implement the full radio protocol stack. For example, and as shown, a network node 105 may be an aggregated network node (having an aggregated architecture), meaning that the network node 105 may implement a full radio protocol stack that is physically and logically integrated within a single node (for example, a single physical structure) in the wireless communication network 100. For example, an aggregated network node 105 may consist of a single standalone base station or a single TRP that uses a full radio protocol stack to enable or facilitate communication between a UE 115 and a core network 120 of the wireless communication network 100.

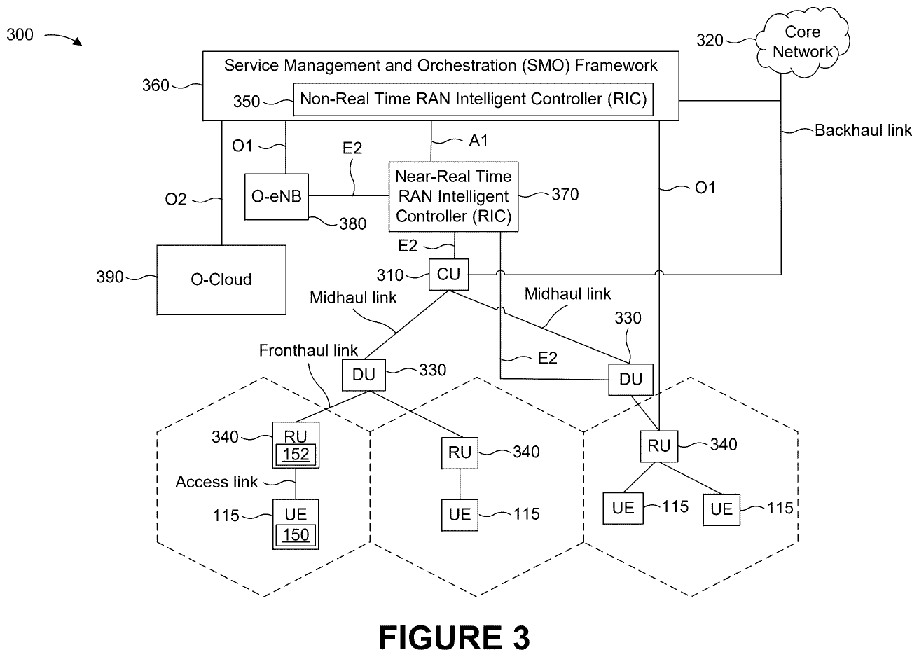

Alternatively, a network node 105 may be a disaggregated network node (sometimes referred to as a disaggregated base station), meaning that the network node 105 may implement a radio protocol stack that is physically distributed and/or logically distributed among two or more nodes in the same geographic location or in different geographic locations. For example, a disaggregated network node may have a disaggregated architecture, as further described herein with reference to FIG. 3. In some deployments, disaggregated network nodes 105 may be used in an integrated access and backhaul (IAB) network, in an open radio access network (O-RAN) (such as a network configuration in compliance with the O-RAN Alliance), or in a virtualized radio access network (vRAN), also known as a cloud radio access network (C-RAN), to facilitate scaling by separating base station functionality into multiple units that can be individually deployed.

The network nodes 105 of the wireless communication network 100 may include one or more central units (CUs), one or more distributed units (DUs), and/or one or more radio units (RUs). A CU may host one or more higher layer control functions, such as radio resource control (RRC) functions, packet data convergence protocol (PDCP) functions, and/or service data adaptation protocol (SDAP) functions, among other examples. A DU may host one or more of a radio link control (RLC) layer, a medium access control (MAC) layer, and/or one or more higher physical (PHY) layers depending, at least in part, on a functional split, such as a functional split defined by the 3GPP. In some examples, a DU also may host one or more lower PHY layer functions, such as a fast Fourier transform (FFT), an inverse FFT (iFFT), beamforming, physical random access channel (PRACH) extraction and filtering, and/or scheduling of resources for one or more UEs 115, among other examples. An RU may host RF processing functions or lower PHY layer functions, such as an FFT, an iFFT, beamforming, or PRACH extraction and filtering, among other examples, according to a functional split, such as a lower layer functional split. In such an architecture, each RU can be operated to handle over the air (OTA) communication with one or more UEs 115.

In some aspects, a single network node 105 may include a combination of one or more CUs, one or more DUs, and/or one or more RUs. Additionally, or alternatively, a network node 105 may include one or more Near-Real Time (Near-RT) RAN Intelligent Controllers (RICs) and/or one or more Non-Real Time (Non-RT) RICs. In some examples, a CU, a DU, and/or an RU may be implemented as a virtual unit, such as a virtual central unit (VCU), a virtual distributed unit (VDU), or a virtual radio unit (VRU), among other examples. A virtual unit may be implemented as a virtual network function, such as associated with a cloud deployment.

Some network nodes 105 (for example, a base station, an RU, or a TRP) may provide communication coverage for a particular geographic area. In the 3GPP, the term “cell” can refer to a coverage area of a network node 105 or to a network node 105 itself, depending on the context in which the term is used. A network node 105 may support one or multiple (for example, three) cells. In some examples, a network node 105 may provide communication coverage for a macro cell, a pico cell, a femto cell, or another type of cell. A macro cell may cover a relatively large geographic area (for example, several kilometers in radius) and may allow unrestricted access by UEs 115 with service subscriptions. A pico cell may cover a relatively small geographic area and may allow unrestricted access by UEs 115 with service subscriptions. A femto cell may cover a relatively small geographic area (for example, a home) and may allow restricted access by UEs 115 having association with the femto cell (for example, UEs 115 in a closed subscriber group (CSG)). A network node 105 for a macro cell may be referred to as a macro network node. A network node 105 for a pico cell may be referred to as a pico network node. A network node 105 for a femto cell may be referred to as a femto network node or an in-home network node. In some examples, a cell may not necessarily be stationary. For example, the geographic area of the cell may move according to the location of an associated mobile network node 105 (for example, a train, a satellite base station, an unmanned aerial vehicle, or an NTN network node).

The wireless communication network 100 may be a heterogeneous network that includes network nodes 105 of different types, such as macro network nodes, pico network nodes, femto network nodes, relay network nodes, aggregated network nodes, and/or disaggregated network nodes, among other examples. In the example shown in FIG. 1, network nodes 105d and 105e are regular macro network nodes, while network nodes 105a-105c are macro network nodes enabled with one of 3 dimension (3D), full dimension (FD), or massive MIMO. Network nodes 105a-105c take advantage of their higher dimension MIMO capabilities to exploit 3D beamforming in both elevation and azimuth beamforming to increase coverage and capacity. Network node 105f is a small cell network node which may be a home node or portable access point. A network node may support one or multiple cells, such as two cells, three cells, four cells, and the like. Various different types of network nodes 105 may generally transmit at different power levels, serve different coverage areas, and/or have different impacts on interference in the wireless communication network 100 than other types of network nodes 105. For example, macro network nodes may have a high transmit power level (for example, 5 to 40 watts), whereas pico network nodes, femto network nodes, and relay network nodes may have lower transmit power levels (for example, 0.1 to 2 watts).

In some examples, a network node 105 may be, may include, or may operate as an RU, a TRP, or a base station that communicates with one or more UEs 115 via a radio access link (which may be referred to as a “Uu” link). The radio access link may include a downlink and an uplink. “Downlink” (or “DL”) refers to a communication direction from a network node 105 to a UE 115, and “uplink” (or “UL”) refers to a communication direction from a UE 115 to a network node 105. Downlink channels may include one or more control channels and one or more data channels. A downlink control channel may be used to transmit downlink control information (DCI) (for example, scheduling information, reference signals, and/or configuration information) from a network node 105 to a UE 115. A downlink data channel may be used to transmit downlink data (for example, user data associated with a UE 115) from a network node 105 to a UE 115. Downlink control channels may include one or more physical downlink control channels (PDCCHs), and downlink data channels may include one or more physical downlink shared channels (PDSCHs). Uplink channels may similarly include one or more control channels and one or more data channels. An uplink control channel may be used to transmit uplink control information (UCI) (for example, reference signals and/or feedback corresponding to one or more downlink transmissions) from a UE 115 to a network node 105. An uplink data channel may be used to transmit uplink data (for example, user data associated with a UE 115) from a UE 115 to a network node 105. Uplink control channels may include one or more physical uplink control channels (PUCCHs), and uplink data channels may include one or more physical uplink shared channels (PUSCHs). The downlink and the uplink may each include a set of resources on which the network node 105 and the UE 115 may communicate.

Downlink and uplink resources may include time domain resources (frames, subframes, slots, and/or symbols), frequency domain resources (frequency bands, component carriers, subcarriers, resource blocks, and/or resource elements), and/or spatial domain resources (particular transmit directions and/or beam parameters). Frequency domain resources of some bands may be subdivided into bandwidth parts (BWPs). A BWP may be a continuous block of frequency domain resources (for example, a continuous block of resource blocks) that are allocated for one or more UEs 115. A UE 115 may be configured with both an uplink BWP and a downlink BWP (where the uplink BWP and the downlink BWP may be the same BWP or different BWPs). A BWP may be dynamically configured (for example, by a network node 105 transmitting a DCI configuration to the one or more UEs 115) and/or reconfigured, which means that a BWP can be adjusted in real-time (or near-real-time) in accordance with changing network conditions in the wireless communication network 100 and/or in accordance with the specific requirements of the one or more UEs 115. This enables more efficient use of the available frequency domain resources in the wireless communication network 100 because fewer frequency domain resources may be allocated to a BWP for a UE 115 (which may reduce the quantity of frequency domain resources that a UE 115 is required to monitor), leaving more frequency domain resources to be spread across multiple UEs 115. Thus, BWPs may also assist in the implementation of lower-capability UEs 115 by facilitating the configuration of smaller bandwidths for communication by such UEs 115.

As described above, in some aspects, the wireless communication network 100 may be, may include, or may be included in, an IAB network. In an IAB network, at least one network node 105 is an anchor network node that communicates with the core network 120. An anchor network node 105 may also be referred to as an IAB donor (or “IAB-donor”). The anchor network node 105 may connect to the core network 120 via a wired backhaul link. For example, an Ng interface of the anchor network node 105 may terminate at the core network 120. Additionally, or alternatively, an anchor network node 105 may connect to one or more devices of the core network 120 that provide a core access and mobility management function (AMF). An IAB network also generally includes multiple non-anchor network nodes 105, which may also be referred to as relay network nodes or simply as IAB nodes (or “IAB-nodes”). Each non-anchor network node 105 may communicate directly with the anchor network node 105 via a wireless backhaul link to access the core network 120, or may communicate indirectly with the anchor network node 105 via one or more other non-anchor network nodes 105 and associated wireless backhaul links that form a backhaul path to the core network 120. Some anchor network nodes 105 or other non-anchor network nodes 105 may also communicate directly with one or more UEs 115 via wireless access links that carry access traffic. In some examples, network resources for wireless communication (such as time resources, frequency resources, and/or spatial resources) may be shared between access links and backhaul links.

The wireless communication network 100 may support synchronous or asynchronous operation. For synchronous operation, the network nodes may have similar frame timing, and transmissions from different network nodes may be approximately aligned in time. For asynchronous operation, the network nodes may have different frame timing, and transmissions from different network nodes may not be aligned in time. In some scenarios, networks may be enabled or configured to handle dynamic switching between synchronous or asynchronous operations.

The UEs 115 are physically dispersed throughout the wireless communication network 100, and each UE may be stationary or mobile. It should be appreciated that, although a mobile apparatus is commonly referred to as a UE in standards and specifications promulgated by the 3GPP, such apparatus may additionally or otherwise be referred to by those skilled in the art as a mobile station (MS), a subscriber station, a mobile unit, a subscriber unit, a wireless unit, a remote unit, a mobile device, a wireless device, a wireless communications device, a remote device, a mobile subscriber station, an access terminal (AT), a mobile terminal, a wireless terminal, a remote terminal, a handset, a terminal, a user agent, a mobile client, a client, or some other suitable terminology. Within the present document, a “mobile” apparatus or UE need not necessarily have a capability to move, and may be stationary. Some non-limiting examples of a mobile apparatus, such as may include implementations of one or more of the UEs 115, include a mobile phone, a cellular (cell) phone, a smart phone, a session initiation protocol (SIP) phone, a wireless local loop (WLL) station, a laptop, a personal computer (PC), a notebook, a netbook, a smart book, a tablet, and a personal digital assistant (PDA). A UE 115 may additionally be an “Internet of Things” (IoT) or “Internet of Everything” (IoE) device, an automotive or other transportation vehicle, a satellite radio, a global positioning system (GPS) device, a global navigation satellite system (GNSS) device, a logistics controller, a drone, a multi-copter, a quad-copter, a smart energy or security device, a solar panel or solar array, municipal lighting, water, or other infrastructure; industrial automation and enterprise devices; consumer and wearable devices, such as eyewear, a wearable camera, a smart watch, a health or fitness tracker, a mammal implantable device, a gesture tracking device, a medical device, a digital audio player (such as MP3 player), a camera or a game console, among other examples. The UEs 115 may also include digital home or smart home devices, such as a home audio, video, and multimedia device, an appliance, a sensor, a vending machine, intelligent lighting, a home security system, or a smart meter, among other examples. In one aspect, a UE may be a device that includes a Universal Integrated Circuit Card (UICC). In another aspect, a UE may be a device that does not include a UICC. In some aspects, UEs that do not include UICCs may be referred to as IoE devices. The UEs 115a-115d of the implementation illustrated in FIG. 1 are examples of mobile smart phone-type devices accessing the wireless communication network 100. A UE may be a machine specifically configured for connected communication, including machine type communication (MTC), enhanced MTC (eMTC), narrowband IoT (NB-IoT) and the like. The UEs 115e-115k illustrated in FIG. 1 are examples of various machines configured for communication that access the wireless communication network 100.

A mobile apparatus, such as the UEs 115, may be able to communicate with any type of the network nodes, whether macro network nodes, pico network nodes, femto network nodes, macro base stations, pico base stations, femto base stations, relays, and the like. In FIG. 1, a communication link (represented as a lightning bolt) indicates wireless transmissions between a UE and a serving network node, which is a network node designated to serve the UE on the downlink or uplink, wireless transmissions between network nodes, and backhaul transmissions between network nodes. Backhaul communication between network nodes of the wireless communication network 100 may occur using wired or wireless communication links.

In some examples, two or more UEs 115 (for example, shown as UE 115i and UE 115j) may communicate directly with one another using sidelink communications (for example, without communicating by way of a network node 105 as an intermediary). As an example, the UE 115i may directly transmit data, control information, or other signaling as a sidelink communication to the UE 115j. This is in contrast to, for example, the UE 115i first transmitting data in a UL communication to a network node 105, which then transmits the data to the UE 115j in a DL communication. In various examples, the UEs 115 may transmit and receive sidelink communications using peer-to-peer (P2P) communication protocols, device-to-device (D2D) communication protocols, vehicle-to-everything (V2X) communication protocols (which may include vehicle-to-vehicle (V2V) protocols, vehicle-to-infrastructure (V2I) protocols, and/or vehicle-to-pedestrian (V2P) protocols), and/or mesh network communication protocols. In some deployments and configurations, a network node 105 may schedule and/or allocate resources for sidelink communications between UEs 115 in the wireless communication network 100. In some other deployments and configurations, a UE 115 (instead of a network node 105) may perform, or collaborate or negotiate with one or more other UEs to perform, scheduling operations, resource selection operations, and/or other operations for sidelink communications.

In some examples, the UEs 115 and the network nodes 105 may perform MIMO communication. “MIMO” generally refers to transmitting or receiving multiple signals (such as multiple layers or multiple data streams) simultaneously over the same time and frequency resources. MIMO techniques generally exploit multipath propagation. MIMO may be implemented using various spatial processing or spatial multiplexing operations. In some examples, MIMO may support simultaneous transmission to multiple receivers, referred to as multi-user MIMO (MU-MIMO). Some RATs may employ advanced MIMO techniques, such as mTRP operation (including redundant transmission or reception on multiple TRPs), reciprocity in the time domain or the frequency domain, single-frequency-network (SFN) transmission, or non-coherent joint transmission (NC-JT).

As an example of operation at the wireless communication network 100, the network nodes 105a-105c serve the UEs 115a and 115b using 3D beamforming and coordinated spatial techniques, such as coordinated multipoint (CoMP) or multi-connectivity. Macro network node 105d performs backhaul communications with the network nodes 105a-105c, as well as with the small cell network node 105f. Macro network node 105d also transmits multicast services which are subscribed to and received by the UEs 115c and 115d. Such multicast services may include mobile television or streaming video, or may include other services for providing community information, such as weather emergencies or alerts, such as Amber alerts or gray alerts.

The wireless communication network 100 of implementations supports mission critical communications with ultra-reliable and redundant links for mission critical devices, such the UE 115e, which is a drone. Redundant communication links with the UE 115e include communication links from the macro network nodes 105d and 105e, as well as the small cell network node 105f. Other machine type devices, such as UE 115f (thermometer), the UE 115g (smart meter), and the UE 115h (wearable device) may communicate through the wireless communication network 100 either directly with network nodes, such as the small cell network node 105f and the macro network node 105e, or in multi-hop configurations by communicating with another user device which relays its information to the network, such as the UE 115f communicating temperature measurement information to the UE 115g, which is then reported to the network through the small cell network node 105f. The wireless communication network 100 may provide additional network efficiency through dynamic, low-latency TDD or FDD communications, such as in a vehicle-to-vehicle (V2V) mesh network between the UEs 115i-115k communicating with the macro network node 105e.

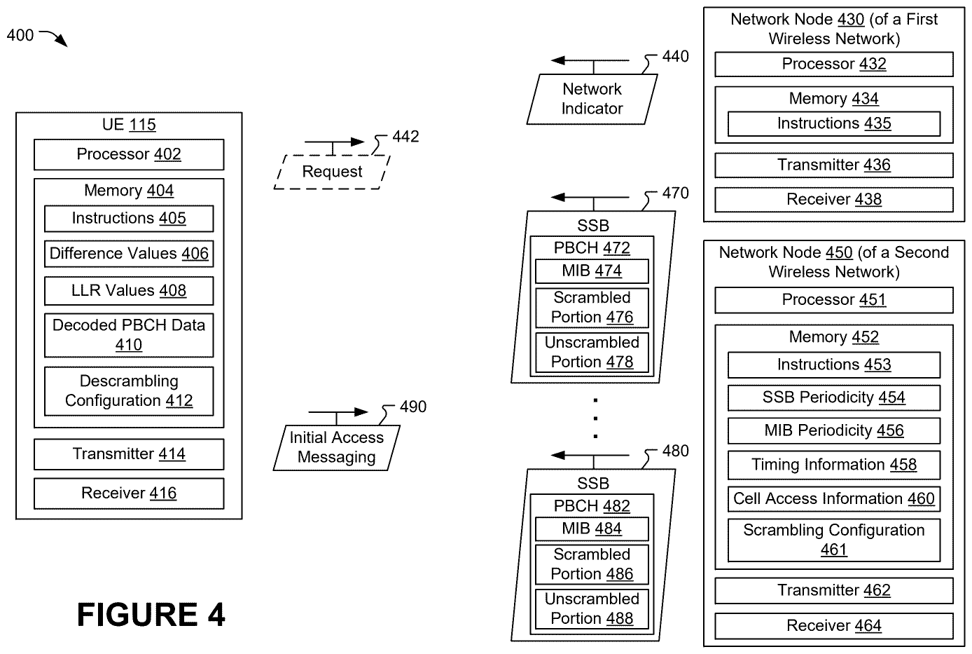

In some aspects, one or more of the network nodes 105 and one or more of the UEs may perform wireless communications that support PBCH scrambling and soft combining. For example, one or more of the UEs 115 (such as the UE 115c) may include a PBCH decoding manager 150 that manages operations that support PBCH scrambling and soft combining. The operations may include receiving multiple SSBs in accordance with an SSB periodicity, the SSBs respectively including multiple PBCHs that respectively include multiple MIBs in accordance with an MIB periodicity, with the PBCHs each having a scrambled portion and an unscrambled portion, as further described herein with reference to FIG. 4. In this example, the unscrambled portions include timing information in accordance with the SSB periodicity and the MIB periodicity, cell access information, or both. The operations may also include decoding the PBCHs by soft combining the PBCHs in accordance with the timing information, the cell access information, or both, as further described herein with reference to FIG. 4.

As another example, one or more of the network nodes 105 (such as the network node 105d) may include a PBCH encoding manager 152 that manages operations that support PBCH scrambling and soft combining. The operations may include generating multiple PBCHs that respectively include multiple MIBs in accordance with an MIB periodicity, with each PBCH having a scrambled portion and an unscrambled portion, as further described herein with reference to FIG. 4. In this example, the unscrambled portions include timing information in accordance with an SSB periodicity and the MIB periodicity, cell access information, or both. The operations may also include transmitting, in accordance with the SSB periodicity, multiple SSBs that respectively include the PBCHs, as further described herein with reference to FIG. 4.

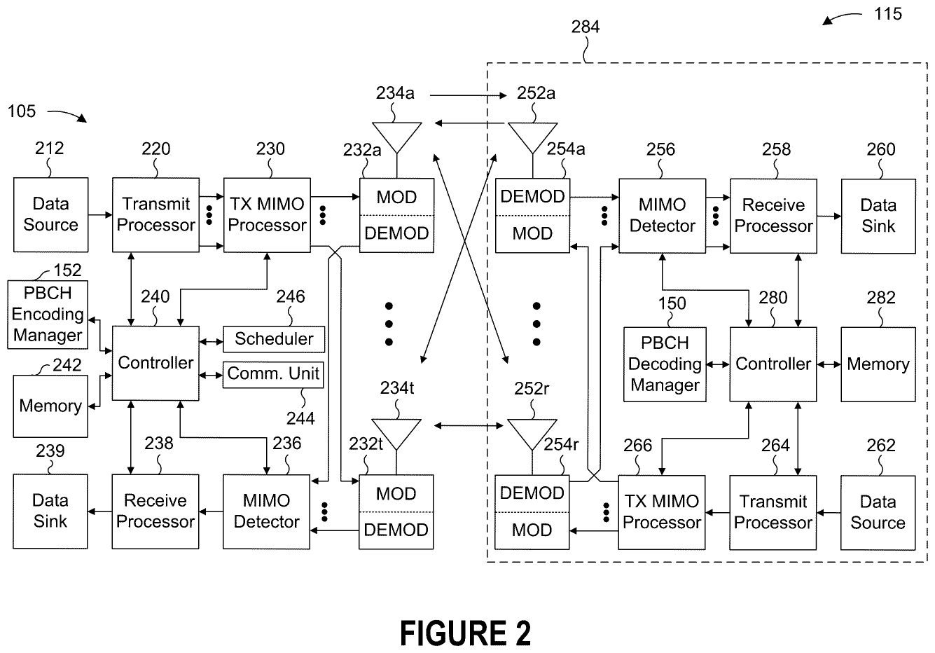

FIG. 2 is a block diagram illustrating examples of a network node 105 and a UE 115 in accordance with the present disclosure. The network node 105 and the UE 115 may be one of the network nodes 105 and one of the UEs 115 in FIG. 1. For a restricted association scenario, the network node 105 may be the small cell network node 105f in FIG. 1, and the UE 115 may be the UE 115c or 115d operating in a service area of the network node 105f, which in order to access the small cell network node 105f, would be included in a list of accessible UEs for the small cell network node 105f. Additionally, the network node 105 may be a base station or network entity of some other type. As shown in FIG. 2, the network node 105 may be equipped with antennas 234a through 234t, and the UE 115 may be equipped with antennas 252a through 252r for facilitating wireless communications.

For downlink communication from the network node 105 to the UE 115, a transmit processor 220 may receive data (“downlink data”) from a data source 212 (such as a data pipeline or a data queue) and control information from a controller 240. The control information may be for the physical broadcast channel (PBCH), physical control format indicator channel (PCFICH), physical hybrid-ARQ (automatic repeat request) indicator channel (PHICH), PDCCH, enhanced physical downlink control channel (EPDCCH), or MTC physical downlink control channel (MPDCCH), among other examples. The data may be for the PDSCH, among other examples. The transmit processor 220 may process, such as encode and symbol map, such as in accordance with a selected modulation and coding scheme (MCS), the data and control information to obtain data symbols and control symbols, respectively. Additionally, the transmit processor 220 may generate reference symbols for reference signals, such as for a cell-specific reference signal (CRS), a demodulation reference signal (DMRS), or a channel state information (CSI) reference signal (CSI-RS) and/or synchronization signals, such as for a primary synchronization signal (PSS) or a secondary synchronization signal (SSS).

Transmit (TX) multiple-input multiple-output (MIMO) processor 230 may perform spatial processing on the data symbols, the control symbols, and/or the reference symbols, if applicable, and may provide output symbol streams to modems 232a through 232t. For example, each output symbol stream may be provided to a respective modulator component (shown as MOD) of a modem 232. In some examples, spatial processing performed on the data symbols, the control symbols, and/or the reference symbols may include precoding. Each modem 232 may use the respective modulator component to process a respective output symbol stream, such as for OFDM, among other examples, to obtain an output sample stream. Each modem 232 may additionally, or alternatively use the respective modulator component to process the output sample stream to obtain a downlink signal. For example, to process the output sample stream, each modem 232 may use the respective modulator component to convert to analog, amplify, filter, and upconvert the output sample stream to obtain the downlink signal. The modems 232a through 232t may together transmit a set of downlink signals from via the antennas 234a through 234t, respectively.

A downlink signal may include a DCI communication, a MAC control element (MAC-CE) communication, an RRC communication, a downlink reference signal, or another type of downlink communication. Downlink signals may be transmitted on a PDCCH, a PDSCH, and/or on another downlink channel. A downlink signal may carry one or more transport blocks (TBs) of data. A TB may be a unit of data that is transmitted over an air interface in the wireless communication network 100. A data stream (for example, from the data source 212) may be encoded into multiple TBs for transmission over the air interface. The quantity of TBs used to carry the data associated with a particular data stream may be associated with a TB size common to the multiple TBs. The TB size may be associated with radio channel conditions of the air interface, the MCS used for encoding the data, the downlink resources allocated for transmitting the data, and/or another parameter. In general, the larger the TB size, the greater the amount of data that can be transmitted in a single transmission, which reduces signaling overhead. However, larger TB sizes may be more prone to transmission and/or reception errors than smaller TB sizes, but such errors may be mitigated by more robust error correction techniques.

At the UE 115, the antennas 252a through 252r may receive the downlink signals from the network node 105 and may provide a set of received signals to modems 254a through 254r. For example, each received signal may be provided to a respective demodulator component (shown as DEMOD) of a modem 254. Each modem 254 may use the respective demodulator component to condition a respective received signal to obtain input samples. For example, to condition the respective received signal, the demodulator component of each modem 254 may filter, amplify, downconvert, and/or digitize the respective received signal to obtain the input samples. Each modem 254 may use the respective demodulator component to further process the input samples, such as for OFDM, among other examples, to obtain received symbols. MIMO detector 256 may obtain received symbols from modems 254a through 254r, perform MIMO detection on the received symbols if applicable, and provide detected symbols. Receive processor 258 may process the detected symbols, provide decoded data for the UE 115 to a data sink 260 (which may include a data pipeline, a data queue, and/or an application executed on the UE 115), and provide decoded control information to a controller 280. For example, to process the detected symbols, the receive processor 258 may demodulate, deinterleave, and decode the detected symbols.

In some aspects, one or a combination of the antenna(s) 252, the modem(s) 254, the MIMO detector 256, the receive processor 258, the transmit processor 264, or the TX MIMO processor 266 may be included in a transceiver that is included in the UE 115. The transceiver may be under control of and used by one or more processors, such as the controller 280, and in some aspects in conjunction with processor-readable code stored in the memory 282, to perform aspects of the methods, processes, or operations described herein. In some aspects, the UE 115 may include another interface, another communication component, and/or another component that facilitates communication with the network node 105 and/or another UE 115. Additionally, or alternatively, one or more of the components of the UE 115 may be included in a housing 284.

For uplink communications from the UE 115 to the network node 105, a transmit processor 264 may receive and process data (“uplink data”) from a data source 262 and control information (such as for the PUCCH) from the controller 280. The control information may include one or more parameters, feedback, one or more signal measurements, and/or other types of control information. In some aspects, the receive processor 258 and/or the controller 280 may determine, for a received signal (such as received from the network node 105 or another UE), one or more parameters relating to transmission of the uplink communication. The one or more parameters may include a reference signal received power (RSRP) parameter, a received signal strength indicator (RSSI) parameter, a reference signal received quality (RSRQ) parameter, a channel quality indicator (CQI) parameter, or a transmit power control (TPC) parameter, among other examples. The control information may include an indication of the RSRP parameter, the RSSI parameter, the RSRQ parameter, the CQI parameter, the TPC parameter, and/or another parameter. The control information may facilitate parameter selection and/or scheduling for the UE 115 by the network node 105.

The transmit processor 264 may generate reference symbols for a reference signal, such as an uplink DMRS, an uplink sounding reference signal (SRS), and/or another type of reference signal. The symbols from the transmit processor 264 may be precoded by a TX MIMO processor 266, if applicable, and further processed by the modems 254a through 254r (such as for DFT-s-OFDM or CP-OFDM, among other examples). The TX MIMO processor 266 may perform spatial processing (for example, precoding) on the data symbols, the control symbols, and/or the reference symbols, if applicable, and may provide a set of output symbol streams to the modems 254. For example, each output symbol stream may be provided to a respective modulator component (shown as MOD) of a modem 254. Each modem 254 may use the respective modulator component to process a respective output symbol stream (for example, for OFDM) to obtain an output sample stream. Each modem 254 may further use the respective modulator component to process (for example, convert to analog, amplify, filter, and/or upconvert) the output sample stream to obtain an uplink signal.

The modems 254a through 254r may transmit a set of uplink signals via the corresponding antennas 252a through 252r, respectively. An uplink signal may include a UCI communication, a MAC-CE communication, an RRC communication, or another type of uplink communication. Uplink signals may be transmitted on a PUSCH, a PUCCH, and/or another type of uplink channel. An uplink signal may carry one or more TBs of data. Sidelink data and control transmissions (that is, transmissions directly between two or more UEs 115) may generally use similar techniques as were described for uplink data and control transmission, and may use sidelink-specific channels such as a physical sidelink shared channel (PSSCH), a physical sidelink control channel (PSCCH), and/or a physical sidelink feedback channel (PSFCH).

At network node 105, the uplink signals from the UE 115 may be received by antennas 234a through 234t, processed by demodulator components of the modems 232a through 232t, detected by a MIMO detector 236 if applicable, and further processed by a receive processor 238 to obtain decoded data and/or control information sent by the UE 115. The receive processor 238 may provide the decoded data to a data sink 239 (which may be a data pipeline, a data queue, and/or another type of data sink) and provide the decoded control information to the controller 240.

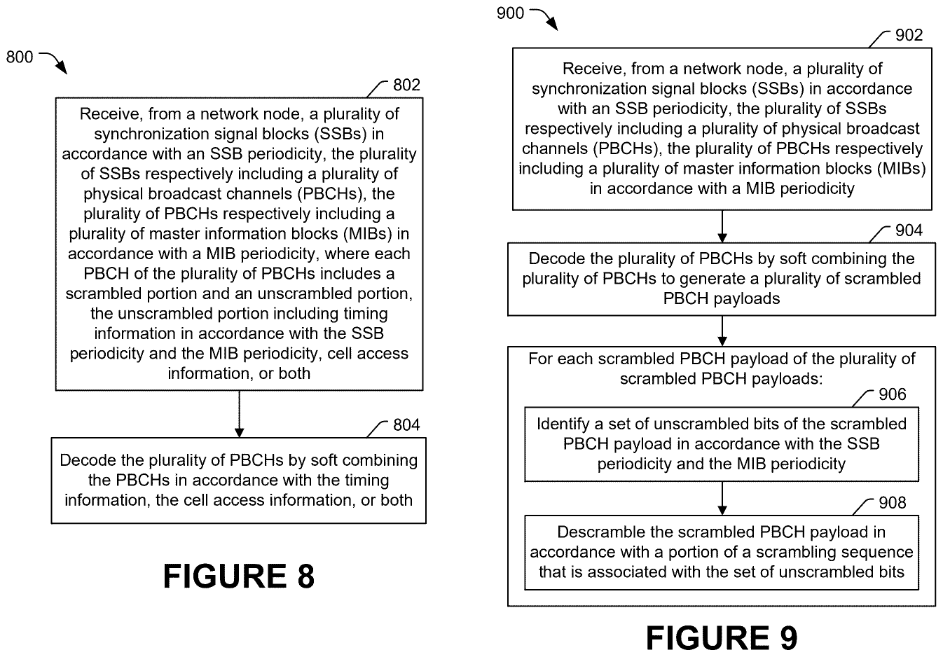

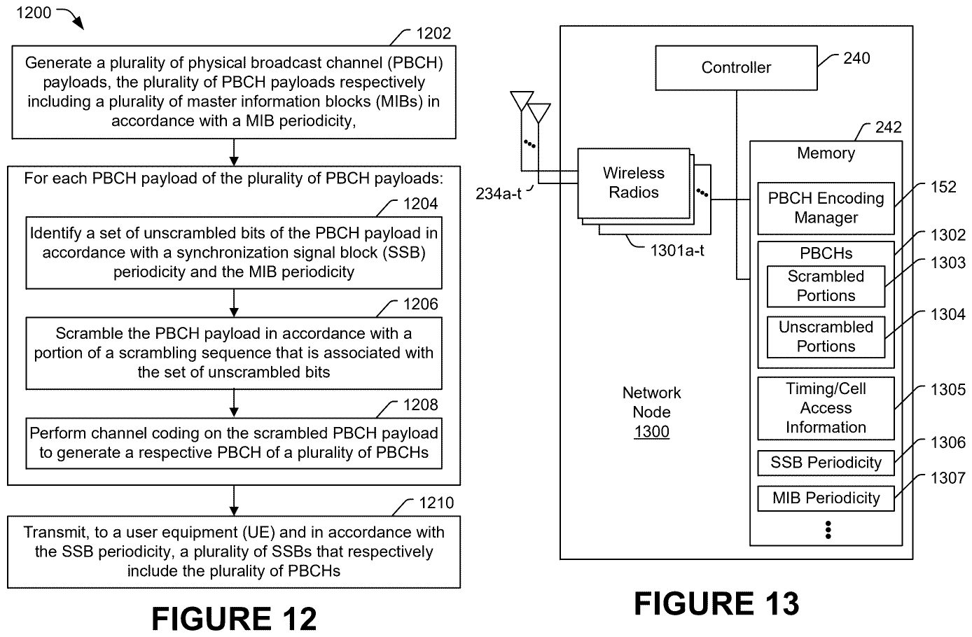

The controllers 240 and 280 may direct the operation at the network node 105 and the UE 115, respectively. The controller 240 (or other processors and modules at the network node 105) may perform or direct the execution of various processes for the techniques described herein, such as the process 1100 of FIG. 11, the process 1200 of FIG. 12, or other processes for the techniques described herein. Similarly, the controller 280 (or other processors and modules at the UE 115) may perform or direct the execution of various processes for the techniques described herein, such as the process 800 of FIG. 8, the process 900 of FIG. 9, or other processes for the techniques described herein. For example, the controller 240 and/or the controller 280 may perform or control operations that support PBCH scrambling and soft combining. Additionally, or alternatively, the UE 115 may include the PBCH decoding manager 150 and the network node 105 may include the PBCH encoding manager 152 that are configured to manage operations to support PBCH scrambling and soft combining, as further described herein. Although referred to as “controllers”, the controllers 240 and 280 may include one or more processors and/or one or more controllers, and also or in the alternative be referred to as “processors” or “controller/processors”. In some aspects, a single processor may perform all of the operations described as being performed by the one or more processors or the one or more controllers. In some aspects, a first set of (one or more) processors of the one or more processors may perform a first operation described as being performed by the one or more processors, and a second set of (one or more) processors of the one or more processors may perform a second operation described as being performed by the one or more processors. The first set of processors and the second set of processors may be the same set of processors or may be different sets of processors.

The memories 242 and 282 may store data and program codes for the network node 105 and the UE 115, respectively. Reference to “one or more memories” should be understood to refer to any one or more memories of a corresponding device, such as the memory described in connection with FIG. 2. For example, an operation described as being performed by one or more memories can be performed by the same subset of the one or more memories or different subsets of the one or more memories.

The network node 105 may use a scheduler 246 to schedule one or more UEs 115 for downlink or uplink communications. In some aspects, the scheduler 246 may use DCI to dynamically schedule DL transmissions to the UE 115 and/or UL transmissions from the UE 115. In some examples, the scheduler 246 may allocate recurring time domain resources and/or frequency domain resources that the UE 115 may use to transmit and/or receive communications using an RRC configuration (for example, a semi-static configuration), for example, to perform semi-persistent scheduling (SPS) or to configure a configured grant (CG) for the UE 115.

In some examples, the network node 105 may use a communication unit 244 to communicate with a core network and/or with other network nodes. The communication unit 244 may support wired and/or wireless communication protocols and/or connections, such as Ethernet, optical fiber, common public radio interface (CPRI), and/or a wired or wireless backhaul, among other examples. The network node 105 may use the communication unit 244 to transmit and/or receive data associated with the UE 115 or to perform network control signaling, among other examples. The communication unit 244 may include a transceiver and/or an interface, such as a network interface.

One or more antennas of the antennas 252 or the antennas 234 may include, or may be included within, one or more antenna panels, one or more antenna groups, one or more sets of antenna elements, or one or more antenna arrays, among other examples. An antenna panel, an antenna group, a set of antenna elements, or an antenna array may include one or more antenna elements (within a single housing or multiple housings), a set of coplanar antenna elements, a set of non-coplanar antenna elements, or one or more antenna elements coupled with one or more transmission or reception components, such as one or more components of FIG. 2. As used herein, “antenna” can refer to one or more antennas, one or more antenna panels, one or more antenna groups, one or more sets of antenna elements, or one or more antenna arrays. “Antenna panel” can refer to a group of antennas (such as antenna elements) arranged in an array or panel, which may facilitate beamforming by manipulating parameters of the group of antennas. “Antenna module” may refer to circuitry including one or more antennas, which may also include one or more other components (such as filters, amplifiers, or processors) associated with integrating the antenna module into a wireless communication device.

In some examples, each of the antenna elements of an antenna 234 or an antenna 252 may include one or more sub-elements for radiating or receiving radio frequency signals. For example, a single antenna element may include a first sub-element cross-polarized with a second sub-element that can be used to independently transmit cross-polarized signals. The antenna elements may include patch antennas, dipole antennas, and/or other types of antennas arranged in a linear pattern, a two-dimensional pattern, or another pattern. A spacing between antenna elements may be such that signals with a desired wavelength transmitted separately by the antenna elements may interact or interfere constructively and destructively along various directions (such as to form a desired beam). For example, given an expected range of wavelengths or frequencies, the spacing may provide a quarter wavelength, a half wavelength, or another fraction of a wavelength of spacing between neighboring antenna elements to allow for the desired constructive and destructive interference patterns of signals transmitted by the separate antenna elements within that expected range.

The amplitudes and/or phases of signals transmitted via antenna elements and/or sub-elements may be modulated and shifted relative to each other (such as by manipulating phase shift, phase offset, and/or amplitude) to generate one or more beams, which is referred to as beamforming. The term “beam” may refer to a directional transmission of a wireless signal toward a receiving device or otherwise in a desired direction. “Beam” may also generally refer to a direction associated with such a directional signal transmission, a set of directional resources associated with the signal transmission (for example, an angle of arrival, a horizontal direction, and/or a vertical direction), and/or a set of parameters that indicate one or more aspects of a directional signal, a direction associated with the signal, and/or a set of directional resources associated with the signal. In some implementations, antenna elements may be individually selected or deselected for directional transmission of a signal (or signals) by controlling amplitudes of one or more corresponding amplifiers and/or phases of the signal(s) to form one or more beams. The shape of a beam (such as the amplitude, width, and/or presence of side lobes) and/or the direction of a beam (such as an angle of the beam relative to a surface of an antenna array) can be dynamically controlled by modifying the phase shifts, phase offsets, and/or amplitudes of the multiple signals relative to each other.

Different UEs 115 or network nodes 105 may include different numbers of antenna elements. For example, a UE 115 may include a single antenna element, two antenna elements, four antenna elements, eight antenna elements, or a different number of antenna elements. As another example, a network node 105 may include eight antenna elements, 24 antenna elements, 64 antenna elements, 128 antenna elements, or a different number of antenna elements. Generally, a larger number of antenna elements may provide increased control over parameters for beam generation relative to a smaller number of antenna elements, whereas a smaller number of antenna elements may be less complex to implement and may use less power than a larger number of antenna elements. Multiple antenna elements may support multiple-layer transmission, in which a first layer of a communication (which may include a first data stream) and a second layer of a communication (which may include a second data stream) are transmitted using the same time and frequency resources with spatial multiplexing.

FIG. 3 is a block diagram illustrating an example disaggregated base station architecture 300 in accordance with the present disclosure. One or more components of the example disaggregated base station architecture 300 may be, may include, or may be included in one or more network nodes (such as one or more network nodes 105). The disaggregated base station architecture 300 may include a CU 310 that can communicate directly with a core network 320 via a backhaul link, or that can communicate indirectly with the core network 320 via one or more disaggregated control units, such as a Non-RT RIC 350 associated with a Service Management and Orchestration (SMO) Framework 360 and/or a Near-RT RIC 370 (for example, via an E2 link). In some implementations, the core network 320 includes or corresponds to the core network 120 of FIG. 1. The CU 310 may communicate with one or more DUs 330 via respective midhaul links, such as via F1 interfaces. Each of the DUs 330 may communicate with one or more RUs 340 via respective fronthaul links. Each of the RUs 340 may communicate with one or more UEs 115 via respective RF access links. In some deployments, a UE 115 may be simultaneously served by multiple RUs 340.

Each of the components of the disaggregated base station architecture 300, including the CUs 310, the DUs 330, the RUs 340, the Near-RT RICs 370, the Non-RT RICs 350, and the SMO Framework 360, may include one or more interfaces or may be coupled with one or more interfaces for receiving or transmitting signals, such as data or information, via a wired or wireless transmission medium.

In some aspects, the CU 310 may be logically split into one or more CU user plane (CU-UP) units and one or more CU control plane (CU-CP) units. A CU-UP unit may communicate bidirectionally with a CU-CP unit via an interface, such as the E1 interface when implemented in an O-RAN configuration. The CU 310 may be deployed to communicate with one or more DUs 330, as necessary, for network control and signaling. Each DU 330 may correspond to a logical unit that includes one or more base station functions to control the operation of one or more RUs 340. For example, a DU 330 may host various layers, such as an RLC layer, a MAC layer, or one or more PHY layers, such as one or more high PHY layers or one or more low PHY layers. Each layer (which also may be referred to as a module) may be implemented with an interface for communicating signals with other layers (and modules) hosted by the DU 330, or for communicating signals with the control functions hosted by the CU 310. Each RU 340 may implement lower layer functionality. In some aspects, real-time and non-real-time aspects of control and user plane communication with the RU(s) 340 may be controlled by the corresponding DU 330.

The SMO Framework 360 may support RAN deployment and provisioning of non-virtualized and virtualized network elements. For non-virtualized network elements, the SMO Framework 360 may support the deployment of dedicated physical resources for RAN coverage requirements, which may be managed via an operations and maintenance interface, such as an O1 interface. For virtualized network elements, the SMO Framework 360 may interact with a cloud computing platform (such as an open cloud (O-Cloud) platform 390) to perform network element life cycle management (such as to instantiate virtualized network elements) via a cloud computing platform interface, such as an O2 interface. A virtualized network element may include, but is not limited to, a CU 310, a DU 330, an RU 340, a non-RT RIC 350, and/or a Near-RT RIC 370. In some aspects, the SMO Framework 360 may communicate with a hardware aspect of a 4G RAN, a 5G NR RAN, and/or a 6G RAN, such as an open eNB (O-eNB) 380, via an O1 interface. Additionally, or alternatively, the SMO Framework 360 may communicate directly with each of one or more RUs 340 via a respective O1 interface. In some deployments, this configuration can enable each DU 330 and the CU 310 to be implemented in a cloud-based RAN architecture, such as a vRAN architecture.

The Non-RT RIC 350 may include or may implement a logical function that enables non-real-time control and optimization of RAN elements and resources, AT/ML workflows including model training and updates, and/or policy-based guidance of applications and/or features in the Near-RT RIC 370. The Non-RT RIC 350 may be coupled to or may communicate with (such as via an A1 interface) the Near-RT RIC 370. The Near-RT RIC 370 may include or may implement a logical function that enables near-real-time control and optimization of RAN elements and resources via data collection and actions via an interface (such as via an E2 interface) connecting one or more CUs 310, one or more DUs 330, and/or an O-eNB with the Near-RT RIC 370.

In some aspects, to generate AI/ML models to be deployed in the Near-RT RIC 370, the Non-RT RIC 350 may receive parameters or external enrichment information from external servers. Such information may be utilized by the Near-RT RIC 370 and may be received at the SMO Framework 360 or the Non-RT RIC 350 from non-network data sources or from network functions. In some examples, the Non-RT RIC 350 or the Near-RT RIC 370 may tune RAN behavior or performance. For example, the Non-RT RIC 350 may monitor long-term trends and patterns for performance and may employ AI/ML models to perform corrective actions via the SMO Framework 360 (such as reconfiguration via an O1 interface) or via creation of RAN management policies (such as A1 interface policies).

The UEs 115, the CU 310, the DUs 330, the RUs 340, or any other component(s) of FIG. 3 may implement one or more techniques or perform one or more operations associated with PBCH scrambling and soft combining, as described further herein. For example, the UEs 115 may include the PBCH decoding manager 150 and the RUs 340 may include the PBCH encoding manager 152, which may manage operations to support PBCH scrambling and soft combining. Although shown as being included in a single UE 115 in FIG. 3, any of the UEs 115 may include the PBCH decoding manager 150, and although shown as being included in a single RU 340 in FIG. 3, any of the RUs 340, the DUs 330, the CU 310, the Non-RT RIC 350, the SMO Framework 360, the Near-RT RIC 370, or a combination thereof, may include the PBCH encoding manager 152. The PBCH decoding manager 150 may direct operations of, for example, the process 800 of FIG. 8, the process 900 of FIG. 9, or other processes as described herein (alone or in conjunction with one or more other processors). Similarly, the PBCH encoding manager 152 may direct operations of, for example, the process 1100 of FIG. 11, the process 1200 of FIG. 12, or other processes as described herein (alone or in conjunction with one or more other processors).

In some examples, the PBCH decoding manager 150 or the PBCH encoding manager 152 may include, or have access to, a non-transitory computer-readable medium storing a set of instructions (for example, code or program code) for wireless communication. The memory may include one or more memories, such as a single memory or multiple different memories (of the same type or of different types). For example, the set of instructions, when executed (for example, directly, or after compiling, converting, or interpreting) by the PBCH decoding manager 150 or one or more processors of the UE 115 may cause the one or more processors or the PBCH decoding manager 150 to perform the process 800 of FIG. 8, the process 900 of FIG. 9, or other processes as described herein. As another example, the set of instructions, when executed (for example, directly, or after compiling, converting, or interpreting) by the PBCH encoding manager 152, one or more processors of the network node 105, the CU 310, the DU 330, the RU 340, the Non-RT RIC 350, the SMO Framework 360, or the Near-RT RIC 370, may cause the one or more processors or the PBCH encoding manager 152 to perform the process 1100 of FIG. 11, the process 1200 of FIG. 12, or other processes as described herein. In some examples, executing instructions may include running the instructions, converting the instructions, compiling the instructions, and/or interpreting the instructions, among other examples.

FIG. 4 is a block diagram illustrating an example wireless communication system 400 that supports PBCH scrambling and soft combining in accordance with the present disclosure. In some examples, the wireless communication system 400 may implement aspects of the wireless communication network 100. The wireless communication system 400 includes the UE 115, a network node 430, and a network node 450. Although one UE 115 and two network nodes 430, 450 are illustrated, in some other implementations, the wireless communication system 400 may generally include multiple UEs 115 and/or more than two network nodes 430, 450.

The UE 115 can include a variety of components (such as structural, hardware components) used for carrying out one or more functions described herein. For example, these components can include one or more processors 402 (hereinafter referred to collectively as “the processor 402”), one or more memory devices 404 (hereinafter referred to collectively as “the memory 404”), one or more transmitters 414 (hereinafter referred to collectively as “the transmitter 414”), and one or more receivers 416 (hereinafter referred to collectively as “the receiver 416”). Although referred to as a processor 402, the UE 115 may include one or more chips, system-on-chips (SoCs), chipsets, packages, or devices that individually or collectively constitute or include a processing system. The processing system includes processor (or “processing”) circuitry in the form of one or multiple processors (such as the processor 402), microprocessors, processing units (such as central processing units (CPUs), graphics processing units (GPUs), neural processing units (NPUs) and/or digital signal processors (DSPs)), processing blocks, application-specific integrated circuits (ASIC), programmable logic devices (PLDs) (such as field programmable gate arrays (FPGAs)), or other discrete gate or transistor logic or circuitry (all of which may be generally referred to herein individually as “processors” or collectively as “the processor 402” or “the processor circuitry”).

One or more of the processors 402 may be individually or collectively configurable or configured to perform various functions or operations described herein. A group of processors, such as the processors 402, collectively configurable or configured to perform a set of functions may include a first processor configurable or configured to perform a first function of the set of functions and a second processor configurable or configured to perform a second function of the set of functions, or may include the group of processors all being configured or configurable to perform the set of functions. The processor 402 may be configured to execute instructions 405 stored in the memory 404 to perform the operations described herein. In some implementations, the processor 402 includes or corresponds to the receive processor 258, the transmit processor 264, the controller 280, or a combination thereof, and the memory 404 includes or corresponds to the memory 282, described with reference to FIG. 2. In some implementations, the processor 402, the memory 404, the instructions 405, another component of the UE 115, or a combination thereof, may include or correspond to the PBCH decoding manager 150 of FIGS. 1-3 and/or may perform the operations associated with the PBCH decoding manager 150 to support PBCH scrambling and soft combining.

The memory 404 may be configured to store the instructions 405, difference values 406, log likelihood ratio (LLR) values 408, decoded PBCH data 410, and a descrambling configuration 412. The difference values 406 indicate differences in bit values between one or more codewords associated with PBCHs during a soft combining process at the UE 115, as further described herein. The LLR values 408 are generated during the soft combining process, as further described herein. The decoded PBCH data 410 represents decoded data derived from codewords representing received PBCHs at the UE 115, also referred to as received PBCH payloads, as further described herein. The descrambling configuration 412 indicates a scrambling sequence used to scramble PBCH payloads (and which may be used to descramble scrambled PBCH payloads received from a network node), an initialization time associated with the scrambling sequence, or both, as further described herein.

The transmitter 414 is configured to transmit reference signals, control information and data to one or more other devices, and the receiver 416 is configured to receive reference signals, synchronization signals, control information and data from one or more other devices. For example, the transmitter 414 may transmit signaling, control information and data to, and the receiver 416 may receive signaling, control information and data from, the network node 430, the network node 450, or both. In some implementations, the transmitter 414 and the receiver 416 may be integrated in one or more transceivers. Additionally, or alternatively, the transmitter 414 or the receiver 416 may include or correspond to one or more components of the UE 115 described with reference to FIG. 2.

The network node 430 is configured to support a first wireless network, such as a terrestrial network (TN), as further described herein. The network node 430 can include a variety of components (such as structural, hardware components) used for carrying out one or more functions described herein. For example, these components can include one or more processors 432 (hereinafter referred to collectively as “the processor 432”), one or more memory devices 434 (hereinafter referred to collectively as “the memory 434”), one or more transmitters 436 (hereinafter referred to collectively as “the transmitter 436”), and one or more receivers 438 (hereinafter referred to collectively as “the receiver 438”). Although referred to as a processor 432, the network node 430 may include one or more chips, SoCs, chipsets, packages, or devices that individually or collectively constitute or include a processing system. The processing system includes processor (or “processing”) circuitry in the form of one or multiple processors (such as the processor 432), microprocessors, processing units (such as CPUs, GPUs, NPUs and/or DSPs), processing blocks, ASICs, PLDs (such as FPGAs), or other discrete gate or transistor logic or circuitry (all of which may be generally referred to herein individually as “processors” or collectively as “the processor 432” or “the processor circuitry”).

One or more of the processors 432 may be individually or collectively configurable or configured to perform various functions or operations described herein. A group of processors, such as the processors 432, collectively configurable or configured to perform a set of functions may include a first processor configurable or configured to perform a first function of the set of functions and a second processor configurable or configured to perform a second function of the set of functions, or may include the group of processors all being configured or configurable to perform the set of functions. The processor 432 may be configured to execute instructions 435 stored in the memory 434 to perform the operations described herein. In some implementations, the network node 430 includes or corresponds to the network node 105, the processor 432 includes or corresponds to the receive processor 238, the transmit processor 220, the controller 240, or a combination thereof, and the memory 434 includes or corresponds to the memory 242, described with reference to FIG. 2. In some implementations, the processor 432, the memory 434, the instructions 435, another component of the network node 430, or a combination thereof, may include or correspond to the PBCH encoding manager 152 of FIGS. 1-3 and/or may perform the operations associated with the PBCH encoding manager 152 to support PBCH scrambling and soft combining. The memory 434 may be configured to store the instructions 435 and any additional data or information to support sharing initial cell selection parameters of another wireless network, as further described herein.

The transmitter 436 is configured to transmit reference signals, synchronization signals, control information, and data to one or more other devices, and the receiver 438 is configured to receive reference signals, control information and data from one or more other devices. For example, the transmitter 436 may transmit signaling, control information and data to, and the receiver 438 may receive signaling, control information and data from, the UE 115, the network node 450, or both. In some implementations, the transmitter 436 and the receiver 438 may be integrated in one or more transceivers. Additionally, or alternatively, the transmitter 436 or the receiver 438 may include or correspond to one or more components of network node 105 described with reference to FIG. 2.

The network node 450 is configured to support a second wireless network, such as a non-terrestrial network (NTN), as further described herein. The network node 450 can include a variety of components (such as structural, hardware components) used for carrying out one or more functions described herein. For example, these components can include one or more processors 451 (hereinafter referred to collectively as “the processor 451”), one or more memory devices 452 (hereinafter referred to collectively as “the memory 452”), one or more transmitters 462 (hereinafter referred to collectively as “the transmitter 462”), and one or more receivers 464 (hereinafter referred to collectively as “the receiver 464”). Although referred to as a processor 451, the network node 450 may include one or more chips, SoCs, chipsets, packages, or devices that individually or collectively constitute or include a processing system. The processing system includes processor (or “processing”) circuitry in the form of one or multiple processors (such as the processor 451), microprocessors, processing units (such as CPUs, GPUs, NPUs and/or DSPs), processing blocks, ASICs, PLDs (such as FPGAs), or other discrete gate or transistor logic or circuitry (all of which may be generally referred to herein individually as “processors” or collectively as “the processor 451” or “the processor circuitry”).

One or more of the processors 451 may be individually or collectively configurable or configured to perform various functions or operations described herein. A group of processors, such as the processors 451, collectively configurable or configured to perform a set of functions may include a first processor configurable or configured to perform a first function of the set of functions and a second processor configurable or configured to perform a second function of the set of functions, or may include the group of processors all being configured or configurable to perform the set of functions. The processor 451 may be configured to execute instructions 453 stored in the memory 452 to perform the operations described herein. In some implementations, the network node 450 includes or corresponds to the network node 105, the processor 451 includes or corresponds to the receive processor 238, the transmit processor 220, the controller 240, or a combination thereof, and the memory 452 includes or corresponds to the memory 242, described with reference to FIG. 2. In some implementations, the processor 451, the memory 452, the instructions 453, another component of the network node 450, or a combination thereof, may include or correspond to the PBCH encoding manager 152 of FIGS. 1-3 and/or may perform the operations associated with the PBCH encoding manager 152 to support PBCH scrambling and soft combining.

The memory 452 may be configured to store the instructions 453, an SSB periodicity 454, an MIB periodicity 456, timing information 458, cell access information 460, and a scrambling configuration 461. The SSB periodicity 454 represents a period of time between SSB transmissions by the network node 450. The MIB periodicity 456 represents a period of time between different MIBs, such as a time period during which a non-time varying portion of a PBCH payload, which includes an MIB or a portion thereof, remains fixed. The timing information 458 indicates timing within a cell supported by the network node 450. In some examples, the timing information 458 includes a system frame number (SFN) that is included in PBCHs provided by the network node 450. The cell access information 460 indicates particular fields or bits that are included in MIBs to enable cell access by UEs. In a particular implementation, the cell access information 460 includes a cell barred bit, an intra-frequency reselection bit, or a combination thereof. The scrambling configuration 461 indicates a scrambling sequence used to scramble PBCH payloads prior to channel coding, an initialization time associated with the scrambling sequence, or both, as further described herein.

The transmitter 462 is configured to transmit reference signals, synchronization signals, control information, and data to one or more other devices, and the receiver 464 is configured to receive reference signals, control information and data from one or more other devices. For example, the transmitter 462 may transmit signaling, control information and data to, and the receiver 464 may receive signaling, control information and data from, the UE 115, the network node 430, or both. In some implementations, the transmitter 462 and the receiver 464 may be integrated in one or more transceivers. Additionally, or alternatively, the transmitter 462 or the receiver 464 may include or correspond to one or more components of network node 105 described with reference to FIG. 2.

In some implementations, the wireless communication system 400 is configured to implement a 5G NR network or a 6G network. For example, the wireless communication system 400 may include multiple 5G-capable UEs 115 (or 6G-capable UEs 115) and multiple 5G-capable network nodes 430, 450, or both (or 6G-capable network nodes 430, 450), such as UEs and network nodes configured to operate in accordance with a 5G NR network protocol, or a 6G network protocol, such as that defined by the 3GPP. In some implementations, the wireless communication system 400 includes multiple wireless networks. For example, the network node 430 may support a first wireless network in accordance with one or more network parameters of the first wireless network, and the network node 450 may support a second wireless network in accordance with one or more network parameters of the second wireless network, such as the SSB periodicity 454, the MIB periodicity 456, the timing information 458, the cell access information 460, coverage information, frequency information, or a combination thereof. In some such implementations, the first wireless network that includes the network node 430 is a TN, such that the network node 430 is a base station, a gNB, or another type of terrestrial network node, and the second wireless network that includes the network node 450 is an NTN, such that the network node 450 is a satellite. Due to differences in communications associated with TNs and NTNs, one or more parameters of the second wireless network may be different than corresponding parameters of the first wireless network. As a non-limiting example, the SSB periodicity 454 may be larger than an SSB periodicity for initial cell selection of the first wireless network, which may be 20 ms according to a wireless communication standard. In this example, the first wireless network may be configured to support an SSB periodicity that is specified in a wireless communication standard, such as according to the following description: For initial cell selection, a UE may assume that half frames with SSBs occur with a periodicity of two frames. Stated differently, the wireless communication standard may specify that a 5 ms duration of SSB transmission (which includes a PBCH) occurs during one of every two 10 ms frames, such that an SSB is transmitted once every 20 ms.

During operation of the wireless communication system 400, the UE 115 may be located within a coverage range of a cell of the first wireless network that is supported by the network node 430. At some point in time, the UE 115 may move outside the coverage range associated with the network node 430 and attempt to perform initial cell selection with the network node 450 to join a cell of the second wireless network that is supported by the network node 450. In some implementations, the network node 430 may provide one or more initial cell selection parameters associated with the second wireless network to the UE 115 prior to the UE 115 leaving the coverage area associated with the network node 430, as further described below.

To enable UEs, such as the UE 115, to connect to the second wireless network, the network node 450 generates and transmits multiple SSBs for use in identifying additional timing and signaling information associated with the second wireless network. The multiple SSBs include an SSB 470 (a first SSB) and an SSB 480 (an Nth SSB, where N is a positive integer greater than or equal to two). Although two SSBs 470, 480 are illustrated in FIG. 4, in other examples, the network node 450 may transmit more than two SSBs, such that N is greater than two. The network node 450 transmits the SSBs 470, 480 in accordance with the SSB periodicity 454. For example, the SSB periodicity 454 may indicate how often SSBs are transmitted, a duration of a time period between SSB transmissions, an SSB transmission frequency, or the like. As an illustrative example, if the SSB periodicity 454 is 20 ms, a first SSB may be transmitted at an initial time t0 and a second SSB, which is the next consecutive SSB, may be transmitted 20 ms after t0. In this example, the SSB 470 may include or correspond to the first SSB that is transmitted at time t0, the network node 450 may transmit the second SSB at time t0+20, the network node 450 may transmit a third SSB at time t0+40, and the SSB 480 may include or correspond to a fourth SSB that is transmitted at time t0+60.

However, unlike some other wireless networks in which the SSB periodicity is a fixed value that is common among multiple different cells and/or types of wireless networks, the SSB periodicity 454 may be specific to the second wireless network and, in some implementations, the SSB periodicity 454 may be larger than the SSB periodicities of other wireless networks. For example, if the first wireless network that includes the network node 430 is a TN that supports an SSB periodicity of 20 ms, the second wireless network that includes the network node 450 may be an NTN that supports the SSB periodicity 454 having a value of 40 ms, 80 ms, or 160 ms, as non-limiting examples. Supporting these larger SSBs may save battery power at satellite(s) of an NTN by reducing power consumption by decreasing the frequency of SSB transmission. As such, PBCHs carried by the SSBs 470, 480 may include payloads in which bits other than the second LSB and the third LSB of the SFN may be different between two PBCHs within the same MIB period, unlike in a typical wireless network (and unlike in the first wireless network). For this reason, the SSB periodicity 454 may be advertised, either by the network node 450 or by the network node 430, and bits of the PBCHs that do not undergo a first scrambling process (such as scrambling before channel coding) may be identified in accordance with the SSB periodicity 454 and the MIB periodicity 456, as described below, such that the network node 450 is able to support the larger SSB periodicity 454 without significantly increasing the computational resource use and power consumption associated with soft combining the PBCHs at the UE 115 to decode the PBCHs.

To convey the timing and signaling information about the cell, the SSBs 470, 480 respectively include multiple PBCHs, and the PBCHs respectively include multiple MIBs. For example, the SSB 470 includes a PBCH 472 that contains a MIB 474 and additional information within the PBCH payload, and the SSB 480 includes a PBCH 482 that contains a MIB 484 and additional information within the PBCH payload. The MIBs are contained within respective PBCHs that are transmitted in accordance with the MIB periodicity 456 such that at least one PBCH containing a respective MIB is transmitted each MIB period, similar to at least one SSB being transmitted each SSB period. If the SSB periodicity 454 is smaller than the MIB periodicity 456, a first SSB that is transmitted during an MIB period includes a PBCH that contains a MIB, and one or more other SSBs that are transmitted during the same MIB period respectively include PBCHs that contain retransmissions of the MIB. Alternatively, if the SSB periodicity 454 is the same as the MIB periodicity 456, one SSB is transmitted per MIB period, and that SSB includes a PBCH that contains the MIB. Alternatively, if the SSB periodicity 454 is larger than the MIB periodicity 456, there are multiple MIB periods between consecutive SSB transmissions, and therefore consecutive PBCH transmissions. A typical MIB periodicity that is specified in some wireless communication standards is once per 80 ms, such that, if the fixed SSB periodicity of 20 ms is also followed, there are four SSB transmissions per MIB period. In such an example, the first SSB includes a PBCH that contains an MIB, and the remaining three SSBs respectively include PBCHs that respectively contain retransmissions of the MIB that are substantially the same except for a few time-varying bits that may have different values in different instances of the respective PBCHs.

Each of the PBCHs 472, 482 include a respective scrambled portion and a respective unscrambled portion. For example, the PBCH 472 includes a scrambled portion 476 and an unscrambled portion 478. Similarly, the PBCH 482 includes a scrambled portion 486 and an unscrambled portion 488. The scrambled portions 476, 486 correspond to portions of respective PBCH payloads that are scrambled prior to being combined with the unscrambled portions 478, 488 and channel coded to form the PBCHs 472, 482. For example, after applying a first scrambling operation to portion of the PBCH payload to generate the scrambled portion 476 and the unscrambled portion 478, the network node 450 may attach a cyclic redundancy check (CRC) portion to the PBCH payload that includes the MIB 474, perform channel coding on the PBCH payload, perform rate matching on the PBCH payload, and apply a second scrambling to the PBCH payload to generate the PBCH 472 that is included in the SSB 470 that is transmitted to the UE 115. The network node 450 may perform similar operations on the PBCH payload that includes the MIB 484 to generate the PBCH 482 that is included in the SSB 480 that is transmitted to the UE 115. In implementations that include application of two types of scrambling, the scrambling described herein that may be omitted from certain bits or fields of a PBCH refers to the first scrambling that is applied prior to performance of the channel coding. In some implementations, the scrambled portion 476 includes a first portion of the MIB 474 and the unscrambled portion 478 includes a second portion of the MIB 474. Additionally, or alternatively, the scrambled portion 486 may include a first portion of the MIB 484 and the unscrambled portion 488 may include a second portion of the MIB 484. Alternatively, the scrambled portions 476, 486 may include the entireties of the MIBs 474, 484, respectively.

The selection of portions of the PBCHs 472, 482 to be scrambled, or to leave unscrambled, may be performed at the field-level or the bit-level of the PBCH. An MIB typically includes a set of fields that provide information for identifying and decoding a system information block type #1 (SIB1) message from the network node 450. For example, the MIBs 474, 484 may each include the timing information 458, such as a portion of an SFN, in addition to a subCarrierSpacingCommon field, a ssb-SubcarrierOffset field, a dmrs-TypeA-Position field, a pdcch-ConfigSIB1 field, a cell barred bit, and an intra-frequency reselection bit. In some examples, the SFN includes ten digits, six of which are included in the MIB, and four of which are carried in the portion of the PBCH payload excluding the MIB. The bits which remain the same in consecutive transmissions or retransmissions of PBCHs are scrambled, and the bits which have different values between consecutive transmissions or retransmissions of the PBCHs are referred to as time-varying bits, which are not scrambled and are retained as a set of one or more unscrambled bits. In typical wireless communication networks in which the SSB periodicity is 20 ms and the MIB periodicity is 80 ms, two bits of the SFN are omitted from the application of the scrambling: the second LSB of the SFN and the third LSB of the SFN. This is because the SFN increases by one every 10 ms, but because a PBCH containing an MIB is transmitted or retransmitted only once every 20 ms (according the SSB periodicity), the second LSB and the third LSB of the SFN vary according to the following pattern in four consecutive MSBs: 00-01-10-11. The first LSB does not vary in each PBCH because the SFN is increased twice during each SSB period, and thus the first LSB is the same between consecutive transmissions or retransmissions of the PBCH. However, because the time varying bits are different in different PBCHs depending on the SSB periodicity 454 and the MIB periodicity 456, the network node 450 does not use the predefined fixed unscrambled bits of conventional wireless networks (for example, the second LSB and the third LSB of the SFN) to generate the PBCHs 472, 482.

Instead of always skipping the second LSB and the third LSB of the SFN when applying the scrambling to the generated PBCH payloads, the network node 450 identifies which bits or fields of the PBCHs 472, 482 to omit from the scrambling in accordance with the SSB periodicity 454 and the MIB periodicity 456 in order to generate the respective unscrambled portions 478, 488 of the PBCHs 472, 482. The bits that are skipped when applying the scrambling correspond to time-varying bits and are therefore included in the unscrambled portions 478, 488 prior to the channel coding to generate the PBCHs 472, 482. For example, the unscrambled portions 478, 488 may include a portion of the timing information 458, the cell access information 460, or both. In some examples, the portion of the timing information 458 may include at least a fourth LSB of the SFN, a fifth LSB of the SFN, or a sixth LSB of the SFN, and the cell access information 460 may include at least one of a cell barred bit and an intra-frequency reselection bit. Depending on the relationship between the SSB periodicity 454 and the MIB periodicity 456, the selection or identification of the bits to be included in the unscrambled portions can correspond to a group of PBCHs that are transmitted during a single MIB period or to a group of PBCHs that are transmitted across multiple MIB periods, such as a first set of PBCHs associated with a first MIB period and a second set of PBCHs associated with a second MIB period.

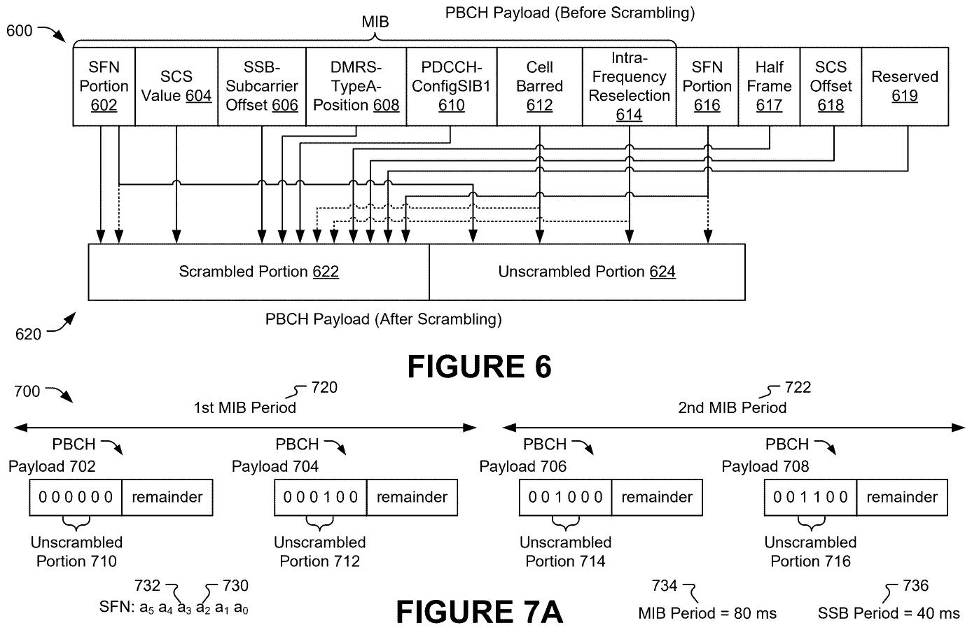

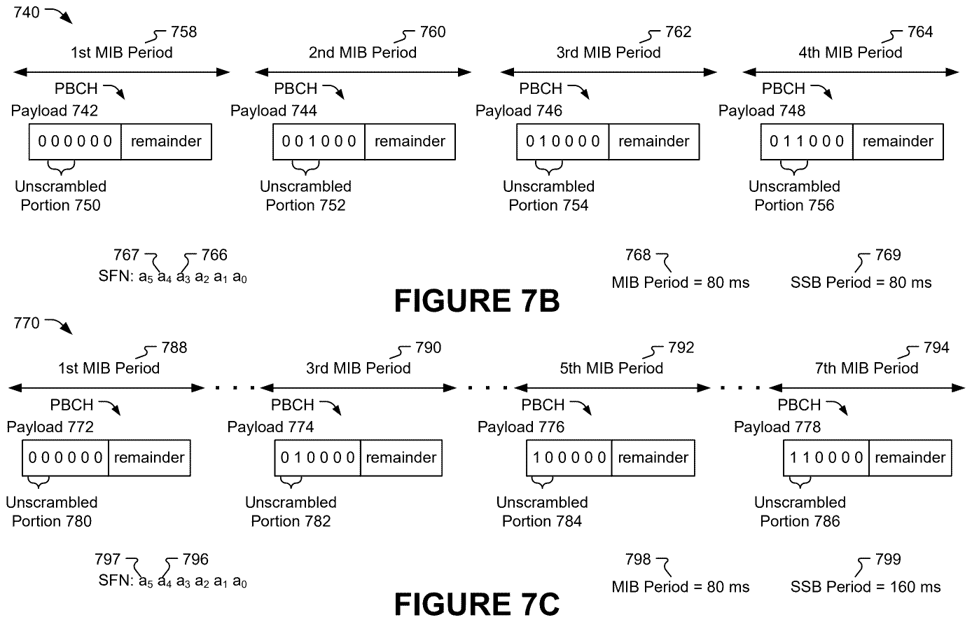

As an illustrative example of scrambling a portion of the PBCH 472, if the SSB periodicity 454 is 40 ms and the MIB periodicity 456 is 80 ms, the unscrambled portion 478 may include the third LSB of the SFN and the fourth LSB of the SFN, due to these two bits of the SFN being different in a sequence of four consecutive PBCHs (which applies to PBCH decoding by the UE 115 across two MIB periods (also referred to as two PBCH transmission time intervals (TTIs))). In this example, if the cell barred status or the intra-frequency reselection status associated with the cell supported by the network node 450 is capable of changing between MIB periods, the unscrambled portion 478 also includes the cell barred bit or the intra-frequency reselection bit. Similarly, the unscrambled portion 488 may include the third LSB of the SFN and the fourth LSB of the SFN, and optionally the cell barred bit or the intra-frequency reselection bit, although the values of one or more of these bits may be different in the PBCH 482 than in the PBCH 472. Thus, in this example, the time-varying or dynamic portion of the PBCHs 472, 482 are included in the unscrambled portions 478, 488 as respective sets of one or more unscrambled bits. In some examples, the portions of the PBCHs 472, 482 that are included in the unscrambled portions 478, 488 are determined according to the following:
For an SSB periodicity having the value of 20×2ⁿ⁻¹ ms, do not scramble the (n+1)th LSB and the (n+2)th LSB of the SFN, and optionally the cell barred bit, the intra-frequency reselection bit, or both,
   where n is a positive integer, the SSB periodicity is in ms, and the MIB periodicity may be 80 ms. An example of scrambling a portion of a PBCH is further described herein with reference to FIG. 6, and additional examples of identifying the portions to which scrambling is not applied are described further herein with reference to FIGS. 7A-7C.

In some aspects, a scrambling sequence that is applied to the PBCH payloads to generate the respective scrambled portions is selected or determined in accordance with values of the respective unscrambled portions. For example, the network node 450 may identify the unscrambled bits in accordance with the SSB periodicity 454 and the MIB periodicity 456, as described above, and the network node 450 may determine one or more values with which to derive the bits of the respective portions of the scrambling sequence in accordance with the values of the selected LSBs of the SFN (or other selected unscrambled bits). These values may be stored as or otherwise indicated by the scrambling configuration 461.

In some embodiments, for a PBCH transmission in a frame, a bit sequence a₀, a₁, a₂, a₃ . . . , a_{A-1} is scrambled into a bit sequence a′₀, a′₁, a′₂, a′₃ . . . , a′_{A-1}, where a′ᵢ=(aᵢ+sᵢ) mod 2 for i=0, 1, . . . A−1 and s₀, s₁, s₂, s₃, . . . , s_{A-1} is generated according to the following pseudo code, where ‘mod’ represents the arithmetic modulo operation that can be represented as A modulo B or mod(A, B):

```
i = 0;
j = 0;
Let the SSB periodicity be 20 * 2ⁿ⁻¹ ms, where n = 1, 2, 3, ...
while i < A:
  if aᵢ corresponds to any of the bits belonging to the candidate SS/PBCH
  block index, the half frame index, and (n+1)th and (n+2)th least
  significant bits of the SFN
    sᵢ = 0;
  else
    sᵢ = c(j + vM);
    j = j + 1;
  end if
  i = i + 1;
end
```

In the above pseudo code, the scrambling sequence ci is defined by a wireless communication standard and is initialized with

$${c}_{init} = {N}_{ID}^{cell}$$

(an identification number associated with the cell supported by the network node 450) at the start of each SFN satisfying mod(SFN, 2*2ⁿ⁺¹)=0; where M is set according to: M=A−3 for L̅ₘₐₓ=4 or L̅ₘₐₓ=8; M=A−4 for L̅ₘₐₓ=10; M=A−5 for L̅ₘₐₓ=20; and M=A−6 for L̅ₘₐₓ=64; and where L̅ₘₐₓ is the number of candidate SS/PBCH blocks in a half frame according to a wireless communication standard; and v is determined according to Table 1 below:

TABLE 1
Value of v for PBCH scrambling for SSB periodicity of 20 * 2ⁿ⁻¹

| ((n + 2)th LSB of SFN, | |
|---|---|
| (n + 1)th LSB of SFN) | Value of v |
| (0, 0) | 0 |
| (0, 1) | 1 |
| (1, 0) | 2 |
| (1, 1) | 3 |

According to the values of v in Table 1, a PBCH payload may be scrambled in accordance with a portion of a scrambling sequence that is associated with the set of unscrambled bits of the PBCH payload in a manner that supports SSB periodicities other than 20 ms. For example, if n=2 and the SSB periodicity 454 is 40 ms, v is determined in accordance with values of the third LSB of the SFN and the fourth LSB of the SFN. As another example, if n=3 and the SSB periodicity 454 is 80 ms, v is determined in accordance with values of the fourth LSB of the SFN and the fifth LSB of the SFN. As another example, if n=4 and the SSB periodicity 454 is 160 ms, v is determined in accordance with values of the fifth LSB of the SFN and the sixth LSB of the SFN. If n=1, the SSB periodicity 454 is 20 ms, such as in some other wireless networks. Accordingly, the network node 450 may scramble PBCH payloads in accordance with a portion of a scrambling sequence that is associated with the unscrambled (n+1)th LSB and (n+2)th LSB of the SFN, which may include the third LSB of the SFN, the fourth LSB of the SFN, the fifth LSB of the SFN, the sixth LSB of the SFN, or a combination thereof. In this notation, n can be any positive integer that is greater than or equal to one.

Additionally, or alternatively, the network node 450 may set an initiation time associated with the scrambling sequence in accordance with the SSB periodicity 454. Instead of initializing the scrambling sequence after every 80 ms, which corresponds to each SFN that is a multiple of eight and thus every four SSBs at a fixed SSB periodicity of 20 ms, the network node 450 may set the initialization time associated with the scrambling sequence to correspond to a SFN associated with a respective MIB that satisfies: mod(SFN, 2*2ⁿ⁺¹)=0, where n is a positive integer such that n=1, 2, 3, . . . Stated another way, the scrambling sequence is initialized when at a system frame having a SFN that is a multiple of 2*2ⁿ⁺¹ such that SFN modulo 2*2ⁿ⁺¹ is equal to zero (in another notation). For example, the initialization time may correspond to the SFN associated with the respective MIB that has a different value of a fourth LSB than a previous SFN when n=2. As another example, the initialization time may correspond to the SFN associated with the respective MIB that has a different value of a fifth LSB than a previous SFN when n=3. This initialization time (or amount of SFNs between initializations) may be stored or otherwise indicated by the scrambling configuration 461.

After scrambling portions of the MIBs and performing the channel coding to generate the PBCHs 472, 482, the PBCHs 472, 482 may be transmitted to the UE 115 within the SSBs 470, 480, respectively, in accordance with the SSB periodicity 454. For example, the network node 450 may transmit the SSB 470 to the UE 115 during a first SSB period, the network node 450 may optionally transmit additional SSB(s) to the UE 115 during additional SSB periods, and the network node 450 may transmit the SSB 480 to the UE 115 during an Nth SSB period. The UE 115 may receive the SSBs 470, 480 from the network node 450 and decode the PBCHs 472, 482 by soft combining the PBCHs 472, 482 in accordance with the timing information 458, the cell access information 460, or both, that are included in the unscrambled portions 478, 488. Such decoding by soft combining the PBCHs 472, 482, including the MIBs 474, 484 contained within, causes the UE 115 to generate the decoded PBCH data 410. As an example, to soft combine the PBCH 472 and the PBCH 482, the UE 115 may calculate one of the difference values 406 between the unscrambled portion 478 of the PBCH 472 and the unscrambled portion 488 of the PBCH 482. After calculating this one of the difference values 406, the UE 115 may adjust one of the LLR values 408 associated with the PBCH 482 in accordance with the one of the difference values 406. After the adjustment, the UE 115 may decode the PBCH 472 and the PBCH 482, respectively, in accordance with the adjusted one of the LLR values 408 that is associated with the PBCH 482.

Stated another way, the UE 115 may determine a sum of the signal associated with two or more instances of PBCHs, which may correspond to or be derived from the difference values 406, and use the sum to determine the LLR values 408 for use in generating the decoded PBCH data 410, by soft combining multiple instances of received PBCHs. Soft combining multiple PBCHs can improve the decoding performance at the UE 115. In some implementations, the soft combining can include performing hypothesis testing on the unscrambled portion 478 and the unscrambled portion 488. For each hypothesis, the UE 115 may use the difference in the PBCH payload after the first scrambling is applied, from the PBCH 472 to the PBCH 482, to compute the difference in two codewords out of channel coding. This difference, included in the difference values 406, is used to adjust one of the LLR values 408 associated with the second codeword (or the Nth codeword for N PBCHs). If there are more than two codewords to be soft combined, differences between the first codeword and any of the other codewords may be similarly determined and used to adjust associated LLR values. The UE 115 then adds the LLR values 408 of the two (or N) codewords for decoding the PBCH 472 and the PBCH 482. Soft combining has been successfully used by TN UEs and may provide additional success for NTN UEs in cases of greater signal attenuation, such as due to foliage or other partial blockages, or due to non-line of sight (NLOS) issues. Accordingly, the success of the PBCH soft combining schemes at the UE 115 may depend on the UE 115 correctly identifying which bits of the timing information 458 and the cell access information 460 change between multiple instances of PBCHs, such as the PBCH 472 and the PBCH 482. As explained above, such identification can be performed in accordance with the SSB periodicity 454 and the 456. Different examples of unscrambled portions and scrambled portions of PBCHs are further described herein with reference to FIGS. 7A-7C.

In some embodiments, soft combining the PBCHs 472, 482 may decode the PBCHs 472, 482 into respective scrambled portions and unscrambled portions of MIBs. For example, the UE 115 may decode the PBCH 472 into the scrambled portion 476 and the unscrambled portion 478, and the UE 115 may decode the PBCH 482 into the scrambled portion 486 and the unscrambled portion 488. To descramble the respective scrambled portions, the UE 115 may identify the set of unscrambled bits of the respective PBCH payload in accordance with the SSB periodicity 454 and the MIB periodicity 456, as described above, and the UE 115 may descramble the respective PBCH payload in accordance with a portion of a scrambling sequence that is associated with the set of unscrambled bits. For example, the set of unscrambled bits for a scrambled PBCH payload may include one or more LSBs of timing information associated with a respective MIB included in the scrambled PBCH payload, such as a fourth LSB of a SFN, a fifth LSB of the SFN, a sixth LSB of the SFN, or a combination thereof. The UE 115 may identify the portion of the scrambling sequence in accordance with the unscrambled bits and the descrambling configuration 412, which may include or correspond to the scrambling configuration 461 (or an inverse thereof) and may indicate the scrambling process and pseudo code described above and the information in Table 1.

To illustrate, the UE 115 may determine a value of v in accordance with the unscrambled portions 478, 488 in order to descramble the scrambled portions 476, 486, respectively. In such an example, the SSB periodicity 454 is equal to 20*2ⁿ⁻¹, n is a positive integer, and the respective unscrambled bits are the (n+1)th LSB of the SFN and the (n+2)th LSB of the SFN. The UE 115 may determine the value of v in accordance with the values of these LSBs in accordance with Table 1, and the UE 115 may derive the scrambling sequence (or a descrambling sequence) in accordance with the value of v. Additionally, or alternatively, the UE 115 may identify an initialization time associated with the scrambling sequence in accordance with the SSB periodicity 454. For example, the UE 115 may identify SFNs as initialization times if the SFNs are associated with a respective MIB that satisfies mod(SFN, 2*2ⁿ⁺¹)=0, where n is a positive integer. In some such examples, the UE 115 may identify the initialization time as corresponding to an MIB that has a different value of a fourth LSB or a fifth LSB than a previous SFN. The decoded and descrambled PBCH payloads may be stored as the decoded PBCH data 410.

After generating the decoded PBCH data 410 using the soft combining process with respect to the PBCH 472 and the PBCH 482, the UE 115 may perform additional operations as part of an initial cell selection and connection process with the network node 450. For example, the decoded PBCH data 410 may indicate parameters of one or more SIB1 transmissions from the network node 450, and the UE 115 may monitor a wireless channel between the UE 115 and the network node 450 to receive and decode the SIB1 transmissions. The SIB1 transmissions may provide additional information for connecting to the cell supported by the network node 450. Such additional information may enable the UE 115 to send initial access messaging 490 to the network node 450, which may include a request to join the second wireless network, handshake information, capabilities information, other data or signaling, or a combination thereof. The above-described operations of the UE 115, from receiving the SSB 470 and the SSB 480 through sending the initial access messaging 490 may be part of performance of an initial connection procedure with the network node 450 that is performed by the UE 115.

In some implementations, prior to monitoring one or more wireless channels for the SSB 470 and the SSB 480, the UE 115 may receive information associated with the second wireless network from another source, such as the network node 430 of the first wireless network. For example, the network node 430 may send a network indicator 440 to the UE 115 to indicate one or more initial cell selection parameters associated with the second wireless network. The network node 430 may provide the network indicator 440 to the UE 115 using various signaling either in-band or out-of-band of the first wireless network. For example, the network indicator 440 may be included in a SIB, a MAC-CE, or a RRC message, that is transmitted from the network node 430 to the UE 115. In some implementations, the network indicator 440 may be requested by the UE 115. For example, the UE 115 may transmit a request 442 to the network node 430, and the network node 430 transmits the network indicator 440 to the UE 115 in accordance with the request 442. In such implementations, the network indicator 440 is included in a MAC-CE or an RRC message. The request 442 is optional and is illustrated using dashed lines in FIG. 4 to indicate that, although the UE 115 may transmit the request 442 in some implementations, in other implementations, the UE 115 does not transmit the request 442 and transmission of the network indicator 440 is initiated by the network node 430. By the network node 430 providing the network indicator 440 to the UE 115 before the UE 115 beings an initial connection procedure with the network node 450, the duration of the initial connection procedure between the UE 115 and the network node 450 may be reduced because the UE 115 already receives one or more parameters associated with the second wireless network from the network node 430 instead of determining the parameters through communications with the network node 450 alone.

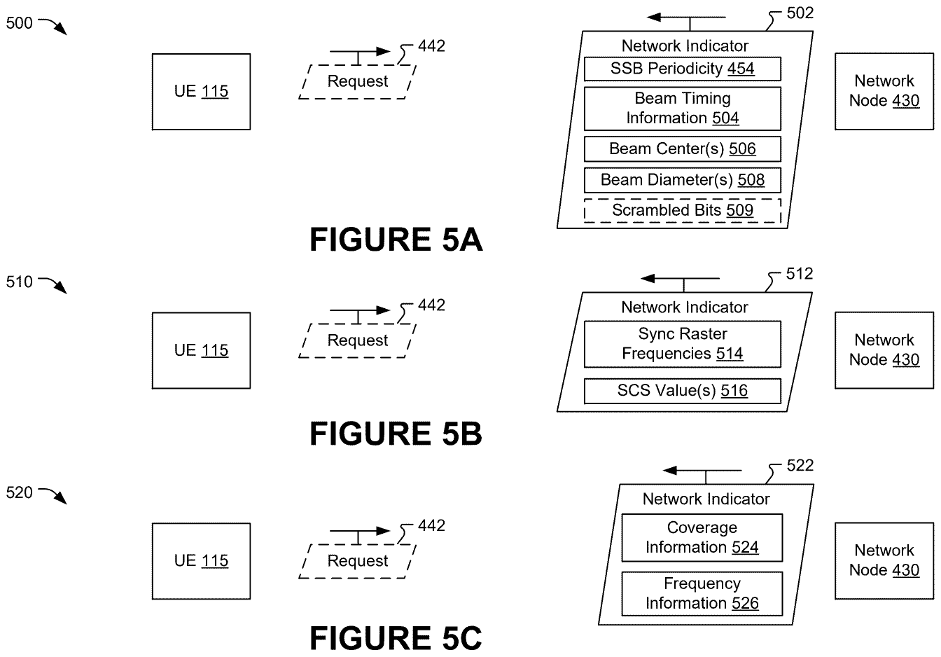

In some implementations, the network indicator 440 includes or indicates coverage information associated with the second wireless network. For example, the coverage information may include the SSB periodicity 454 and other beam information associated with the second wireless network, as further described herein with reference to FIG. 5A. Optionally, the coverage information may also include an indication of the timing information 458, the cell access information 460, or both, that are included in unscrambled portions of the PBCHs 472, 482 that are transmitted from the network node 450. In some implementations, the network indicator 440 includes or indicates frequency information associated with the second wireless network. For example, the frequency information may include one or more frequencies to be monitored during initial cell selection, as further described herein with reference to FIG. 5B. In some other implementations, the network indicator 440 includes coverage information and frequency information associated with the second wireless network, as further described herein with reference to FIG. 5C. In some implementations, the network node 450 may transmit information to the network node 430, such as the SSB periodicity 454, the timing information 458, the cell access information 460, other information, or a combination thereof, to enable the network node 430 to provide the network indicator 440 to the UE 115.

As described with reference to FIG. 4, the wireless communication system 400 supports PBCH scrambling and soft combining for supporting larger SSB periodicities. For example, in contrast to typical wireless networks in which the SSB periodicity for initial cell selection is set at a fixed value of once per 20 ms, the wireless communication system 400 can support larger SSB periodicities, such as by the SSB periodicity 454 being once per 40 ms, once per 80 ms, or once per 160 ms, as non-limiting examples. Increasing the SSB periodicity 454 reduces the frequency of SSB transmissions by the network node 450 and thus reduces power consumption at the network node 450, which may be beneficial to NTN nodes or other types of wireless network nodes that do not have access to fixed power supplies.

Additionally, because the unscrambled portions 478, 488 are selected or determined in accordance with the SSB periodicity 454 and the MIB periodicity 456, instead of being fixed in accordance with a single fixed SSB periodicity for both the first wireless network and the second wireless network, these larger SSB periodicities can be supported without increasing the difficulty of the soft combining process at the UE 115. For example, instead of one or more bits being different between the scrambled portion 476 and the scrambled portion 486 due to use of a larger SSB periodicity, the bits of the PBCHs 472, 482 to which the scrambling process is applied by the network node 450 to generate the scrambled portions 476, 486 and the unscrambled portions 478, 488 can be selected in accordance with the SSB periodicity 454 and the MIB periodicity 456. In this manner, time-varying bits of the PBCHs 472, 482 are not scrambled and are included in the unscrambled portions 478, 488. The UE 115 may similarly identify the unscrambled portions 478, 488 during the soft combining process in accordance with the SSB periodicity 454 and the MIB periodicity 456. Additionally, initializing a scrambling sequence and selecting a portion of the scrambling sequence to be applied to the PBCH payloads to generate the PBCHs 472, 482 may increase the randomness of the PBCHs 472, 482, which may reduce interference caused by the PBCHs 472, 482 to one or more other wireless devices, such as one or more UEs in a neighboring cell. Additionally, aspects of decoding a single PBCH, including selection of the scrambling sequence and identification of the initialization time associated with a scrambling sequence, can be determined by the UE 115 in accordance with the unscrambled portions 478, 488 and/or the SSB periodicity 454, thereby enabling the UE 115 to correctly decode and descramble the PBCHs 472, 482 that are included in the SSBs 470, 480 and thus to support SSB periodicities beyond the single fixed SSB periodicity supported by other wireless networks.

Additionally, or alternatively, some implementations of the wireless communication system 400 enable a first wireless network, such as a TN that includes the network node 430, to advertise initial cell selection parameters of a second wireless network, such as an NTN that includes the network node 450, in a manner that shortens initial cell selection delay for the UE 115 to join the second wireless network. For example, the network node 430 may provide the UE 115 with the network indicator 440, such as in a SIB, a MAC-CE, or a RRC message, that indicates coverage and/or frequency information associated with the second wireless network, as further described herein with reference to FIGS. 5A-5C. Accordingly, the UE 115 may leave the coverage area of the first wireless network, which may be a TN, and may more quickly search for and discover the second wireless network, which may be an NTN cell, thereby consuming less power, even though the second wireless network may support a different SSB periodicity than the first wireless network, different beams, different raster frequencies, or the like.

FIGS. 5A-5C are block diagrams illustrating examples of a network node providing information associated with a different wireless network to a UE in accordance with the present disclosure. For example, as described with reference to FIG. 4, the network node 430 that is included in the first wireless network may provide an indicator of information associated with a different, second wireless network that does not include the network node 430. FIG. 5A depicts an example 500 in which the network node 430 provides an indicator of coverage information for the second wireless network. FIG. 5B depicts an example 510 in which the network node 430 provides an indicator of frequency information for the second wireless network. FIG. 5C depicts an example 520 in which the network node 430 provides an indicator of coverage information and frequency information for the second wireless network. In some implementations, the indicator of various information for the second wireless network in FIGS. 5A-5C may include or correspond to the network indicator 440 of FIG. 4. Additionally, or alternatively, the first wireless network that includes the network node 430 may include or correspond to a TN, and the second wireless network may include the network node 450 and may include or correspond to an NTN.

In the example 500 illustrated in FIG. 5A, prior to the UE 115 receiving any SSBs from the network node 450, the network node 430 transmits a network indicator 502 to the UE 115, optionally in accordance with receiving the request 442 from the UE 115. The network indicator 502 represents an indicator of coverage information associated with the second wireless network. In some implementations, the coverage information indicated by the network indicator 502 includes the SSB periodicity 454 associated with the second wireless network, beam timing information 504 associated with the second wireless network, one or more beam centers 506 associated with the second wireless network, one or more beam diameters 508 associated with the second wireless network, or a combination thereof. The beam timing information 504 includes timing associated with transmission of one or more SSB beams or other types of beams transmitted by the network node 450. The beam centers 506 indicate coordinates or location information associated with one or more SSB beams or other types of beams transmitted by the network node 450. The beam diameters 508 indicate diameters associated with one or more SSB beams or other types of beams transmitted by the network node 450. In some implementations, the coverage information indicated by the network indicator 502 also includes an indication of scrambled bits 509, which include or correspond to one or more bits of the timing information 458, one or more bits of the cell access information 460, or both, that are included in unscrambled portions of PBCHs.

By transmitting the network indicator 502 to the UE 115, the network node 430 provides the UE 115 with parameters associated with the second wireless network that the UE 115 would otherwise have to communicate with the network node 450 to determine. Additionally, other types of signaling or messaging from the network node 430 or network node 450 do not provide such information. For example, although the network node 430 may be configured to provide timing information associated with a neighboring cell during an SSB measurement timing configuration (SMTC) window, the timing information that is provided is not associated with initial cell selection at another cell. Instead, the network node 430 may provide the network indicator 502 to the UE 115 before the UE 115 begins an initial search for the second wireless network.

In an example in which the first wireless network is a TN and the second wireless network is an NTN, the TN can indicate to UEs that support both TN and NTN functionality about the SSB periodicity for initial cell selection of a nearby NTN network. This indication, the network indicator 502, may include the NTN coverage information such as the beam timing information 504, the beam centers 506, and/or the beam diameters 508 of beam footprint(s) of one or more satellite beams, as well as the SSB periodicity 454 to be applied by the NTN network. Additionally, or alternatively, the TN network may indicate the bits that are skipped in the first scrambling performed before channel coding in the network indicator 502, such as by including the scrambled bits 509, or UEs such as the UE 115 can derive the information in accordance with the SSB periodicity 454 indicated for initial cell selection for NTN. Providing the UE 115 with the SSB periodicity 454 or the scrambled bits 509 enables the UE 115 to use a larger SSB periodicity than associated with the first wireless network, which otherwise may result in the UE 115 soft combining noise received in a time interval of an expected SSB (due to the incorrect SSB periodicity) or performing additional hypothesis testing on potentially absent SSB(s), thereby degraded decoding performance or requiring a higher decoder complexity.

In the example 510 illustrated in FIG. 5B, prior to the UE 115 receiving any SSBs from the network node 450, the network node 430 transmits a network indicator 512 to the UE 115, optionally in accordance with receiving the request 442 from the UE 115. The network indicator 512 represents an indicator of frequency information associated with the second wireless network. In some implementations, the frequency information indicated by the network indicator 512 includes sync raster frequencies 514 associated with the second wireless network, one or more sub-carrier spacing (SCS) values 516 associated with the second wireless network, or a combination thereof. The sync raster frequencies 514 indicate one or more frequency ranges covered by the second wireless network, and the SCS values 516 indicate sub-carrier spacing between frequencies. In some implementations, the network indicator 512 includes an absolute radio frequency channel number (ARFCN) that indicates the sync raster frequencies 514. For example, a particular value of an ARFCN included in the network indicator 512 may be interpreted by the UE 115 as an indication that one or more particular frequencies that map to the particular value of the ARFCN are raster frequencies associated with the second wireless network.

In an example in which the first wireless network is a TN and the second wireless network is an NTN, the TN can indicate to UEs that support both TN and NTN functionality about the frequency information associated with a nearby NTN network to prevent the UEs from searching all available synch raster frequencies. This indication, the network indicator 512, may include the NTN frequency coverage information such as the sync raster frequencies 514 and/or the SCS values 516 of one or more NTN carriers. Providing the UE 115 with the particular raster frequency and/or SCS value can compensate for the increase to the average SSB decoding time caused by the NTN using a larger SSB periodicity. Because the TN cell size is typically small compared to the size of an NTN cell, the network node 430 can be tasked with storing information about which satellites may potentially cover area surrounding the UE 115 (or another UE within the coverage range).

In the example 520 illustrated in FIG. 5C, prior to the UE 115 receiving any SSBs from the network node 450, the network node 430 transmits an network indicator 522 to the UE 115, optionally in accordance with receiving the request 442 from the UE 115. The network indicator 522 represents an indicator of beam coverage information and frequency information associated with the second wireless network. For example, the network indicator 522 includes coverage information 524 and frequency information 526. The coverage information 524 may include the SSB periodicity 454 and the beam timing information 504, the beam centers 506, the beam diameters 508, or a combination thereof, as described with reference to FIG. 5A. In some implementations, the coverage information 524 optionally includes the scrambled bits 509. The frequency information 526 includes the sync raster frequencies 514, the SCS values 516, or both, as described with reference to FIG. 5B. Providing both the coverage information 524 and the frequency information 526 in the network indicator 522 to the UE 115 may reduce the initial cell access time more than providing either the network indicator 502 or the network indicator 512 individually.

FIG. 6 is a diagram illustrating an example of PBCH payload scrambling in accordance with the present disclosure. In some implementations, the PBCH payload scrambling illustrated in FIG. 6 may include or correspond to the PBCH scrambling performed by the network node 450 of FIG. 4 to generate the scrambled portion 476 and the unscrambled portion 478 of the PBCH 472, the scrambled portion 486 and the unscrambled portion 488 of the PBCH 482, or both.

Prior to any scrambling, a pre-scrambling PBCH payload 600 includes multiple fields of information associated with finding and decoding SIB1 messages. For example, the pre-scrambling PBCH payload 600 may include an SFN portion 602, an SCS value 604, an SSB-subcarrier offset 606, a DMRS-TypeA-position 608, a PDCCH-ConfigSIB1 610, a cell barred bit 612, an intra-frequency reselection bit 614, an SFN portion 616, a half frame bit 617, an SCS offset 618, and one or more reserved bits 619. In some examples, the SFN is 10 bits, the SFN portion 602 includes the 6 most significant bits (MSBs) of the SFN, and the SFN portion 616 includes the 4 LSBs of the SFN. The SCS offset 618 may include or correspond to a MSB of K_{SSB}, which represents a subcarrier offset of the SSB in one or more wireless communication specifications such as a 3GPP specification. The pre-scrambling PBCH payload 600 may include an MIB and additional fields, with the MIB including the bits or fields 602-614 and the additional fields including the bits or fields 616-619. For some typical wireless networks, first scrambling is applied to the bits and fields 602-614 and 617-619 as well as to the SFN portion 616 except that the second LSB and the third LSB of the SFN portion 616 are skipped. This is because the SSB periodicity is typically fixed at once per 20 ms and the MIB periodicity is typically fixed at once per 80 ms, such that, for four transmissions of a PBCH payload during an MIB period, the only bits that are different in each of the four instances of the PBCH payloads are the second and third LSB of the SFN portion 616, which proceed according to the following pattern: 00-01-10-11, due to the SFN portion 616 being incremented once per 10 ms.

Because larger SSB periodicities are supported, a partially scrambled PBCH payload 620 that is generated prior to channel encoding does not include only the second LSB and the third LSB as unscrambled bits. Instead, the scrambling applied to the pre-scrambling PBCH payload 600 causes the partially scrambled PBCH payload 620 to be generated, which includes a scrambled or partially scrambled MIB. The partially scrambled PBCH payload 620 includes a scrambled portion 622 and an unscrambled portion 624. The unscrambled portion 624 includes one or more fields or bits that are selected in accordance with the SSB periodicity and the MIB periodicity, such as the SSB periodicity 454 and the MIB periodicity 456 of FIG. 4. For example, the unscrambled portion 624 may include one or more bits of the SFN portion 602, the cell barred bit 612, the intra-frequency reselection bit 614, one or more bits of the SFN portion 616, or a combination thereof, and the scrambled portion 622 may include the SCS value 604, the SSB-subcarrier offset 606, the DMRS-TypeA-position 608, and the PDCCH-ConfigSIB1 610, as well as the remaining bits or fields that are not included in the unscrambled portion 624.

As an example, the unscrambled portion 624 may include the third LSB and the fourth LSB of the SFN portion 616, the cell barred bit 612, and the intra-frequency reselection bit 614, and the remainder of the SFN portion 616 and the SFN portion 602 may be included in the scrambled portion 622, as further described herein with reference to FIG. 7A. As another example, the unscrambled portion 624 may include the fourth LSB of the SFN portion 616 and the fifth LSB of the SFN portion 602, the cell barred bit 612, and the intra-frequency reselection bit 614, and the remainder of the SFN portion 602 and the SFN portion 616 may be included in the scrambled portion 622, as further described herein with reference to FIG. 7B. As another example, the unscrambled portion 624 may include the fifth LSB and the sixth LSB of the SFN portion 602, the cell barred bit 612, and the intra-frequency reselection bit 614, and the remainder of the SFN portion 602 and the SFN portion 616 may be included in the scrambled portion 622, as further described herein with reference to FIG. 7C. In other examples, one or more of the cell barred bit 612 or the intra-frequency reselection bit 614 may be included in the scrambled portion 622 if these bits do not vary between a sequence of transmitted PBCHs. In other examples, other bits of the SFN portion 602, other bits of the SFN portion 616, or both, may be included in the unscrambled portion 624 if those bits are different between consecutive instances of PBCH payloads, such as due to the difference between the SSB periodicity and the MIB periodicity.

FIGS. 7A-7C are timing diagrams illustrating examples of PBCH payload scrambling and timing in accordance with the present disclosure. FIGS. 7A-7C respectively illustrate timing associated with multiple PBCH payloads that are soft combined by a UE, such as the lower-capability UEs 115 of FIG. 4. The PBCH payloads respectively contain multiple MIBs, the PBCH payloads are respectively included in multiple SSBs, and the multiple SSBs are transmitted in accordance with different SSB periodicities in the different Figures. In some implementations, PBCH payloads illustrated in FIGS. 7A-7C include or correspond to the PBCH 472 and the PBCH 482 of FIG. 4, the partially scrambled PBCH payload 620, or a combination thereof.

FIG. 7A depicts an example 700 in which four PBCH payloads are received by a UE for soft combining as part of a decoding process. In the example 700, the four PBCH payloads include a PBCH payload 702, a PBCH payload 704, a PBCH payload 706, and a PBCH payload 708. Each of the PBCH payloads may include a respective unscrambled portion and a respective scrambled portion. Each unscrambled portion may include one or more bits of a respective SFN, and optionally cell access information (not shown in FIG. 7A), and each scrambled portion includes one or more non-selected bits of the respective SFN and a remainder of the respective PBCH payload. For example, the PBCH payload 702 includes an unscrambled portion 710, the PBCH payload 704 includes an unscrambled portion 712, the PBCH payload 706 includes an unscrambled portion 714, and the PBCH payload 708 includes an unscrambled portion 716, and the remaining bits of the PBCH payloads 702-708 respectively make up the scrambled portions after performance of one or more scrambling operations.

The unscrambled portions 710-716 include one or more selected bits of timing information, such as an SFN, of the respective PBCH payloads. These bits of the SFN are selected or identified in accordance with an MIB period 734 and an SSB period 736. In the example 700 illustrated in FIG. 7A, a value of the MIB period 734 is 80 ms, a value of the SSB period 736 is 40 ms, and the SFN is incremented once every 10 ms. Accordingly, if the six LSBs (a₅-a₀) of the SFN in the PBCH payload 702 have values of zero, the values of the six LSBs of the SFN in the PBCH payload 704 have the value “000100” because the PBCH payload 704 is transmitted 40 ms after the PBCH payload 702. In some examples, the SFN may include a first portion that is included in a respective MIB of the PBCH payload and a second portion that is included in the PBCH payload portion that excludes the MIB. As a particular example, the six MSBs of the SFN may be included in the MIB and the four LSBs may be included in the non-MIB portion. In other examples, the SFN may be divided differently between the MIB and the non-MIB portion, or the SFN may be entirely included in the MIB.

In this example, at time t0, the first LSB (a₀) has a value of zero and the second LSB (a₁) has a value of zero, and these values are included in the PBCH payload 702. At time t0+10 ms, the value of the first LSB transitions to one. At time t0+20 ms, the value of the first LSB returns to zero and the value of the second LSB transitions to one. At time t0+30 ms, the value of the second LSB transitions to one. At time t0+40 ms, the first LSB returns to the zero, the second LSB returns to zero, a third LSB 730 (a₂) transitions to one, and a fourth LSB 732 (a₃) has a value of zero, and these values are included in the PBCH payload 704. This process of bit transitions associated with the first LSB and the second LSB of the SFN repeats during the next 40 ms, such that at time t0+80 ms, the third LSB 730 returns to zero and the fourth LSB 732 transitions to one, and these values are included in the PBCH payload 706. Similarly, at time t0+120 ms, the third LSB 730 transitions to one and the fourth LSB 732 remains one, and these values are included in the PBCH payload 708. As can be appreciated, if four PBCH payloads are to be soft combined, the third LSB 730 and the fourth LSB 732 change values in the instances of the PBCH payloads 702-708.

Additionally, in the example 700, the PBCH payloads 702-708 are transmitted as pairs during consecutive MIB periods. In this example, because the MIB period 734 is twice as long as the SSB period 736, SSBs are transmitted twice for each MIB period. For example, the PBCH payload 702 and the PBCH payload 704 are transmitted during a first MIB period 720, and the PBCH payload 706 and the PBCH payload 708 are transmitted during a second MIB period 722 that occurs consecutively after the first MIB period 720.

Because the third LSB 730 and the fourth LSB 732 are the only bits of the SFN that are time varying with respect to the PBCH payloads 702-708 associated with transmission during the MIB periods 720, 722, each of the unscrambled portions 710-716 include the values of the third LSB 730 and the fourth LSB 732 in the respective PBCH payload. For example, the unscrambled portion 710 includes “00”, the unscrambled portion 712 includes “01”, the unscrambled portion 714 includes “10”, and the unscrambled portion 716 includes “11”. As such, these bits may be omitted from the first scrambling process that is applied to the other bits of the PBCH payloads 702-708 prior to channel coding, such as polar encoding, to generate the respective coded PBCHs, as described above with reference to FIG. 4. In this example, because the third LSB 730 and the fourth LSB 732 are included in the respective portion of the PBCH payloads 702-708 that is excluded from the MIB, an entirety of the MIB can be included in the scrambled portion of the respective PBCH payload.

FIG. 7B depicts an example 740 in which in which four PBCH payloads are received by a UE for soft combining as part of a decoding process. In the example 740, the four PBCH payloads include a PBCH payload 742, a PBCH payload 744, a PBCH payload 746, and a PBCH payload 748. Each of the PBCH payloads may include a respective unscrambled portion and a respective scrambled portion. Each unscrambled portion may include one or more bits of a respective SFN, and optionally cell access information (not shown in FIG. 7B), and each scrambled portion includes one or more non-selected bits of the respective SFN and a remainder of the respective PBCH payload. For example, the PBCH payload 742 includes an unscrambled portion 750, the PBCH payload 744 includes an unscrambled portion 752, the PBCH payload 746 includes an unscrambled portion 754, and the PBCH payload 748 includes an unscrambled portion 756, and the remaining bits of the PBCH payloads 742-748 respectively make up the scrambled portions after performance of one or more scrambling operations.

The unscrambled portions 750-756 include one or more selected bits of timing information, such as an SFN, of the respective PBCH payloads. These bits of the SFN are selected or identified in accordance with an MIB period 768 and an SSB period 769. In the example 740 illustrated in FIG. 7B, a value of the MIB period 768 is 80 ms, a value of the SSB period 769 is 80 ms, and the SFN is incremented once every 10 ms. Accordingly, if the six LSBs (a₅-a₀) of the SFN in the PBCH payload 742 have values of zero, the values of the six LSBs of the SFN in the PBCH payload 744 have the value “001000” because the PBCH payload 744 is transmitted 80 ms after the PBCH payload 742. As described with reference to FIG. 7A, the bits of the SFN follow similar patterns based on the SFN being incremented every 10 ms. In this example, at time t0, a fourth LSB 766 (a₃) has a value of zero and a fifth LSB 767 (a₄) has a value of zero, and the value “000000” is included in the PBCH payload 742. At time t0+800 ms, the fourth LSB 766 transitions to one and the fifth LSB 767 has a value of zero, and the value “001000” is included in the PBCH payload 744. The process of bit transitions associated with the first-third LSBs of the SFN repeats during the next 80 ms, such that at time t0+160 ms, the fourth LSB 766 returns to zero and the fifth LSB 767 transitions to one, and the value “010000” is included in the PBCH payload 746. Similarly, at time t0+240 ms, the fourth LSB 766 transitions to one and the fifth LSB 767 remains one, and the value “011000” is included in the PBCH payload 748. As can be appreciated, if four PBCH payloads are to be soft combined, the fourth LSB 766 and the fifth LSB 767 change values in the instances of the PBCH payloads 742-748.

Additionally, in the example 740, the PBCH payloads 742-748 are transmitted individually during consecutive MIB periods. In this example, because the MIB period 768 is the same as the SSB period 769, SSBs are transmitted once for each MIB period. For example, the PBCH payload 742 is transmitted during a first MIB period 758, the PBCH payload 744 is transmitted during a second MIB period 760, the PBCH payload 746 is transmitted during a third MIB period 762, and the PBCH payload 748 is transmitted during a fourth MIB period 764, each of which occur in a consecutive sequence during the MIB periods 758-764.

Because the fourth LSB 766 and the fifth LSB 767 are the only bits of the SFN that are time varying with respect to the PBCH payloads 742-748 associated with transmission during the MIB periods 758-764, each of the unscrambled portions 750-756 include the values of the fourth LSB 766 and the fifth LSB 767 in the respective PBCH payload. For example, the unscrambled portion 750 includes “00”, the unscrambled portion 752 includes “01”, the unscrambled portion 754 includes “10”, and the unscrambled portion 756 includes “11”. Additionally, or alternatively, the unscrambled portions 750-756 may include cell access information that changes during the MIB periods 758-764. As such, these bits may be omitted from the first scrambling process that is applied to the other bits of the PBCH payloads 742-748 prior to channel coding, such as polar encoding, to generate the respective PBCHs, as described above with reference to FIG. 4. In this example, because the fourth LSB 766 is included in the portion that is excluded from the MIB of the respective PBCH payload and the fifth LSB 767 is included in the MIB of the respective PBCH payload, a portion of the MIB and a non-MIB portion can be included in the scrambled portion of the respective PBCH payload.

FIG. 7C depicts an example 770 in which in which in which four PBCH payloads are received by a UE for soft combining as part of a decoding process. In the example 770, the four PBCH payloads include a PBCH payload 772, a PBCH payload 774, a PBCH payload 776, and a PBCH payload 778. Each of the PBCH payloads may include a respective unscrambled portion and a respective scrambled portion. Each unscrambled portion may include one or more bits of a respective SFN, and optionally cell access information (not shown in FIG. 7C), and each scrambled portion includes one or more non-selected bits of the respective SFN and a remainder of the respective PBCH payload. For example, the PBCH payload 772 includes an unscrambled portion 780, the PBCH payload 774 includes an unscrambled portion 782, the PBCH payload 776 includes an unscrambled portion 784, and the PBCH payload 778 includes an unscrambled portion 786, and the remaining bits of the PBCH payloads 772-778 respectively make up the scrambled portions after performance of one or more scrambling operations.

The unscrambled portions 780-786 include one or more selected bits of timing information, such as an SFN, of the respective PBCH payloads. These bits of the SFN are selected or identified in accordance with an MIB period 798 and an SSB period 799. In the example 770 illustrated in FIG. 7C, a value of the MIB period 798 is 80 ms, a value of the SSB period 799 is 160 ms, and the SFN is incremented once every 10 ms. Accordingly, if the six LSBs (a₅-a₀) of the SFN in the PBCH payload 772 have values of zero, the values of the six LSBs of the SFN in the PBCH payload 774 have the value “010000” because the PBCH payload 774 is transmitted 160 ms after the PBCH payload 772. As described with reference to FIG. 7A, the bits of the SFN follow similar patterns based on the SFN being incremented every 10 ms. In this example, at time t0, a fifth LSB 796 (a₄) has a value of zero and a sixth LSB 797 (a₅) has a value of zero, and the value “000000” is included in the PBCH payload 772. At time t0+160 ms, the fifth LSB 796 transitions to one and the sixth LSB 797 has a value of zero, and the value “010000” is included in the PBCH payload 774. The process of bit transitions associated with the first-fourth LSBs of the SFN repeats during the next 160 ms, such that at time t0+320 ms, the fifth LSB 796 returns to zero and the sixth LSB 797 transitions to one, and the value “100000” is included in the PBCH payload 776. Similarly, at time t0+480 ms, the fifth LSB 796 transitions to one and the sixth LSB 797 remains one, and the value “110000” is included in the PBCH payload 778. As can be appreciated, if four PBCH payloads are to be soft combined, the fifth LSB 796 and the sixth LSB 797 change values in the instances of the PBCH payloads 772-778.

Additionally, in the example 770, the PBCH payloads 772-778 are transmitted individually during consecutive pairs of MIB periods. In this example, because the SSB period 799 is twice as long as the MIB period 798, SSBs are transmitted once for every two MIB periods. For example, the PBCH payload 772 is transmitted during a first MIB period 788, the PBCH payload 774 is transmitted during a third MIB period 790, the PBCH payload 776 is transmitted during a fifth MIB period 792, and the PBCH payload 778 is transmitted during a seventh MIB period 794, each of which occur in a sequence during the MIB periods 788-794.

Because the fifth LSB 796 and the sixth LSB 797 are the only bits of the SFN that are time varying with respect to the PBCH payloads 772-778 associated with transmission during the MIB periods 788-784, each of the unscrambled portions 780-786 include the values of the fifth LSB 796 and the sixth LSB 797 in the respective PBCH payload. For example, the unscrambled portion 780 includes “00”, the unscrambled portion 782 includes “01”, the unscrambled portion 784 includes “10”, and the unscrambled portion 786 includes “11”. Additionally, or alternatively, the unscrambled portions 780-786 may include cell access information that changes during the MIB periods 788-794. As such, these bits may be omitted from the first scrambling process that is applied to the other bits of the PBCH payloads 772-778 prior to channel coding, such as polar encoding, to generate the respective PBCHs, as described above with reference to FIG. 4. In this example, because the fifth LSB 796 and the sixth LSB 797 are included in the MIB of the respective PBCH payload, a portion of the MIB and can be included in the scrambled portion of the respective PBCH payload without including any of the non-MIB portion.

FIG. 8 is a flow diagram illustrating an example process 800 that supports PBCH scrambling and soft combining in accordance with the present disclosure, and FIG. 9 is a flow diagram illustrating an example process 900 that supports PBCH scrambling and soft combining in accordance with the present disclosure. Operations of the process 800, the process 900, or both, may be performed by a UE, such as the UE 115 described above with reference to FIGS. 1-5C. For example, example operations (also referred to as “blocks”) of the process 800, the process 900, or both, may enable the UE to support PBCH scrambling and soft combining, according to some aspects of the present disclosure.

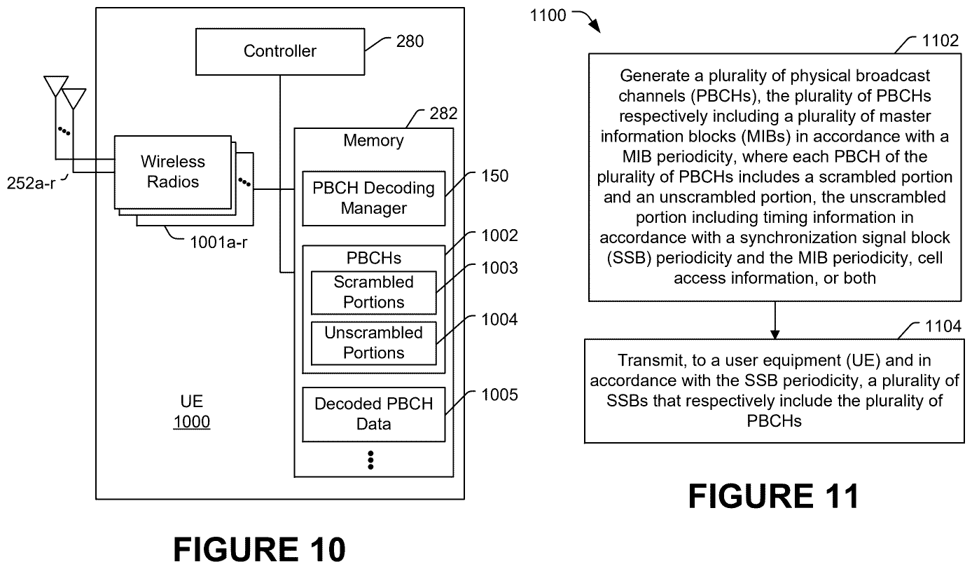

FIG. 10 is a block diagram of an example UE 1000 that supports PBCH scrambling and soft combining in accordance with the present disclosure. The UE 1000 may be configured to perform operations, including the blocks of the process 800 described with reference to FIG. 8, the blocks of the process 900 described with reference to FIG. 9, or both, to support PBCH scrambling and soft combining. In some implementations, the UE 1000 includes the structure, hardware, and components shown and described with reference to the UE 115 of FIGS. 1-5C. For example, the UE 1000 includes the controller 280, which operates to execute logic or computer instructions stored in the memory 282, as well as controlling the components of the UE 1000 that provide the features and functionality of the UE 1000. The UE 1000, under control of the controller 280, transmits and receives signals via wireless radios 1001a-r and the antennas 252a-r. The wireless radios 1001a-r include various components and hardware, as illustrated in FIG. 2 for the UE 115, including the modems 254 a-r, the MIMO detector 256, the receive processor 258, the transmit processor 264, and the TX MIMO processor 266.

As shown, the memory 282 may include the PBCH decoding manager 150, multiple PBCHs 1002 (received PBCH payloads), and decoded PBCH data 1005. The PBCHs 1002 include scrambled portions 1003 and unscrambled portions 1004. Although illustrated in FIG. 10 as being included in the memory 282, in other implementations, the PBCH decoding manager 150 may be a separate component of the UE 1000. The PBCH decoding manager 150 may be configured to manage one or more operations supporting PBCH scrambling and soft combining, such as identifying timing information included in the unscrambled portions 1004 and soft combining PBCHs 1002 in accordance with the timing information to generate the decoded PBCH data 1005. The PBCHs 1002 may include or correspond to the PBCH 472 and the PBCH 482 of FIG. 4. The scrambled portions 1003 may include or correspond to the scrambled portion 476 and the scrambled portion 486 of FIG. 4, and the unscrambled portions 1004 may include or correspond to the unscrambled portion 478 and the unscrambled portion 488 of FIG. 4. The decoded PBCH data 1005 may include or correspond to the decoded PBCH data 410 of FIG. 4. The UE 1000 may receive signals from or transmit signals to one or more network nodes, such as the network node 105 of FIGS. 1-3, the network node 430 of FIGS. 4-5C, the network node 450 of FIG. 4, or a network node as illustrated in FIG. 13.

Referring back to the process 800 of FIG. 8, in block 802, the UE 1000 receives, from a network node, a plurality of SSBs in accordance with an SSB periodicity. For example, the plurality of SSBs may include or correspond to the SSB 470 and the SSB 480 received from the network node 450 in accordance with the SSB periodicity 454. The plurality of SSBs respectively include a plurality of PBCHs. For example, SSB 470 includes the PBCH 472 and the SSB 480 includes the PBCH 482. The plurality of PBCHs respectively include a plurality of MIBs in accordance with a MIB periodicity. For example, the PBCH 472 includes the MIB 474 and the PBCH 482 includes the MIB 484. Each PBCH of the plurality of PBCHs includes a scrambled portion and an unscrambled portion, the unscrambled portion including timing information in accordance with the SSB periodicity and the MIB periodicity, cell access information, or both. For example, the PBCH 472 includes the scrambled portion 476 and the unscrambled portion 478, and the PBCH 482 includes the scrambled portion 486 and the unscrambled portion 488. The unscrambled portions 478, 488 may include one or more bits of the timing information 458, the cell access information 460, or both. In some implementations, for each unscrambled portion of the plurality of PBCHs, the timing information includes at least a fourth LSB of a SFN, a fifth LSB of the SFN, or a sixth LSB of the SFN, as further described above with reference to FIGS. 7A-7C. Additionally, or alternatively, the cell access information in each of the unscrambled portions of the plurality of PBCHs may include at least one of a respective cell barred bit and a respective intra-frequency reselection bit. For example, the cell barred bit may include or correspond to the cell barred bit 612 and the intra-frequency reselection bit may include or correspond to the intra-frequency reselection bit 614 of FIG. 6.

In block 804, the UE 1000 decodes the plurality of PBCHs by soft combining the PBCHs in accordance with the timing information, the cell access information, or both. For example, the PBCH 472 and the PBCH 482 may be decoded by soft combining the PBCHs 472, 482 in accordance with the timing information, the cell access information, or both, that are included in the unscrambled portion 478 and the unscrambled portion 488. The UE 115 may identify which bits are included in the unscrambled portion 478 and the unscrambled portion 488 in accordance with the SSB periodicity 454 and the MIB periodicity 456.

In some implementations, soft combining a first PBCH and a second PBCH of the plurality of PBCHs includes: calculating a difference between the respective unscrambled portion of the first PBCH and the respective unscrambled portion of the second PBCH, adjusting a LLR value associated with the second PBCH in accordance with the difference, and decoding the first PBCH and the second PBCH in accordance with the adjusted LLR value associated with the second PBCH. For example, the difference may include or correspond to one of the difference values 406, the LLR may include or correspond to one of the LLR values 408, and the decoding may generate the decoded PBCH data 410, as described with reference to FIG. 4.

In some implementations, the SSB periodicity is 40 ms, the MIB periodicity is 80 ms, and for each unscrambled portion of the plurality of PBCHs, the timing information includes a third LSB of a SFN and a fourth LSB of the SFN. Such an example is further described above with reference to FIG. 7A. In some other implementations, the SSB periodicity is 80 ms or 160 ms, the MIB periodicity is 80 ms, the plurality of SSBs is received over at least two MIB periods associated with the MIB periodicity, and the timing information includes two of: a fourth LSB of a SFN, a fifth LSB of the SFN, or a sixth LSB of the SFN. Such examples are further described above with reference to FIG. 7B and FIG. 7C.

In some implementations, the process 800 includes, prior to receiving the plurality of SSBs, receiving, from a different network node of a first wireless network, an indicator of coverage information associated with a second wireless network. The second wireless network includes the network node. For example, the UE 115 may receive the network indicator 440 from the network node 430 prior to receiving any of the SSBs 470, 480 from the network node 450. The coverage information includes the SSB periodicity and beam timing information associated with the second wireless network, one or more beam centers associated with the second wireless network, one or more beam diameters associated with the second wireless network, or a combination thereof. For example, the network indicator 440 may include or correspond to the network indicator 502 of FIG. 5A that includes the SSB periodicity 454 and at least one of the beam timing information 504, the beam centers 506, and the beam diameters 508, or the coverage information 524 of FIG. 5C may include the SSB periodicity 454 and at least one of the beam timing information 504, the beam centers 506, and the beam diameters 508. In such implementations, the process 800 also includes performing an initial connection procedure with the second wireless network in accordance with the coverage information. Receipt of the plurality of SSBs occurs during the initial connection procedure. For example, the UE 115 may perform an initial connection procedure with the network node 450 that includes receiving the SSBs 470, 480, and optionally transmitting the initial access messaging 490 of FIG. 4.

In some such implementations in which the indicator of coverage information associated with the second wireless network is received at the UE 1000, the indicator is included in a SIB, a MAC-CE, or a RRC message, as further explained above with reference to FIG. 4. In such implementations, the first wireless network may include a TN and the second wireless network may include an NTN. For example, the network node 430 may be included in a TN and the network node 450 may be included in an NTN, in some examples. Additionally, or alternatively, the coverage information may further include an indication of the timing information. For example, the network indicator 502 of FIG. 5A may include the scrambled bits 509.

In some implementations, the process 800 includes, prior to receiving the plurality of SSBs, receiving, from a different network node of a first wireless network, an indicator of frequency information associated with a second wireless network. For example, the UE 115 may receive the network indicator 440 from the network node 430 prior to receiving any of the SSBs 470, 480 from the network node 450. The second wireless network includes the network node, and the frequency information includes a raster frequency associated with the second wireless network, an SCS value associated with the second wireless network, or a combination thereof. For example, the network indicator 440 may include or correspond to the network indicator 512 of FIG. 5B that includes the sync raster frequencies 514, the SCS values 516, or both, or the frequency information 526 of FIG. 5C may include the sync raster frequencies 514, the SCS values 516, or both. In such implementations, the process 800 also includes performing an initial connection procedure with the second wireless network in accordance with the frequency information. Receipt of the plurality of SSBs occurs during the initial connection procedure. For example, the UE 115 may perform an initial connection procedure with the network node 450 that includes receiving the SSBs 470, 480, and optionally transmitting the initial access messaging 490 of FIG. 4.

In some such implementations in which the indicator of frequency information associated with the second wireless network is received at the UE 1000, the frequency information may include an ARFCN that indicates the raster frequency. For example, the sync raster frequencies 514 may be an ARFCN that is included in the network indicator 512 to indicate the raster frequencies associated with the second wireless network. In such implementations, the indicator may be included in a SIB, a MAC-CE, or a RRC message, as further explained above with reference to FIG. 4. In such implementations, the first wireless network may include a TN and the second wireless network may include an NTN. For example, the network node 430 may be included in a TN and the network node 450 may be included in an NTN, in some examples.

As described with reference to FIG. 8, the process 800 supports PBCH scrambling and soft combining for supporting larger SSB periodicities. For example, in contrast to typical wireless networks in which the SSB periodicity for initial cell selection is set at a fixed value for multiple types of wireless networks, the process 800 enables the UE 1000 to perform soft combining of PBCHs that are included in SSBs having larger SSB periodicities, such as once per 40 ms, once per 80 ms, or once per 160 ms, as non-limiting examples. Increasing the SSB periodicity reduces the frequency of SSB transmissions by a network node and thus reduces power consumption at the network node, which may be beneficial to NTN nodes or other types of wireless network nodes that do not have access to fixed power supplies.

Referring to the process 900 of FIG. 9, in block 902, the UE 1000 receives, from a network node, a plurality of SSBs in accordance with an SSB periodicity. For example, the plurality of SSBs may include or correspond to the SSB 470 and the SSB 480 received from the network node 450 in accordance with the SSB periodicity 454. The plurality of SSBs respectively include a plurality of PBCHs. For example, the SSB 470 includes the PBCH 472 and the SSB 480 includes the PBCH 482. The plurality of PBCHs respectively include a plurality of MIBs in accordance with a MIB periodicity. For example, the PBCH 472 includes the MIB 474 and the PBCH 482 includes the MIB 484.

In block 904, the UE 1000 decodes the plurality of PBCHs by soft combining the plurality of PBCHs to generate a plurality of scrambled PBCH payloads. For example, the PBCH 472 and the PBCH 482 may be decoded by soft combining the PBCHs 472, 482 to generate the scrambled portion 476, the unscrambled portion 478, the scrambled portion 486, and the unscrambled portion 488.

In block 906, for each scrambled PBCH payload of the plurality of scrambled PBCH payloads, the UE 1000 identifies a set of unscrambled bits of the scrambled PBCH payload in accordance with the SSB periodicity and the MIB periodicity. For example, the UE 115 may identify which bits are included in the unscrambled portion 478 and the unscrambled portion 488 in accordance with the SSB periodicity 454 and the MIB periodicity 456.

In block 908, for each scrambled PBCH payload of the plurality of scrambled PBCH payloads, the UE 1000 descrambles the scrambled PBCH payload in accordance with a portion of a scrambling sequence that is associated with the set of unscrambled bits. For example, the UE 115 may identify, for the scrambled portion 476 of the PBCH 472, a portion of a scrambling sequence indicated by the descrambling configuration 412 in accordance with the unscrambled portion 478. Similarly, the UE 115 may identify, for the scrambled portion 486 of the PBCH 482, a portion of a scrambling sequence indicated by the descrambling configuration 412 in accordance with the unscrambled portion 488.

In some implementations, soft combining a first PBCH and a second PBCH of the plurality of PBCHs includes: calculating a difference between the first PBCH and the second PBCH, adjusting a LLR value associated with the second PBCH in accordance with the difference, and decoding the first PBCH and the second PBCH in accordance with the adjusted LLR value associated with the second PBCH. For example, the difference may include or correspond to one of the difference values 406, the LLR may include or correspond to one of the LLR values 408, and the decoding may generate the scrambled portion 476 and the unscrambled portion 478 and/or the scrambled portion 486 and the unscrambled portion 488, as described with reference to FIG. 4.

In some implementations, for each scrambled PBCH payload of the plurality of scrambled PBCH payloads, the set of unscrambled bits includes one or more LSBs of timing information associated with the respective MIB included in the scrambled PBCH payload. For example, the unscrambled portions 478, 488 may include one or more LSBs of the timing information 458 that are associated with the MIBs 474, 484, respectively. In some implementations, the one or more LSBs of the timing information includes at least a fourth LSB of a SFN, a fifth LSB of the SFN, a sixth LSB of the SFN, or a combination thereof, as further described above with reference to FIGS. 7A-7C. Additionally, or alternatively, the SSB periodicity may be equal to 20*2ⁿ⁻¹, n may be a positive integer, and the one or more LSBs of the timing information may include an (n+1)th LSB of a SFN and an (n+2)th LSB of the SFN, as described with reference to FIG. 4.

In some implementations, the process 900 includes, for a scrambled PBCH payload of the plurality of scrambled PBCH payloads, identifying an initialization time associated with the scrambling sequence in accordance with the SSB periodicity. For example, the UE 115 may identify the initialization time associated with the scrambling sequence for the scrambled portion 476 of the PBCH 472 in accordance with the SSB periodicity 454. In some such implementations, n is a positive integer and the initialization time corresponds to a SFN associated with the respective MIB that satisfies mod(SFN, 2*2ⁿ⁺¹)=0, as further described above with reference to FIG. 4. In some such implementations, the initialization time corresponds to the SFN associated with the respective MIB that has a different value of a fourth LSB than a previous SFN, such as when n is two. Alternatively, the initialization time corresponds to the SFN associated with the respective MIB that has a different value of a fifth LSB than a previous SFN, such as when n is three.

In some implementations, the SSB periodicity is 40 ms, 80 ms, or 160 ms, and the MIB periodicity is 80 ms. Such examples are further described above with reference to FIGS. 7A-7C, respectively.

FIG. 11 is a flow diagram illustrating an example process 1100 that supports PBCH scrambling and soft combining in accordance with the present disclosure, and FIG. 12 is a flow diagram illustrating an example process 1200 that supports PBCH scrambling and soft combining in accordance with the present disclosure. Operations of the process 1100, the process 1200, or both, may be performed by a network node, such as the network node 105 described above with reference to FIGS. 1-3, the network node 430 of FIGS. 4-5C, or the network node 450 of FIG. 4. For example, example operations of the process 1100, the process 1200, or both, may enable a network node to support PBCH scrambling and soft combining.

FIG. 13 is a block diagram of an example network node 1300 that supports PBCH scrambling and soft combining in accordance with the present disclosure. The network node 1300 may be configured to perform operations, including the blocks of the process 1100 described with reference to FIG. 11, the blocks of the process 1200 described with reference to FIG. 12, or both, to support PBCH scrambling and soft combining. In some implementations, the network node 1300 includes the structure, hardware, and components shown and described with reference to the network node 105 of FIGS. 1-3, the network node 430 of FIGS. 4-5C, or the network node 450 of FIG. 4. For example, the network node 1300 may include the controller 240, which operates to execute logic or computer instructions stored in the memory 242, as well as controlling the components of the network node 1300 that provide the features and functionality of the network node 1300. The network node 1300, under control of the controller 240, transmits and receives signals via wireless radios 1301a-t and the antennas 234a-t. The wireless radios 1301a-t include various components and hardware, as illustrated in FIG. 2 for the network node 105, including the modems 232a-t, the transmit processor 220, the TX MIMO processor 230, the MIMO detector 236, and the receive processor 238.

As shown, the memory 242 may include the PBCH encoding manager 152, multiple PBCHs 1302, timing/cell access information 1305, an SSB periodicity 1306, and an MIB periodicity 1307. The PBCHs 1302 include scrambled portions 1303 and unscrambled portions 1304. Although illustrated in FIG. 13 as being included in the memory 242, in other implementations, the PBCH encoding manager 152 may be a separate component of the network node 1300. The PBCH encoding manager 152 may be configured to manage one or more operations supporting PBCH scrambling and soft combining, such as generating the PBCHs 1302 having the unscrambled portions that include portions of the timing/cell access information 1305, in addition to transmitting the PBCHs 1302, which contain multiple MIBs respectively, within multiple SSBs in accordance with the SSB periodicity 1306 and the MIB periodicity 1307. The PBCHs 1302 may include or correspond to the PBCH 472 and the PBCH 482 of FIG. 4. The scrambled portions 1303 may include or correspond to the scrambled portion 476 and the scrambled portion 486 of FIG. 4, and the unscrambled portions 1304 may include or correspond to the unscrambled portion 478 and the unscrambled portion 488 of FIG. 4. The timing/cell access information 1305 may include or correspond to the timing information 458, the cell access information 460, or both, of FIG. 4. The SSB periodicity 1306 may include or correspond to the SSB periodicity 454 of FIG. 4. The MIB periodicity 1307 may include or correspond to the MIB periodicity 456 of FIG. 4. The network node 1300 may receive signals from or transmit signals to one or more UEs, such as the UE 115 of FIGS. 1-5C or the UE 1000 of FIG. 10.

Referring back to the process 1100 of FIG. 11, in block 1102, the network node 1300 generates a plurality of PBCHs. For example, the network node 450 generates the PBCH 472 and the PBCH 482. The plurality of PBCHs respectively include a plurality of MIBs in accordance with a MIB periodicity. For example, the PBCH 472 includes the MIB 474 and the PBCH 482 includes the MIB 484. Each PBCH of the plurality of PBCHs includes a scrambled portion and an unscrambled portion, the unscrambled portion including timing information in accordance with an SSB periodicity and the MIB periodicity, cell access information, or both. For example, the PBCH 472 includes the scrambled portion 476 and the unscrambled portion 478, and the PBCH 482 includes the scrambled portion 486 and the unscrambled portion 488. The network node 450 may select which bits are to be included in the unscrambled portion 478 and the unscrambled portion 488 in accordance with the SSB periodicity 454 and the MIB periodicity 456. In some implementations, for each unscrambled portion of the plurality of PBCHs, the timing information includes at least a fourth LSB of a SFN, a fifth LSB of the SFN, or a sixth LSB of the SFN, and the cell access information includes a cell barred bit, an intra-frequency reselection bit, or a combination thereof. For example, the timing information may include at least the fourth LSB 732 of FIG. 7A, the fourth LSB 766 and the fifth LSB 767 of FIG. 7B, and the fifth LSB 796 and the sixth LSB 797 of FIG. 7C. Additionally or alternatively, the cell access information may include the cell barred bit 612, the intra-frequency reselection bit 614, or both.

In block 1104, the network node 1300 transmits, to a UE and in accordance with the SSB periodicity, a plurality of SSBs that respectively include the plurality of PBCH. For example, the plurality of SSBs may include or correspond to the SSB 470 and the SSB 480 that are transmitted in accordance with the SSB periodicity 454. The SSB 470 includes the PBCH 472, and the SSB 480 includes the PBCH 482.

In some implementations, the plurality of PBCHs includes a first set of PBCHs associated with a first MIB period and a second set of PBCHs associated with a second MIB period. For example, the time periods during which some of the SSBs are transmitted may include the first MIB period 720 and the second MIB period 722 of FIG. 7A.

In some implementations, the network node is included in an NTN, and the process 1100 also includes transmitting, to another network node of a TN, an indicator of coverage information associated with the NTN, an indicator of frequency information associated with the NTN, or a combination thereof. For example, the network node 450 may transmit the information included in or indicated by the network indicator 440 to the network node 430. The coverage information may include the SSB periodicity and beam timing information associated with the NTN, one or more beam centers associated with the NTN, one or more beam diameters associated with the NTN, or a combination thereof. The frequency information may include a raster frequency associated with the NTN, a SCS value associated with the NTN, or a combination thereof. For example, the network indicator 440 may include or correspond to the network indicator 522 of FIG. 5C that includes the coverage information 524 and the frequency information 526.

As described with reference to FIG. 11, the process 1100 supports PBCH scrambling and soft combining for supporting larger SSB periodicities. For example, in contrast to typical wireless networks in which the SSB periodicity for initial cell selection is set at a fixed value for multiple types of wireless networks, the process 1100 enables the network node 1300 to support larger SSB periodicities, such as once per 40 ms, once per 80 ms, or once per 160 ms, as non-limiting examples. Increasing the SSB periodicity reduces the frequency of SSB transmissions by the network node 1300 and thus reduces power consumption at the network node 1300, which may be beneficial to NTN nodes or other types of wireless network nodes that do not have access to fixed power supplies.

Referring to the process 1200 of FIG. 12, in block 1202, the network node 1300 generates a plurality of PBCH payloads. The plurality of PBCH payloads respectively include a plurality of MIBs in accordance with a MIB periodicity. For example, the network node 450 may generate the MIB 474 and the MIB 484 as two respective PBCH payloads.

In block 1204, for each PBCH payload of the plurality of PBCH payloads, the network node 1300 identifies a set of unscrambled bits of the PBCH payload in accordance with a SSB periodicity and the MIB periodicity. For example, the network node 450 may select which bits are to be included in the unscrambled portion 478 and the unscrambled portion 488 in accordance with the SSB periodicity 454 and the MIB periodicity 456.

In block 1206, for each PBCH payload of the plurality of PBCH payloads, the network node 1300 scrambles the PBCH payload in accordance with a portion of a scrambling sequence that is associated with the set of unscrambled bits. For example, the network node 450 may scramble the scrambled portion 476 in accordance with a portion of a scrambling sequence that is indicated by the scrambling configuration 461 and is associated with the unscrambled portion 478. Similarly, the network node 450 may scramble the scrambled portion 486 in accordance with a portion of a scrambling sequence that is indicated by the scrambling configuration 461 and is associated with the unscrambled portion 488.

In block 1208, for each PBCH payload of the plurality of PBCH payloads, the network node 1300 performs channel coding on the scrambled PBCH payload to generate a respective PBCH of a plurality of PBCHs. For example, the network node 450 may perform channel coding on the scrambled portion 476 and the unscrambled portion 478 to generate the PBCH 472. Similarly, the network node 450 may perform channel coding on the scrambled portion 486 and the unscrambled portion 488 to generate the PBCH 482.

In block 1210, the network node 1300 transmits, to a UE and in accordance with the SSB periodicity, a plurality of SSBs that respectively include the plurality of PBCHs. For example, the plurality of SSBs may include or correspond to the SSB 470 and the SSB 480 that are transmitted in accordance with the SSB periodicity 454. The SSB 470 includes the PBCH 472, and the SSB 480 includes the PBCH 482.

In some implementations, for each PBCH payload of the plurality of PBCH payloads, the set of unscrambled bits includes one or more LSBs of timing information associated with the respective MIB included in the scrambled PBCH payload. For example, the unscrambled portions 478, 488 may include one or more LSBs of the timing information 458 that are associated with the MIBs 474, 484, respectively. In some implementations, the one or more LSBs of the timing information includes at least a fourth LSB of a SFN, a fifth LSB of the SFN, a sixth LSB of the SFN, or a combination thereof, as described above with reference to FIGS. 7A-7C. In some such implementations, the SSB periodicity is equal to 20*2ⁿ⁻¹, n is a positive integer, and the one or more LSBs of the timing information include an (n+1)th LSB of a SFN and an (n+2)th LSB of the SFN, as described with reference to FIG. 4.

In some implementations, the process 1200 includes, for a PBCH payload of the plurality of PBCH payloads, setting an initialization time associated with the scrambling sequence in accordance with the SSB periodicity. For example, the network node 450 may set the initialization time associated with the scrambling sequence for the scrambled portion 476 of the PBCH 472 in accordance with the SSB periodicity 454. In some such implementations, n is a positive integer and the initialization time corresponds to a SFN associated with the respective MIB that satisfies mod(SFN, 2*2ⁿ⁺¹)=0, as further described above with reference to FIG. 4.

It is noted that one or more blocks (or operations) described with reference to FIGS. 8, 9, 11, and 12 may be combined with one or more blocks (or operations) described with reference to another of the figures. For example, one or more blocks (or operations) of FIG. 8 may be combined with one or more blocks (or operations) of FIG. 9. As another example, one or more blocks (or operations) of FIG. 11 may be combined with one or more blocks (or operations) of FIG. 12. As another example, one or more blocks associated with FIG. 8-10 may be combined with one or more blocks (or operations) associated with FIGS. 1-7C. Additionally, or alternatively, one or more operations described above with reference to FIGS. 1-7C may be combined with one or more operations described with reference to FIGS. 11-13.

In the following, further examples are described to facilitate the understanding of the disclosure.

According to Example 1, a UE for wireless communication includes: a processing system that includes one or more processors and one or more memories coupled with the one or more processors, the processing system configured to cause the UE to: receive, from a network node, a plurality of SSBs in accordance with an SSB periodicity, the plurality of SSBs respectively including a plurality of PBCHs, the plurality of PBCHs respectively including a plurality of MIBs in accordance with a MIB periodicity, wherein each PBCH of the plurality of PBCHs includes: a scrambled portion; and an unscrambled portion, the unscrambled portion including timing information in accordance with the SSB periodicity and the MIB periodicity, cell access information, or both; and decode the plurality of PBCHs by soft combining the PBCHs in accordance with the timing information, the cell access information, or both.

Example 2 includes the UE of Example 1, where, to soft combine a first PBCH and a second PBCH of the plurality of PBCHs, the processing system is configured to cause the UE to: calculate a difference between the respective unscrambled portion of the first PBCH and the respective unscrambled portion of the second PBCH; adjust a LLR value associated with the second PBCH in accordance with the difference; and decode the first PBCH and the second PBCH in accordance with the adjusted LLR value associated with the second PBCH.

Example 3 includes the UE of Example 1 or Example 2, where, for each unscrambled portion of the plurality of PBCHs, the timing information includes at least a fourth LSB of a SFN, a fifth LSB of the SFN, or a sixth LSB of the SFN.

Example 4 includes the UE of any of Examples 1 to 3, where: the SSB periodicity is 40 ms, the MIB periodicity is 80 ms, and for each unscrambled portion of the plurality of PBCHs, the timing information includes a third LSB of a SFN and a fourth LSB of the SFN.

Example 5 includes the UE of any of Examples 1 to 3, where: the SSB periodicity is 80 ms or 160 ms, the MIB periodicity is 80 ms, the plurality of SSBs is received over at least two MIB periods associated with the MIB periodicity, and the timing information includes two of: a fourth LSB of a SFN, a fifth LSB of the SFN, or a sixth LSB of the SFN.

Example 6 includes the UE of any of Examples 1 to 5, where the cell access information in each of the unscrambled portions of the plurality of PBCHs includes at least one of a respective cell barred bit and a respective intra-frequency reselection bit.

Example 7 includes the UE of any of Examples 1 to 6, where the processing system is configured to cause the UE to, prior to receipt of the plurality of SSBs: receive, from a different network node of a first wireless network, an indicator of coverage information associated with a second wireless network, wherein the second wireless network includes the network node, wherein the coverage information includes: the SSB periodicity, and beam timing information associated with the second wireless network, one or more beam centers associated with the second wireless network, one or more beam diameters associated with the second wireless network, or a combination thereof; and perform an initial connection procedure with the second wireless network in accordance with the coverage information, wherein receipt of the plurality of SSBs occurs during the initial connection procedure.

Example 8 includes the UE of Example 7, where: the indicator is included in a SIB, a MAC-CE, or a RRC message, the first wireless network includes a TN, and the second wireless network includes a NTN.

Example 9 includes the UE of Example 7 or Example 8, where the coverage information further includes an indication of the timing information.

Example 10 includes the UE of any of Examples 1 to 9, where the processing system is configured to cause the UE to, prior to receipt of the plurality of SSBs: receive, from a different network node of a first wireless network, an indicator of frequency information associated with a second wireless network, wherein the second wireless network includes the network node, and wherein the frequency information includes a raster frequency associated with the second wireless network, a subcarrier spacing (SCS) value associated with the second wireless network, or a combination thereof; and perform an initial connection procedure with the second wireless network in accordance with the frequency information, wherein receipt of the plurality of SSBs occurs during the initial connection procedure.

Example 11 includes the UE of Example 10, where: the frequency information includes an ARFCN that indicates the raster frequency, the indicator is included in a SIB, a MAC-CE, or a RRC message, the first wireless network includes a TN, and the second wireless network includes a NTN.

According to Example 12, a method of wireless communication by a UE includes: receiving, from a network node, a plurality of SSBs in accordance with an SSB periodicity, the plurality of SSBs respectively including a plurality of PBCHs, the plurality of PBCHs respectively including a plurality of MIBs in accordance with a MIB periodicity, wherein each PBCH of the plurality of PBCHs includes: a scrambled portion; and an unscrambled portion, the unscrambled portion including timing information in accordance with the SSB periodicity and the MIB periodicity, cell access information, or both; and decoding the plurality of PBCHs by soft combining the PBCHs in accordance with the timing information, the cell access information, or both.

Example 13 includes the method of Example 12, where soft combining a first PBCH and a second PBCH of the plurality of PBCHs comprises: calculating a difference between the respective unscrambled portion of the first PBCH and the respective unscrambled portion of the second PBCH; adjusting a LLR value associated with the second PBCH in accordance with the difference; and decoding the first PBCH and the second PBCH in accordance with the adjusted LLR value associated with the second PBCH.

Example 14 includes the method of Example 12 or Example 13, where, for each unscrambled portion of the plurality of PBCHs, the timing information includes at least a fourth LSB of a SFN, a fifth LSB of the SFN, or a sixth LSB of the SFN.

Example 15 includes the method of any of Examples 12 to 14, where: the SSB periodicity is 40 ms, the MIB periodicity is 80 ms, and for each unscrambled portion of the plurality of PBCHs, the timing information includes a third LSB of a SFN and a fourth LSB of the SFN.

Example 16 includes the method of any of Examples 12 to 15, where: the SSB periodicity is 80 ms or 160 ms, the MIB periodicity is 80 ms, the plurality of SSBs is received over at least two MIB periods associated with the MIB periodicity, and the timing information includes two of: a fourth LSB of a SFN, a fifth LSB of the SFN, or a sixth LSB of the SFN.

Example 17 includes the method of any of Examples 12 to 15, where the cell access information in each of the unscrambled portions of the plurality of PBCHs includes at least one of a respective cell barred bit and a respective intra-frequency reselection bit.

Example 18 includes the method of any of Examples 12 to 17, and further includes, prior to receiving the plurality of SSBs: receiving, from a different network node of a first wireless network, an indicator of coverage information associated with a second wireless network, wherein the second wireless network includes the network node, wherein the coverage information includes: the SSB periodicity, and beam timing information associated with the second wireless network, one or more beam centers associated with the second wireless network, one or more beam diameters associated with the second wireless network, or a combination thereof; and performing an initial connection procedure with the second wireless network in accordance with the coverage information, wherein receipt of the plurality of SSBs occurs during the initial connection procedure.

Example 19 includes the method of Example 18, where: the indicator is included in a SIB, a MAC-CE, or a RRC message, the first wireless network includes a TN, and the second wireless network includes a NTN.

Example 20 includes the method of Example 18 or Example 19, where the coverage information further includes an indication of the timing information.

Example 21 includes the method of any of Examples 12 to 20, and further includes, prior to receiving the plurality of SSBs: receiving, from a different network node of a first wireless network, an indicator of frequency information associated with a second wireless network, wherein the second wireless network includes the network node, and wherein the frequency information includes a raster frequency associated with the second wireless network, a SCS value associated with the second wireless network, or a combination thereof; and performing an initial connection procedure with the second wireless network in accordance with the frequency information, wherein receipt of the plurality of SSBs occurs during the initial connection procedure.

Example 22 includes the method of Example 21, where: the frequency information includes an ARFCN that indicates the raster frequency, the indicator is included in a SIB, a MAC-CE, or a RRC message, the first wireless network includes a TN, and the second wireless network includes a NTN.

According to Example 23, a network node for wireless communication includes: a processing system that includes one or more processors and one or more memories coupled with the one or more processors, the processing system configured to cause the network node to: generate a plurality of PBCHs, the plurality of PBCHs respectively including a plurality of MIBs in accordance with a MIB periodicity, wherein each PBCH of the plurality of PBCHs includes: a scrambled portion; and an unscrambled portion, the unscrambled portion including timing information in accordance with a SSB periodicity and the MIB periodicity, cell access information, or both; and transmit, to a UE and in accordance with the SSB periodicity, a plurality of SSBs that respectively include the plurality of PBCH.

Example 24 includes the network node of Example 23, where, for each unscrambled portion of the plurality of PBCHs: the timing information includes at least a fourth LSB of a SFN, a fifth LSB of the SFN, or a sixth LSB of the SFN; and the cell access information includes a cell barred bit, an intra-frequency reselection bit, or a combination thereof.

Example 25 includes the network node of Example 23 or Example 24, where the plurality of PBCHs includes a first set of PBCHs associated with a first MIB period and a second set of PBCHs associated with a second MIB period.

Example 26 includes the network node of any of Examples 23 to 25, where the network node is included in a NTN, and wherein the processing system is configured to cause the network node to: transmit, to another network node of a TN, an indicator of coverage information associated with the NTN, an indicator of frequency information associated with the NTN, or a combination thereof, wherein: the coverage information includes: the SSB periodicity, and beam timing information associated with the NTN, one or more beam centers associated with the NTN, one or more beam diameters associated with the NTN, or a combination thereof, and the frequency information includes a raster frequency associated with the NTN, a subcarrier spacing (SCS) value associated with the NTN, or a combination thereof.

According to Example 27, a method of wireless communication by a network node includes: generating a plurality of PBCHs, the plurality of PBCHs respectively including a plurality of MIBs in accordance with a MIB periodicity, wherein each PBCH of the plurality of PBCHs includes: a scrambled portion; and an unscrambled portion, the unscrambled portion including timing information in accordance with a SSB periodicity and the MIB periodicity, cell access information, or both; and transmitting, to a UE and in accordance with the SSB periodicity, a plurality of SSBs that respectively include the plurality of PBCH.

Example 28 includes the method of Example 27, where, for each unscrambled portion of the plurality of PBCHs: the timing information includes at least a fourth LSB of a SFN, a fifth LSB of the SFN, or a sixth LSB of the SFN; and the cell access information includes a cell barred bit, an intra-frequency reselection bit, or a combination thereof.

Example 29 includes the method of Example 27 or Example 28, where the plurality of PBCHs includes a first set of PBCHs associated with a first MIB period and a second set of PBCHs associated with a second MIB period.

Example 30 includes the method of any of Examples 27 to 29, where the network node is included in a NTN, and further includes transmitting, to another network node of a TN, an indicator of coverage information associated with the NTN, an indicator of frequency information associated with the NTN, or a combination thereof, wherein: the coverage information includes: the SSB periodicity, and beam timing information associated with the NTN, one or more beam centers associated with the NTN, one or more beam diameters associated with the NTN, or a combination thereof, and the frequency information includes a raster frequency associated with the NTN, a SCS value associated with the NTN, or a combination thereof.

According to Example 31, a UE for wireless communication includes: a processing system that includes one or more processors and one or more memories coupled with the one or more processors, the processing system configured to cause the UE to: receive, from a network node, a plurality of SSBs in accordance with an SSB periodicity, the plurality of SSBs respectively including a plurality of PBCHs, the plurality of PBCHs respectively including a plurality of MIBs in accordance with a MIB periodicity; decode the plurality of PBCHs by soft combining the plurality of PBCHs to generate a plurality of scrambled PBCH payloads; and for each scrambled PBCH payload of the plurality of scrambled PBCH payloads: identify a set of unscrambled bits of the scrambled PBCH payload in accordance with the SSB periodicity and the MIB periodicity; and descramble the scrambled PBCH payload in accordance with a portion of a scrambling sequence that is associated with the set of unscrambled bits.

Example 32 includes the UE of Example 31, where, to soft combine a first PBCH and a second PBCH of the plurality of PBCHs, the processing system is configured to cause the UE to: calculate a difference between the first PBCH and the second PBCH, adjust a LLR value associated with the second PBCH in accordance with the difference, and decode the first PBCH and the second PBCH in accordance with the adjusted LLR value associated with the second PBCH.

Example 33 includes the UE of Example 31 or Example 32, where each scrambled PBCH payload of the plurality of scrambled PBCH payloads includes a respective MIB of the plurality of MIBs, and for each scrambled PBCH payload of the plurality of scrambled PBCH payloads, the set of unscrambled bits comprises one or more least significant bits (LSBs) of timing information associated with the respective MIB.

Example 34 includes the UE of Example 33, where the one or more LSBs of the timing information include a fourth LSB of a SFN, a fifth LSB of the SFN, a sixth LSB of the SFN, or a combination thereof.

Example 35 includes the UE of Examples 33 or Example 34, where: the SSB periodicity is equal to 20*2ⁿ⁻¹, n is a positive integer, and the one or more LSBs of the timing information include an (n+1)th LSB of a SFN and an (n+2)th LSB of the SFN.

Example 36 includes the UE of any of Examples 31 to 35, where the one or more processors are configured to, for a scrambled PBCH payload of the plurality of scrambled PBCH payloads: identify an initialization time associated with the scrambling sequence in accordance with the SSB periodicity.

Example 37 includes the UE of Example 36, where: n is a positive integer, mod(A, B) represents the modulo arithmetic operation on inputs A and B, and the initialization time corresponds to a SFN associated with the respective MIB that satisfies: mod(SFN, 2*2ⁿ⁺¹)=0.

Example 38 includes the UE of Example 37, where the initialization time corresponds to the SFN associated with the respective MIB that has a different value of a fourth LSB than a previous SFN.

Example 39 includes the UE of Example 37, where the initialization time corresponds to the SFN associated with the respective MIB that has a different value of a fifth LSB than a previous SFN.

Example 40 includes the UE of any of Examples 31 to 39, wherein: the SSB periodicity is 40 ms, 80 ms, or 160 ms, and the MIB periodicity is 80 ms.

According to Example 41, a method of wireless communication by a user UE includes: receiving, from a network node, a plurality of SSBs in accordance with an SSB periodicity, the plurality of SSBs respectively including a plurality of PBCHs, the plurality of PBCHs respectively including a plurality of MIBs in accordance with a MIB periodicity; decoding the plurality of PBCHs by soft combining the plurality of PBCHs to generate a plurality of scrambled PBCH payloads; and, for each scrambled PBCH payload of the plurality of scrambled PBCH payloads: identifying a set of unscrambled bits of the scrambled PBCH payload in accordance with the SSB periodicity and the MIB periodicity; and descrambling the scrambled PBCH payload in accordance with a portion of a scrambling sequence that is associated with the set of unscrambled bits.

Example 42 includes the method of Example 41, where soft combining a first PBCH and a second PBCH of the plurality of PBCHs comprises: calculating a difference between the first PBCH and the second PBCH; adjusting a LLR value associated with the second PBCH in accordance with the difference; and decoding the first PBCH and the second PBCH in accordance with the adjusted LLR value associated with the second PBCH.

Example 43 includes the method of Example 41 or Example 42, where each scrambled PBCH payload of the plurality of scrambled PBCH payloads includes a respective MIB of the plurality of MIBs, and for each scrambled PBCH payload of the plurality of scrambled PBCH payloads, the set of unscrambled bits comprises one or more least significant bits (LSBs) of timing information associated with the respective MIB.

Example 44 includes the method of Example 43, where the one or more LSBs of the timing information include a fourth LSB of a SFN, a fifth LSB of the SFN, a sixth LSB of the SFN, or a combination thereof.

Example 45 includes the method of Example 43 or Example 44, where: the SSB periodicity is equal to 20*2ⁿ⁻¹, n is a positive integer, and the one or more LSBs of the timing information include an (n+1)th LSB of a SFN and an (n+2)th LSB of the SFN.

Example 46 includes the method of any of Examples 41 to 45 and further includes, for a scrambled PBCH payload of the plurality of scrambled PBCH payloads: identifying an initialization time associated with the scrambling sequence in accordance with the SSB periodicity.

Example 47 includes the method of Example 46, where: n is a positive integer, mod(A, B) represents the modulo arithmetic operation on inputs A and B, and the initialization time corresponds to a SFN associated with the respective MIB that satisfies: mod(SFN, 2*2ⁿ⁺¹)=0.

Example 48 includes the method of Example 47, where the initialization time corresponds to the SFN associated with the respective MIB that has a different value of a fourth LSB than a previous SFN.

Example 49 includes the method of Example 47, where the initialization time corresponds to the SFN associated with the respective MIB that has a different value of a fifth LSB than a previous SFN.

Example 50 includes the method of any of Examples 41 to 49, where: the SSB periodicity is 40 ms, 80 ms, or 160 ms, and the MIB periodicity is 80 ms.

According to Example 51, a network node for wireless communication includes: a processing system that includes one or more processors and one or more memories coupled with the one or more processors, the processing system configured to cause the network node to: generate a plurality of PBCH payloads, the plurality of PBCH payloads respectively including a plurality of MIBs in accordance with a MIB periodicity; for each PBCH payload of the plurality of PBCH payloads: identify a set of unscrambled bits of the PBCH payload in accordance with a SSB periodicity and the MIB periodicity; scramble the PBCH payload in accordance with a portion of a scrambling sequence that is associated with the set of unscrambled bits; and perform channel coding on the scrambled PBCH payload to generate a respective PBCH of a plurality of PBCHs; and transmit, to a UE and in accordance with the SSB periodicity, a plurality of SSBs that respectively include the plurality of PBCHs.

Example 52 includes the network node of Example 51, where each scrambled PBCH payload of the plurality of scrambled PBCH payloads includes a respective MIB of the plurality of MIBs, and for each scrambled PBCH payload of the plurality of scrambled PBCH payloads, the set of unscrambled bits comprises one or more least significant bits (LSBs) of timing information associated with the respective MIB.

Example 53 includes the network node of Example 52, where: the SSB periodicity is equal to 20*2n−1, n is a positive integer, and the one or more LSBs of the timing information include an (n+1)th LSB of a SFN and an (n+2)th LSB of the SFN.

Example 54 includes the network node of any of Examples 51 to 53, where the one or more processors are configured to, for a PBCH payload of the plurality of PBCH payloads: set an initialization time associated with the scrambling sequence in accordance with the SSB periodicity.

Example 55 includes the network node of Example 54, where: n is a positive integer, mod(A, B) represents the modulo arithmetic operation on inputs A and B, and the initialization time corresponds to a SFN associated with the respective MIB that satisfies: mod(SFN, 2*2ⁿ⁺¹)=0.

According to Example 56, a method of wireless communication by a network node includes: generating a plurality of PBCH payloads, the plurality of PBCH payloads respectively including a plurality of MIBs in accordance with a MIB periodicity; for each PBCH payload of the plurality of PBCH payloads: identifying a set of unscrambled bits of the PBCH payload in accordance with a SSB periodicity and the MIB periodicity; scrambling the PBCH payload in accordance with a portion of a scrambling sequence that is associated with the set of unscrambled bits; and performing channel coding on the scrambled PBCH payload to generate a respective PBCH of a plurality of PBCHs; and transmitting, to a UE and in accordance with the SSB periodicity, a plurality of SSBs that respectively include the plurality of PBCHs.

Example 57 includes the method of Example 56, where each scrambled PBCH payload of the plurality of scrambled PBCH payloads includes a respective MIB of the plurality of MIBs, and for each scrambled PBCH payload of the plurality of scrambled PBCH payloads, the set of unscrambled bits comprises one or more least significant bits (LSBs) of timing information associated with the respective MIB.

Example 58 includes the method of Example 57, where: the SSB periodicity is equal to 20*2ⁿ⁻¹, n is a positive integer, and the one or more LSBs of the timing information include an (n+1)th LSB of a SFN and an (n+2)th LSB of the SFN.

Example 59 includes the method of any of Examples 56 to 58 and further includes, for a PBCH payload of the plurality of PBCH payloads: setting an initialization time associated with the scrambling sequence in accordance with the SSB periodicity.

Example 60 includes the method of Example 59, where: n is a positive integer, mod(A, B) represents the modulo arithmetic operation on inputs A and B, and the initialization time corresponds to a SFN associated with the respective MIB that satisfies: mod(SFN, 2*2ⁿ⁺¹)=0.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Components, the functional blocks, and the modules described herein with respect to FIGS. 1-13 include processors, electronics devices, hardware devices, electronics components, logical circuits, memories, software codes, firmware codes, among other examples, or any combination thereof. In addition, features discussed herein may be implemented via specialized processor circuitry, via executable instructions, or combinations thereof.

Those of skill would further appreciate that the various illustrative logics, logical blocks, modules, circuits, and algorithm processes described in connection with the disclosure herein may be implemented as electronic hardware, computer software, or combinations of both. To clearly illustrate this interchangeability of hardware and software, various illustrative components, blocks, modules, circuits, and processes have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure. Skilled artisans will also readily recognize that the order or combination of components, methods, or interactions that are described herein are merely examples and that the components, methods, or interactions of the various aspects of the present disclosure may be combined or performed in ways other than those illustrated and described herein.

As used herein, the term “component” is intended to be broadly construed as hardware or a combination of hardware and at least one of software or firmware. “Software” shall be construed broadly to mean instructions, instruction sets, code, code segments, program code, programs, subprograms, software modules, applications, software applications, software packages, routines, subroutines, objects, executables, threads of execution, procedures, or functions, among other examples, whether referred to as software, firmware, middleware, microcode, hardware description language, or otherwise. As used herein, a “processor” is implemented in hardware or a combination of hardware and software. It will be apparent that systems or methods described herein may be implemented in different forms of hardware or a combination of hardware and software. The actual specialized control hardware or software code used to implement these systems or methods is not limiting of the aspects. Thus, the operation and behavior of the systems or methods are described herein without reference to specific software code, because those skilled in the art will understand that software and hardware can be designed to implement the systems or methods based, at least in part, on the description herein. A component being configured to perform a function means that the component has a capability to perform the function, and does not require the function to be actually performed by the component, unless noted otherwise.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or any conventional processor, controller, microcontroller, or state machine. In some implementations, a processor may be implemented as a combination of computing devices, such as a combination of a DSP and a microprocessor, a plurality of microprocessors, one or more microprocessors in conjunction with a DSP core, or any other such configuration. In some implementations, particular processes and methods may be performed by circuitry that is specific to a given function.

If implemented in software, the functions may be stored on or transmitted over as one or more instructions or code on a computer-readable medium. The processes of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include random access memory (RAM), read-only memory (ROM), electronically erasable programable ROM (EEPROM), compact disc (CD) ROM (CD-ROM), or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and Blu-ray disc where disks usually reproduce data magnetically, while discs reproduce data optically with lasers. Combinations of the above should also be included within the scope of computer-readable media. Additionally, the operations of a method or algorithm may reside as one or any combination or set of codes and instructions on a machine readable medium and computer-readable medium, which may be incorporated into a computer program product or a computer-readable storage device.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one or more example processes in the form of a flow diagram. However, other operations that are not depicted can be incorporated in the example processes that are schematically illustrated. For example, one or more additional operations can be performed before, after, simultaneously with, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, some other implementations are within the scope of the following claims. In some cases, the actions recited in the claims can be performed in a different order and still achieve desirable results.

As used herein, including in the claims, the term “or,” when used in a list of two or more items, means that any one of the listed items can be employed by itself, or any combination of two or more of the listed items can be employed. For example, if a composition is described as containing components A, B, or C, the composition can contain A alone; B alone; C alone; A and B in combination; A and C in combination; B and C in combination; or A, B, and C in combination. Also, as used herein, including in the claims, “or” as used in a list of items prefaced by “at least one of” indicates a disjunctive list such that, for example, a list of “at least one of A, B, or C” means A or B or C or AB or AC or BC or ABC (that is A and B and C) or any of these in any combination thereof. The term “substantially” is defined as largely but not necessarily wholly what is specified (and includes what is specified; for example, substantially 90 degrees includes 90 degrees and substantially parallel includes parallel), as understood by a person of ordinary skill in the art. In any disclosed implementations, the term “substantially” may be substituted with “within [a percentage] of” what is specified, where the percentage includes 0.1, 1, 5, or 10 percent.

As used herein, “satisfying a threshold” may, depending on the context, refer to a value being greater than the threshold, greater than or equal to the threshold, less than the threshold, less than or equal to the threshold, equal to the threshold, or not equal to the threshold, among other examples. Such a threshold may be a single value or a range of values. As an illustrative example, a value may satisfy a threshold range of values if the value is greater than or equal to each of the threshold values included within in the threshold range of values.

No element, act, or instruction used herein should be construed as critical or essential unless explicitly described as such. Also, as used herein, the articles “a” and “an” are intended to include one or more items and may be used interchangeably with “one or more.” It should be understood that “one or more” is equivalent to “at least one.” Further, as used herein, the article “the” is intended to include one or more items referenced in connection with the article “the” and may be used interchangeably with “the one or more.” Furthermore, as used herein, the terms “set” and “group” are intended to include one or more items and may be used interchangeably with “one or more.” Where only one item is intended, the phrase “only one” or similar language is used. Also, as used herein, the terms “has,” “have,” “having,” and similar terms are intended to be open-ended terms that do not limit an element that they modify (for example, an element “having” A may also have B). Further, the phrase “based on” is intended to mean “based on or otherwise in association with” unless explicitly stated otherwise. Similarly, the phrase “in accordance with” is intended to mean “based on or otherwise in association with” unless explicitly stated otherwise.

The previous description of the disclosure is provided to enable any person skilled in the art to make or use the disclosure. Various modifications to the implementations described in this disclosure may be readily apparent to those skilled in the art, and the generic principles defined herein may be applied to other variations without departing from the scope of this disclosure. Thus, the disclosure is not intended to be limited to the examples and designs described herein but is to be accorded the widest scope consistent with the principles and novel features disclosed herein.

Even though particular combinations of features are recited in the claims or disclosed in the specification, these combinations are not intended to limit the disclosure of various aspects. Many of these features may be combined in ways not specifically recited in the claims or disclosed in the specification. The disclosure of various aspects includes each dependent claim in combination with every other claim in the claim set.

What is claimed is:

1. A user equipment (UE) for wireless communication, comprising:
a processing system that includes one or more processors and one or more memories coupled with the one or more processors, the processing system configured to cause the UE to:
receive, from a network node, a plurality of synchronization signal blocks (SSBs) in accordance with an SSB periodicity, the plurality of SSBs respectively including a plurality of physical broadcast channels (PBCHs), the plurality of PBCHs respectively including a plurality of master information blocks (MIBs) in accordance with a MIB periodicity;
decode the plurality of PBCHs by soft combining the plurality of PBCHs to generate a plurality of scrambled PBCH payloads; and
for each scrambled PBCH payload of the plurality of scrambled PBCH payloads:
identify a set of unscrambled bits of the scrambled PBCH payload in accordance with the SSB periodicity and the MIB periodicity; and
descramble the scrambled PBCH payload in accordance with a portion of a scrambling sequence that is associated with the set of unscrambled bits.

2. The UE of claim 1, wherein, to soft combine a first PBCH and a second PBCH of the plurality of PBCHs, the processing system is configured to cause the UE to:
calculate a difference between the first PBCH and the second PBCH,
adjust a log likelihood ratio (LLR) value associated with the second PBCH in accordance with the difference, and
decode the first PBCH and the second PBCH in accordance with the adjusted LLR value associated with the second PBCH.

3. The UE of claim 1, wherein:
each scrambled PBCH payload of the plurality of scrambled PBCH payloads includes a respective MIB of the plurality of MIBs, and
for each scrambled PBCH payload of the plurality of scrambled PBCH payloads, the set of unscrambled bits comprises one or more least significant bits (LSBs) of timing information associated with the respective MIB.

4. The UE of claim 3, wherein the one or more LSBs of the timing information include a fourth LSB of a system frame number (SFN), a fifth LSB of the SFN, a sixth LSB of the SFN, or a combination thereof.

5. The UE of claim 3, wherein:
the SSB periodicity is equal to 20*2ⁿ⁻¹,
n is a positive integer, and
the one or more LSBs of the timing information include an (n+1)th LSB of a system frame number (SFN) and an (n+2)th LSB of the SFN.

6. The UE of claim 1, wherein the one or more processors are configured to, for a scrambled PBCH payload of the plurality of scrambled PBCH payloads:
identify an initialization time associated with the scrambling sequence in accordance with the SSB periodicity.

7. The UE of claim 6, wherein:
n is a positive integer,
mod(A, B) represents the modulo arithmetic operation on inputs A and B, and
the initialization time corresponds to a system frame number (SFN) associated with the respective MIB that satisfies:
$$mod ( S F N , 2 * {2}^{n + 1} ) = 0 .$$

8. The UE of claim 7, wherein the initialization time corresponds to the SFN associated with the respective MIB that has a different value of a fourth least significant bit (LSB) than a previous SFN.

9. The UE of claim 7, wherein the initialization time corresponds to the SFN associated with the respective MIB that has a different value of a fifth least significant bit (LSB) than a previous SFN.

10. The UE of claim 1, wherein:
the SSB periodicity is 40 milliseconds (ms), 80 ms, or 160 ms, and
the MIB periodicity is 80 ms.

11. A method of wireless communication by a user equipment (UE), comprising:
receiving, from a network node, a plurality of synchronization signal blocks (SSBs) in accordance with an SSB periodicity, the plurality of SSBs respectively including a plurality of physical broadcast channels (PBCHs), the plurality of PBCHs respectively including a plurality of master information blocks (MIBs) in accordance with a MIB periodicity,
decoding the plurality of PBCHs by soft combining the plurality of PBCHs to generate a plurality of scrambled PBCH payloads; and
for each scrambled PBCH payload of the plurality of scrambled PBCH payloads:
identifying a set of unscrambled bits of the scrambled PBCH payload in accordance with the SSB periodicity and the MIB periodicity; and
descrambling the scrambled PBCH payload in accordance with a portion of a scrambling sequence that is associated with the set of unscrambled bits.

12. The method of claim 11, wherein soft combining a first PBCH and a second PBCH of the plurality of PBCHs comprises:
calculating a difference between the first PBCH and the second PBCH;
adjusting a log likelihood ratio (LLR) value associated with the second PBCH in accordance with the difference; and
decoding the first PBCH and the second PBCH in accordance with the adjusted LLR value associated with the second PBCH.

13. The method of claim 11, wherein:
each scrambled PBCH payload of the plurality of scrambled PBCH payloads includes a respective MIB of the plurality of MIBs, and
for each scrambled PBCH payload of the plurality of scrambled PBCH payloads, the set of unscrambled bits comprises one or more least significant bits (LSBs) of timing information associated with the respective MIB.

14. The method of claim 13, wherein the one or more LSBs of the timing information include a fourth LSB of a system frame number (SFN), a fifth LSB of the SFN, a sixth LSB of the SFN, or a combination thereof.

15. The method of claim 13, wherein:
the SSB periodicity is equal to 20*2ⁿ⁻¹,
n is a positive integer, and
the one or more LSBs of the timing information include an (n+1)th LSB of a system frame number (SFN) and an (n+2)th LSB of the SFN.

16. The method of claim 11, further comprising, for a scrambled PBCH payload of the plurality of scrambled PBCH payloads:
identifying an initialization time associated with the scrambling sequence in accordance with the SSB periodicity.

17. The method of claim 16, wherein:
n is a positive integer, and
mod(A, B) represents the modulo arithmetic operation on inputs A and B,
the initialization time corresponds to a system frame number (SFN) associated with the respective MIB that satisfies:
$$mod ( S F N , 2 * {2}^{n + 1} ) = 0 .$$

18. The method of claim 17, wherein the initialization time corresponds to the SFN associated with the respective MIB that has a different value of a fourth least significant bit (LSB) than a previous SFN.

19. The method of claim 17, wherein the initialization time corresponds to the SFN associated with the respective MIB that has a different value of a fifth least significant bit (LSB) than a previous SFN.

20. The method of claim 11, wherein:
the SSB periodicity is 40 milliseconds (ms), 80 ms, or 160 ms, and
the MIB periodicity is 80 ms.

21. A network node for wireless communication, comprising:
a processing system that includes one or more processors and one or more memories coupled with the one or more processors, the processing system configured to cause the network node to:
generate a plurality of physical broadcast channel (PBCH) payloads, the plurality of PBCH payloads respectively including a plurality of master information blocks (MIBs) in accordance with a MIB periodicity;
for each PBCH payload of the plurality of PBCH payloads:
identify a set of unscrambled bits of the PBCH payload in accordance with a synchronization signal block (SSB) periodicity and the MIB periodicity;
scramble the PBCH payload in accordance with a portion of a scrambling sequence that is associated with the set of unscrambled bits; and
perform channel coding on the scrambled PBCH payload to generate a respective PBCH of a plurality of PBCHs; and
transmit, to a user equipment (UE) and in accordance with the SSB periodicity, a plurality of SSBs that respectively include the plurality of PBCHs.

22. The network node of claim 21, wherein:
each scrambled PBCH payload of the plurality of scrambled PBCH payloads includes a respective MIB of the plurality of MIBs, and
for each scrambled PBCH payload of the plurality of scrambled PBCH payloads, the set of unscrambled bits comprises one or more least significant bits (LSBs) of timing information associated with the respective MIB.

23. The network node of claim 22, wherein:
the SSB periodicity is equal to 20*2ⁿ⁻¹,
n is a positive integer, and
the one or more LSBs of the timing information include an (n+1)th LSB of a system frame number (SFN) and an (n+2)th LSB of the SFN.

24. The network node of claim 21, wherein the one or more processors are configured to, for a PBCH payload of the plurality of PBCH payloads:
set an initialization time associated with the scrambling sequence in accordance with the SSB periodicity.

25. The network node of claim 24, wherein:
n is a positive integer,
mod(A, B) represents the modulo arithmetic operation on inputs A and B, and
the initialization time corresponds to a system frame number (SFN) associated with the respective MIB that satisfies:
$$mod ( S F N , 2 * {2}^{n + 1} ) = 0 .$$

26. A method of wireless communication by a network node, comprising:
generating a plurality of physical broadcast channel (PBCH) payloads, the plurality of PBCH payloads respectively including a plurality of master information blocks (MIBs) in accordance with a MIB periodicity;
for each PBCH payload of the plurality of PBCH payloads:
identifying a set of unscrambled bits of the PBCH payload in accordance with a synchronization signal block (SSB) periodicity and the MIB periodicity;
scrambling the PBCH payload in accordance with a portion of a scrambling sequence that is associated with the set of unscrambled bits; and
performing channel coding on the scrambled PBCH payload to generate a respective PBCH of a plurality of PBCHs; and
transmitting, to a user equipment (UE) and in accordance with the SSB periodicity, a plurality of SSBs that respectively include the plurality of PBCHs.

27. The method of claim 26, wherein:
each scrambled PBCH payload of the plurality of scrambled PBCH payloads includes a respective MIB of the plurality of MIBs, and
for each scrambled PBCH payload of the plurality of scrambled PBCH payloads, the set of unscrambled bits comprises one or more least significant bits (LSBs) of timing information associated with the respective MIB.

28. The method of claim 27, wherein:
the SSB periodicity is equal to 20*2ⁿ⁻¹,
n is a positive integer, and
the one or more LSBs of the timing information include an (n+1)th LSB of a system frame number (SFN) and an (n+2)th LSB of the SFN.

29. The method of claim 26, further comprising, for a PBCH payload of the plurality of PBCH payloads:
setting an initialization time associated with the scrambling sequence in accordance with the SSB periodicity.

30. The method of claim 29, wherein:
n is a positive integer,
mod(A, B) represents the modulo arithmetic operation on inputs A and B, and
the initialization time corresponds to a system frame number (SFN) associated with the respective MIB that satisfies:
$$mod ( S F N , 2 * {2}^{n + 1} ) = 0 .$$
